(19) United States
(12) Patent Application Publication
(10) Pub. No.: US 2025/0361246 A1
(43) Pub. Date: Nov. 27, 2025

(54) ORGANIC ELECTROLUMINESCENT MATERIAL AND USE THEREOF

(71) Applicant: GUANGDONG AGLAIA OPTOELECTRONIC MATERIALS CO., LTD, Guangdong (CN)

(72) Inventors: Keyan BAI, Guangdong (CN); Lei DAI, Guangdong (CN); Lifei CAI, Guangdong (CN)

(73) Assignee: GUANGDONG AGLAIA OPTOELECTRONIC MATERIALS CO., LTD, Guangdong (CN)

(21) Appl. No.: 18/873,893

(22) PCT Filed: Jun. 28, 2023
(86) PCT No.: PCT/CN2023/102979

§ 371 Date: Dec. 11, 2024

(30) Foreign Application Priority Data
Jul. 19, 2022 (CN) 202210844394.3
Apr. 20, 2023 (CN) 202310426386.1

(51) Int. Cl. C07F 5/02; C09K 11/06; H10K 50/12; H10K 85/60

(52) U.S. Cl. CPC C07F 5/027; C09K 11/06; H10K 85/636; C09K 2211/1018; H10K 50/121; H10K 85/658

(57) ABSTRACT

The present disclosure relates to an organic electroluminescent material having a structural formula as shown in formula (A) or (B). Based on a conventional B-N resonance structure, in such material, an aromatic ring that does not participate in the resonance is fixed to a resonance ring by means of a dimethyl-substituted methylene group to form a larger rigid structure, thereby decreasing non-radiative vibration, reducing delayed fluorescence lifetime and reducing efficiency roll-off. Moreover, the introduction of the dimethyl-substituted methylene distorts the B-N planar skeleton, which can reduce fluorescence quenching at high concentrations, thereby obtaining relatively high efficiency. In addition, when Cy1 and Cy2 are different, especially after a heteroatom is introduced, this type of asymmetric structure can further distort the molecular plane, reduce film aggregation and quenching, and achieve a higher current efficiency.

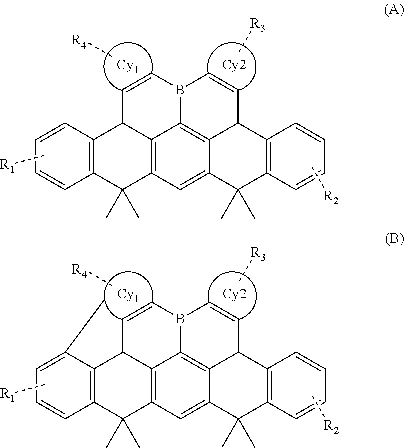

### CROSS-REFERENCE TO RELATED APPLICATIONS

The present application is a national phase entry under 35 USC § 371 of International Application No. PCT/CN2023/102979 filed Jun. 28, 2023, which claims the benefit of and priority to Chinese Patent Application No. 202210844394.3, filed Jul. 19, 2022, and Chinese Patent Application No. 202310426386.1, filed Apr. 20, 2023, the entire disclosures of which are incorporated herein by reference.

### TECHNICAL FIELD

The present disclosure relates to the field of luminescent materials, and in particular, to an organic luminescent material containing a B-N structure and use thereof in organic light-emitting diodes.

### BACKGROUND

Organic light-emitting diode (OLED) devices have been widely used in the display and lighting industry, especially in mobile phone displays. All latest mobile phone products launched by mobile phone manufacturers such as Apple, Samsung, Huawei and Xiaomi use OLED screens, which is mainly attributed to OLED's excellent characteristics such as self-illumination, wide viewing angle, high contrast, fast response speed, and the ability to prepare flexible devices.

Currently commercialized OLED devices have a multi-layer sandwich structure, including an anode, a hole injection layer, a hole transport layer, an emission layer, an electron transport layer, an electron injection layer and a cathode. Holes are generated at the anode and enter the emission layer through the hole injection layer and transport layer, while electrons move from the cathode through the electron injection layer and transport layer to the emission layer. The holes and electrons recombine in the emission layer to generate excitons. These excitons transition from the excited state to the ground state, thereby emitting visible light. In order to achieve color display, OLED devices use the additive color principle, i.e., the emission layer is divided into a blue emission layer, a green emission layer and a red emission layer, and different emission layers use organic materials with different luminescent colors.

When OLED devices are used in displays, they are required to have low driving voltage, high luminous efficiency and long service life. Therefore, in the gradual improvement of display performance, organic materials have experienced the development from fluorescent materials to phosphorescent materials, and then to thermally activated delayed fluorescence materials (TADF). At present, green and red light materials are phosphorescent materials, which can use either singlet excitons or triplet excitons for light-emission, so the internal quantum efficiency can reach 100%. However, phosphorescent materials contain heavy metals and have the problems of high cost and poor stability, etc. Blue light materials are fluorescent materials and can only use singlet excitons for light-emission. Although the TTA (two triplet excitons are converted into one singlet exciton) principle is used, its theoretical efficiency is only 40%, which is far below the market demand. TADF materials utilize a small singlet-triplet energy gap (ΔEST), and triplet excitons can be transformed into singlet excitons by Reverse Intersystem Crossing, thus achieving 100% internal quantum efficiency. However, TADF materials have a strong charge transfer characteristic (CT) and a too wide full-width at half maximum, which is not conducive to high color purity display.

### SUMMARY

In view of the existing problems of the aforementioned organic materials, the present disclosure provides an organic light-emitting material containing a B—N structure and use thereof in organic light-emitting devices. Based on a conventional B—N resonance structure, in such materials, an aromatic ring that does not participate in the resonance is fixed to a resonance ring by means of a dimethyl-substituted methylene group to form a larger rigid structure, thereby decreasing non-radiative vibration, reducing delayed fluorescence lifetime and reducing efficiency roll-off. Moreover, the introduction of the dimethyl-substituted methylene distorts the B—N planar skeleton, which can reduce fluorescence quenching at high concentrations, thereby obtaining a relatively high efficiency.

The present disclosure provides an organic electroluminescent material containing a B—N structure, having a structural formula as shown in formula (A) or (B):

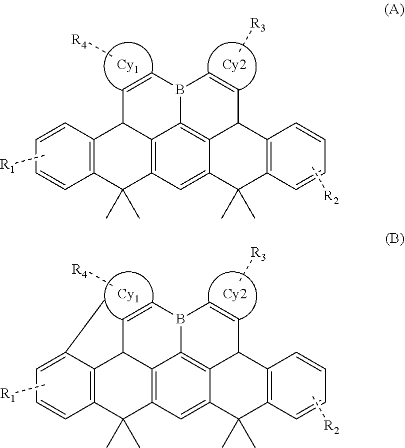

wherein Cy1 and Cy2 each are independently selected from an aryl group having 6-30 carbon atoms, or a substituted or unsubstituted heteroaryl group having 5-30 carbon atoms;
R₁ to R₄ each are independently selected from one or more of the substituents selected from the group consisting of hydrogen, deuterium, cyano, nitro, halogen, hydroxyl, alkylthio having 1 to 4 carbon atoms, alkyl having 1 to 30 carbon atoms, cycloalkyl having 1 to 20 carbon atoms, aryloxy having 6 to 30 carbon atoms, alkoxy having 1 to 30 carbon atoms, alkylamino having 1 to 30 carbon atoms, arylamino having 6 to 30 carbon atoms, arylamino having 6 to 30 carbon atoms, arylalkylamino having 6 to 30 carbon atoms, heteroarylamino having 2 to 24 carbon atoms, alkylsilyl having 1 to 30 carbon atoms, arylsilyl having 6 to 30 carbon atoms, alkenyl having 2 to 30 carbon atoms, alkynyl having 2 to 24 carbon atoms, arylalkyl having 7 to 30 carbon atoms, aryl having 6 to 30 carbon atoms, heteroaryl having 5 to 60 carbon atoms, or heteroarylalkyl having 6 to 30 carbon atoms, respectively; or R₁ to R₄ are connected to an aromatic ring skeleton by any one of a single bond, a substituted or unsubstituted alkyl chain having 1 to 30 carbon atoms, a substituted or unsubstituted alkylthio chain having 1 to 30 carbon atoms, a substituted or unsubstituted alkoxy chain having 1 to 30 carbon atoms, —C—C—, —C═C—, —C═N—, —C═P—, —C≡C—,

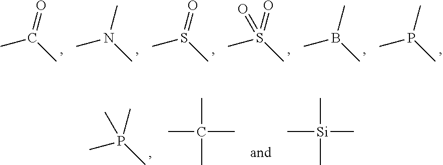

to form a ring;
the substitution is a substitution by halogen, C1-C4 alkyl, or C6-C10 aryl;
the heteroatom in the heteroaryl and heteroarylalkyl is at least one of O, S, N, P, Si, Se.

For example, Cy1 and Cy2 each are independently selected from an aryl group having 6 to 20 carbon atoms, or a substituted or unsubstituted heteroaryl group having 5 to 20 carbon atoms.

For example, Cy1 and Cy2 are different.

R₁ to R₄ each are independently selected from one or more of the substituents selected from the group consisting of hydrogen, deuterium, cyano, nitro, halogen, alkyl having 1 to 10 carbon atoms, cycloalkyl having 1 to 20 carbon atoms, aryloxy having 6 to 20 carbon atoms, alkoxy having 1 to 10 carbon atoms, alkylamino having 1 to 10 carbon atoms, arylamino having 6 to 20 carbon atoms, arylamino having 6 to 20 carbon atoms, arylalkylamino having 6 to 20 carbon atoms, heteroarylamino having 2 to 20 carbon atoms, alkylsilyl having 1 to 10 carbon atoms, arylsilyl having 6 to 20 carbon atoms, alkenyl having 2 to 10 carbon atoms, alkynyl having 2 to 10 carbon atoms, arylalkyl having 7 to 20 carbon atoms, aryl having 6 to 20 carbon atoms, heteroaryl having 5 to 30 carbon atoms, or heteroarylalkyl having 6 to 20 carbon atoms, respectively, or R₁ to R₄ are connected to an aromatic ring skeleton by any one of a single bond, a substituted or unsubstituted alkyl chain having 1 to 30 carbon atoms, a substituted or unsubstituted alkylthio chain having 1 to 30 carbon atoms, a substituted or unsubstituted alkoxy chain having 1 to 30 carbon atoms, —C—C—, —C═C—, —C═N—, —C═P—, —C≡C—,

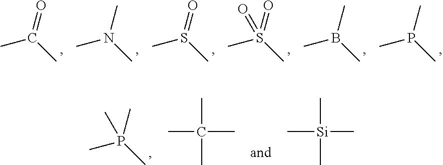

to form a ring.

For example, R₃ and R₄ are not both hydrogen.

The aryl group is selected from one or more of the group consisting of phenyl, naphthyl, anthracenyl, binaphthyl, phenanthrenyl, dihydrophenanthrene, pyrenyl, perylene, tetracene, pentacene, benzoperylene, benzocyclopentadienyl, spirofluorenyl and fluorenyl.

The heteroaryl group is selected from one of more of the group consisting of pyrrolyl, imidazolyl, thienyl, furanyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indole, isoindole, benzimidazole, naphthimidazole, phenanthroimidazole, benzotriazole, purine, benzoxazole, naphthoxazole, phenanthroxazole, benzothiadiazolyl, benzoselenadiazolyl, benzotriazolyl, quinolyl, isoquinolyl, benzopyrazinyl, benzothiophenyl, benzofuranyl, benzopyrrolyl, carbazolyl, acridinyl, dibenzothiophenyl, dibenzofuranyl, silyfluorenyl, dibenzothiophene-5,5-dioxy, naphthothiadiazolyl, naphthoselenadiazolyl and 10,15-dihydro-5H-diindolo[3,2-a:3′,2′-c]carbazole. For example, the heteroaryl group is selected from one or more of the group consisting of pyrrolyl, imidazolyl, thienyl, furanyl, 1,2-thiazolyl, 1,3-thiazolyl, 1,2,3-oxadiazolyl, 1,2,4-oxadiazolyl, thiadiazolyl, selenodiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indole, isoindole, benzimidazole, naphthimidazole, phenanthroimidazole, benzotriazole, purine, benzoxazole, naphthoxazole, phenanthroxazole, benzothiadiazolyl, benzotriazolyl, quinolyl, isoquinolyl, benzopyrazinyl, benzothiophenyl, benzofuranyl, benzopyrrolyl, carbazolyl, acridinyl, dibenzothiophenyl, dibenzofuranyl, dibenzothiophene-5,5-dioxy, naphthothiadiazolyl, naphthoselenodiazolyl and 10,15-dihydro-5H-diindolo[3,2-a:3′,2′-c]carbazolyl.

R₁ to R₄ each are independently selected from the group consisting of hydrogen, deuterium, cyano, methyl, ethyl, propyl, n-propyl, isopropyl, butyl, n-butyl, isobutyl, tert-butyl, sec-butyl, 1-methylbutyl, 1-ethylbutyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, cyclopentyl, cyclohexyl, vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, methoxy, ethoxy, propoxy, isobutoxy, sec-butoxy, pentyloxy, isopentyloxy, hexyloxy, silyl, trimethylsilyl, triethylsilyl, triphenylsilyl, trimethoxysilyl, dimethoxyphenylsilyl, diphenylmethylsilyl, diphenylvinylsilyl, methylcyclobutylsilyl, dimethylfurylsilylphenyl, biphenyl, terphenyl, naphthyl, anthracenyl, phenanthrenyl, pyrenyl, perylene, tetraphenyl, fluorenyl, acenaphathcenyl, triphenylene, fluoranthenyl, thienyl, furanyl, pyrrolyl, imidazolyl, azolyl, diazolyl, triazolyl, pyridyl, bipyridyl, pyrimidyl, triazinyl, triazolyl, acridinyl, pyridazinyl, pyrazinyl, quinolyl, quinazolinyl, quinoxalinyl, phthalazinyl, pyridopyrimidinyl, pyridopyrazinyl, pyrazinopyrazinyl, isoquinolyl, indolyl, carbazolyl, benzazolyl, benzimidazolyl, benzothiazolyl, benzocarbazolyl, benzothiophenyl, dibenzothiophenyl, benzofuranyl, dibenzofuranyl, phenanthrolinyl, thiazolyl, isoxazolyl, thiadiazolyl and phenothiazinyl, respectively.

For example, the structural formula of the organic electroluminescent material is as shown in one of formulas (A1) to (A6) and formulas (B1) to (B6):

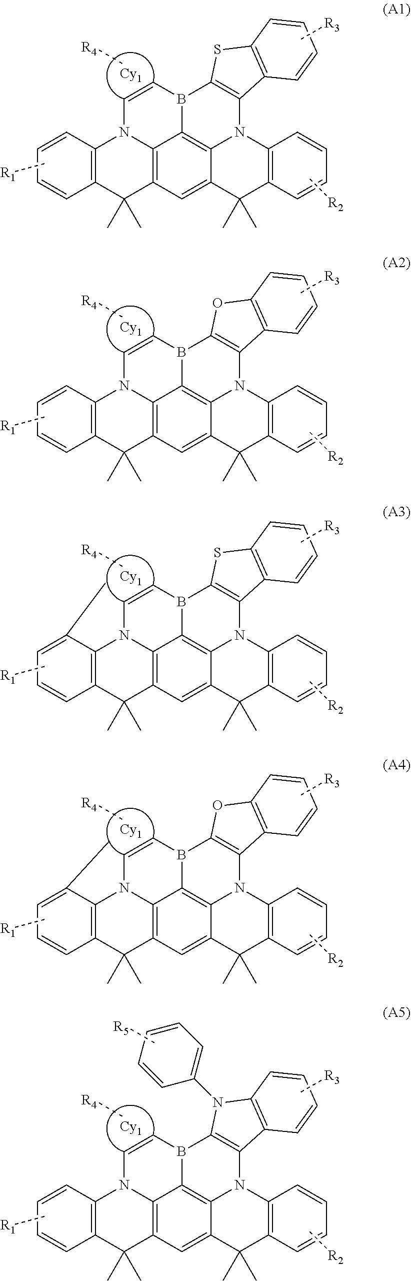

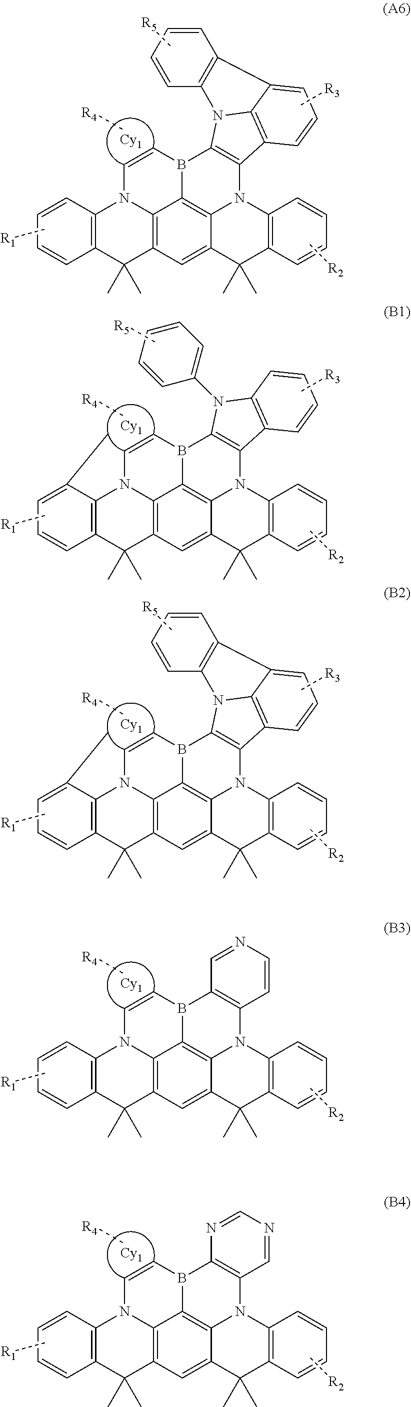

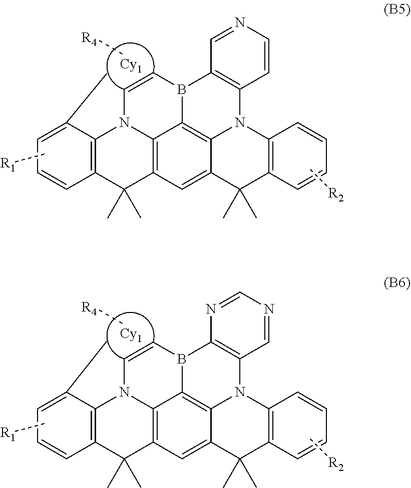

The definition of R₅ in the structural formulas (A1) to (A6) and (B1) to (B6) is the same as the definitions of R₁-R₄ in the structural formulas (A) and (B).

R₁ to R₅ each are independently selected from one of the group consisting of a hydrogen atom, a protium atom, a deuterium atom, a tritium atom, a fluorine atom, cyano, straight or branched C1-8 alkyl, C6-10 substituted or unsubstituted aryl, C5-20 substituted or unsubstituted heteroaryl, respectively, or R₁ to R₅ each are independently connected to an aromatic ring skeleton, respectively, to form a ring; a heteroatom in the heteroaryl group is selected from one or more of the group consisting of N, O, S or Se, and the substitution in the aryl or heteroaryl group is a substitution by C1-C4 alkyl.

R₁ to R₅ each are independently selected from the group consisting of a hydrogen atom, a deuterium atom, straight or branched C1-4 alkyl, phenyl, naphthyl, carbazole, indolocarbazole, indole (3,2,1-JK) carbazole, respectively, or R₁ to R₅ each are independently connected to an aromatic ring skeleton, respectively, to form a ring.

Cy1 is independently selected from an aryl group having 6-10 carbon atoms, or a substituted or unsubstituted heteroaryl group having 5-10 carbon atoms; a heteroatom is N, S, and Se under the condition of Cy1 being a heteroaryl group.

The structure of the organic electroluminescent material is represented by one of the following formulas:

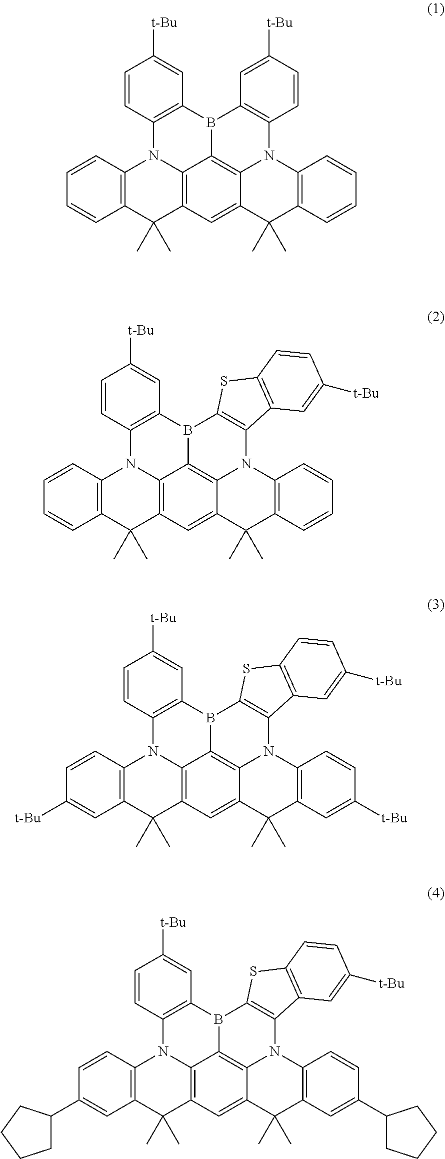 [SMILES: CC(C)(C)c1ccc2c(c1)B1c3cc(C(C)(C)C)ccc3N3c4ccccc4C(C)(C)c4cc5c(c1c43)N2c1ccccc1C5(C)C ; CC(C)(C)c1ccc2c(c1)B1c3sc4ccc(C(C)(C)C)cc4c3N3c4ccccc4C(C)(C)c4cc5c(c1c43)N2c1ccccc1C5(C)C ; CC(C)(C)c1ccc2c(c1)B1c3sc4ccc(C(C)(C)C)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3sc4ccc(C(C)(C)C)cc4c3N3c4ccc(C5CCCC5)cc4C(C)(C)c4cc5c(c1c43)N2c1ccc(C2CCCC2)cc1C5(C)C]

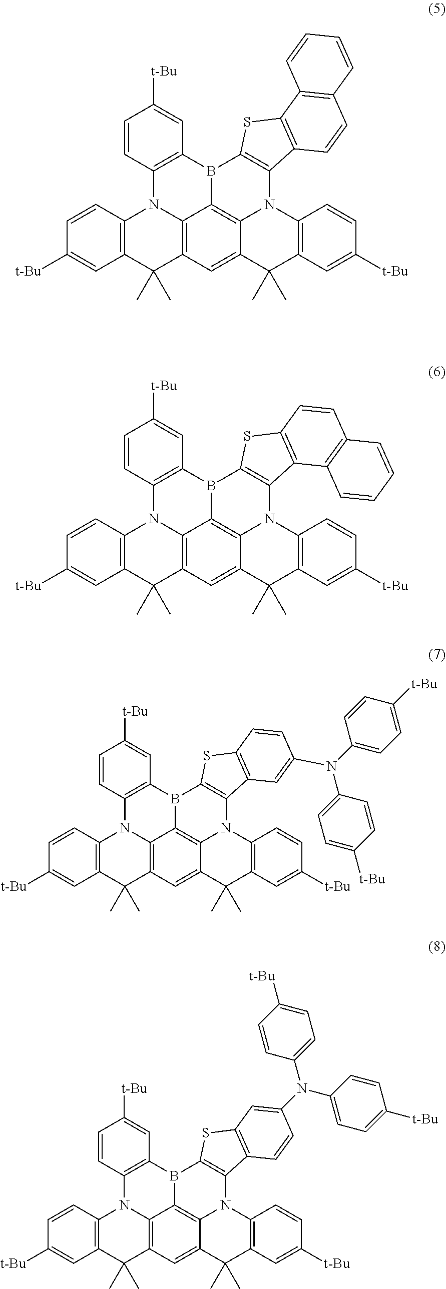

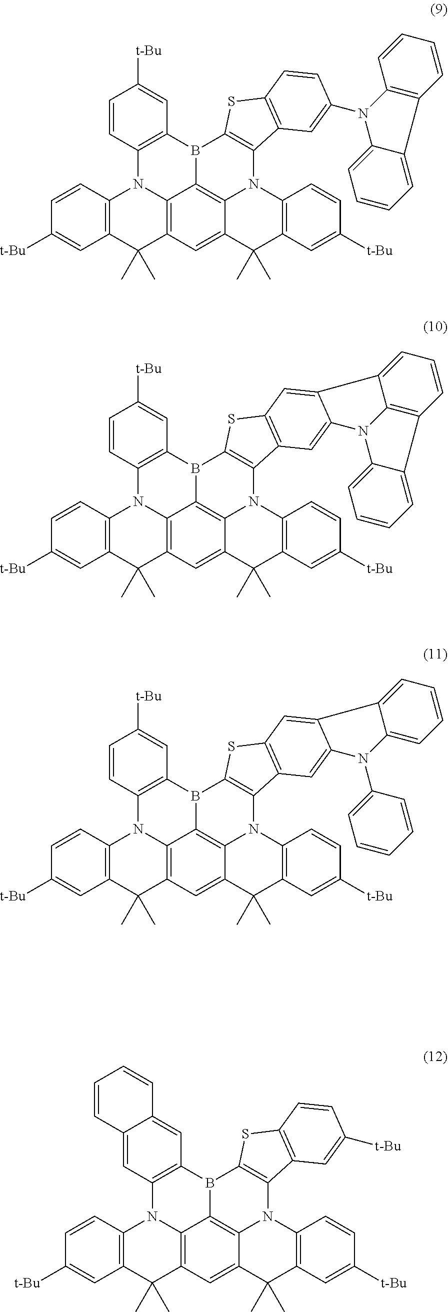 [SMILES: CC(C)(C)c1ccc2c(c1)B1c3sc4ccc(-n5c6ccccc6c6ccccc65)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3sc4cc5c6cccc7c8ccccc8n(c5cc4c3N3c4ccc(C(C)(C)C)cc4C(C)(C)c4cc5c(c1c43)N2c1ccc(C(C)(C)C)cc1C5(C)C)c76 ; CC(C)(C)c1ccc2c(c1)B1c3sc4cc5c6ccccc6n(-c6ccccc6)c5cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)C(C)(C)c1cc3c4c5c1N2c1cc2ccccc2cc1B5c1sc2ccc(C(C)(C)C)cc2c1N4c1ccc(C(C)(C)C)cc1C3(C)C]

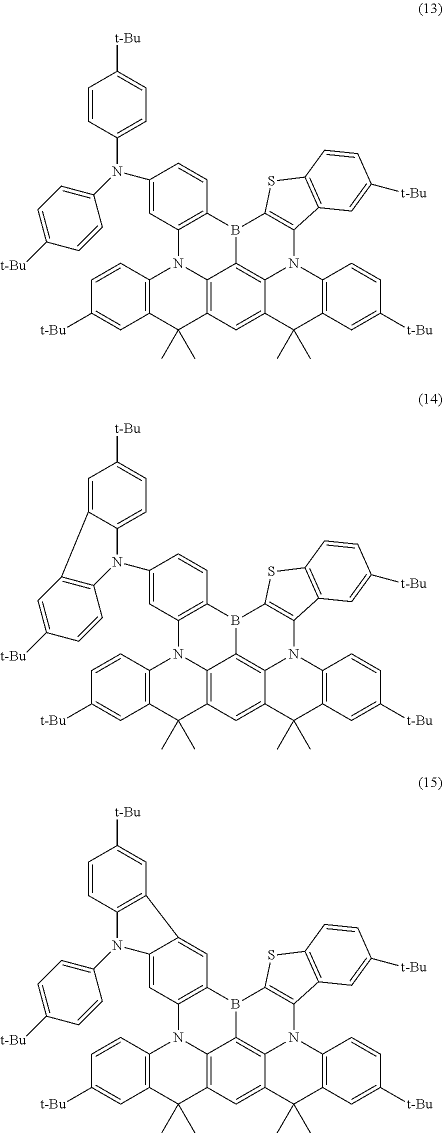 [SMILES: CC(C)(C)c1ccc(N(c2ccc(C(C)(C)C)cc2)c2ccc3c(c2)N2c4ccc(C(C)(C)C)cc4C(C)(C)c4cc5c6c(c42)B3c2sc3ccc(C(C)(C)C)cc3c2N6c2ccc(C(C)(C)C)cc2C5(C)C)cc1 ; CC(C)(C)c1ccc2c(c1)C(C)(C)c1cc3c4c5c1N2c1cc(-n2c6ccc(C(C)(C)C)cc6c6cc(C(C)(C)C)ccc62)ccc1B5c1sc2ccc(C(C)(C)C)cc2c1N4c1ccc(C(C)(C)C)cc1C3(C)C ; CC(C)(C)c1ccc(-n2c3ccc(C(C)(C)C)cc3c3cc4c(cc32)N2c3ccc(C(C)(C)C)cc3C(C)(C)c3cc5c6c(c32)B4c2sc3ccc(C(C)(C)C)cc3c2N6c2ccc(C(C)(C)C)cc2C5(C)C)cc1]

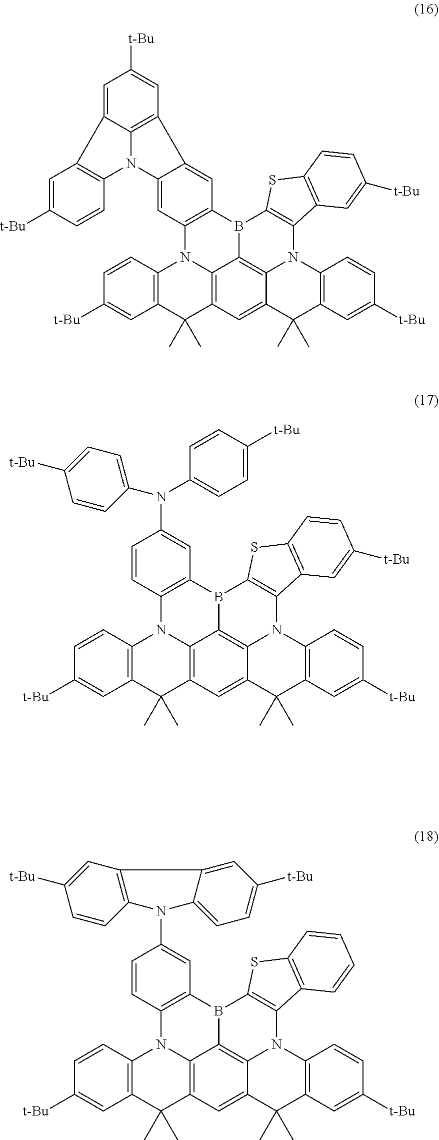 [SMILES: CC(C)(C)c1ccc2c(c1)C(C)(C)c1cc3c4c5c1N2c1cc2c(cc1B5c1sc5ccc(C(C)(C)C)cc5c1N4c1ccc(C(C)(C)C)cc1C3(C)C)c1cc(C(C)(C)C)cc3c4cc(C(C)(C)C)ccc4n2c31 ; CC(C)(C)c1ccc(N(c2ccc(C(C)(C)C)cc2)c2ccc3c(c2)B2c4sc5ccc(C(C)(C)C)cc5c4N4c5ccc(C(C)(C)C)cc5C(C)(C)c5cc6c(c2c54)N3c2ccc(C(C)(C)C)cc2C6(C)C)cc1 ; CC(C)(C)c1ccc2c(c1)C(C)(C)c1cc3c4c5c1N2c1ccc(-n2c6ccc(C(C)(C)C)cc6c6cc(C(C)(C)C)ccc62)cc1B5c1sc2ccccc2c1N4c1ccc(C(C)(C)C)cc1C3(C)C]

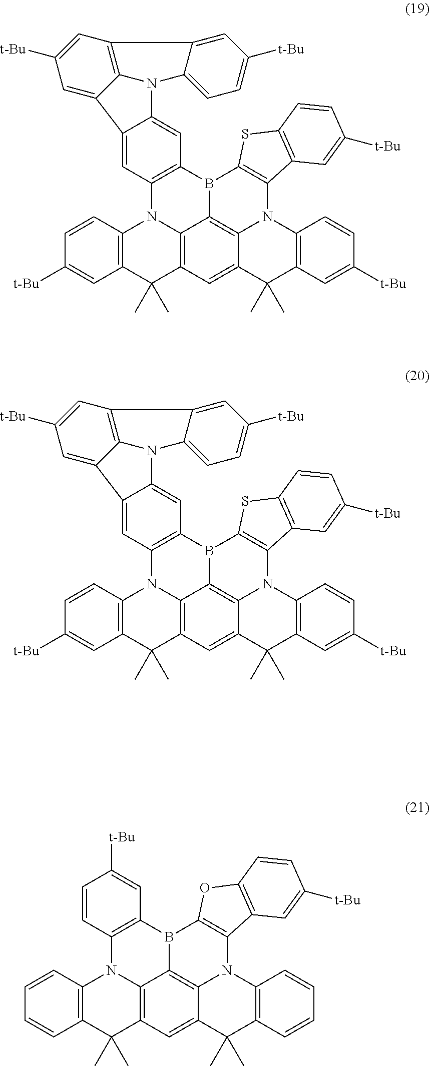 [SMILES: CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1sc2ccc(C(C)(C)C)cc2c1N4c1ccc(C(C)(C)C)cc1C3(C)C)c76 ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1sc2ccc(C(C)(C)C)cc2c1N4c1ccc(C(C)(C)C)cc1C3(C)C)c76 ; CC(C)(C)c1ccc2c(c1)B1c3oc4ccc(C(C)(C)C)cc4c3N3c4ccccc4C(C)(C)c4cc5c(c1c43)N2c1ccccc1C5(C)C]

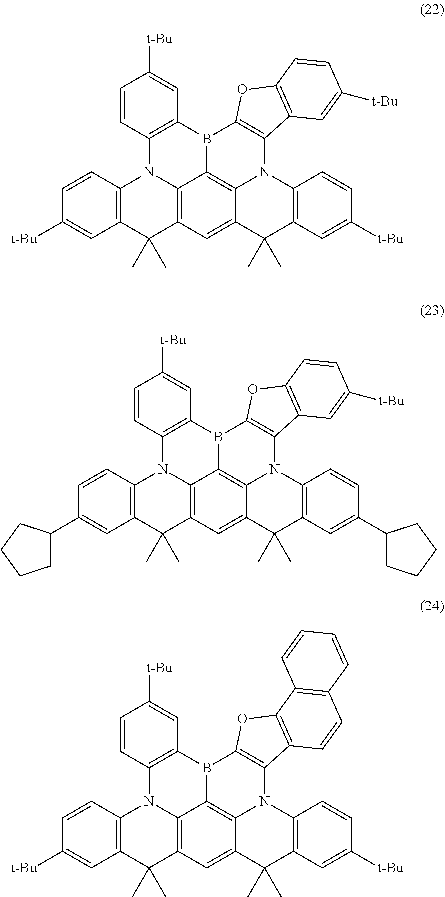 [SMILES: CC(C)(C)c1ccc2c(c1)B1c3oc4ccc(C(C)(C)C)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3oc4ccc(C(C)(C)C)cc4c3N3c4ccc(C5CCCC5)cc4C(C)(C)c4cc5c(c1c43)N2c1ccc(C2CCCC2)cc1C5(C)C ; CC(C)(C)c1ccc2c(c1)B1c3oc4c(ccc5ccccc54)c3N3c4ccc(C(C)(C)C)cc4C(C)(C)c4cc5c(c1c43)N2c1ccc(C(C)(C)C)cc1C5(C)C]

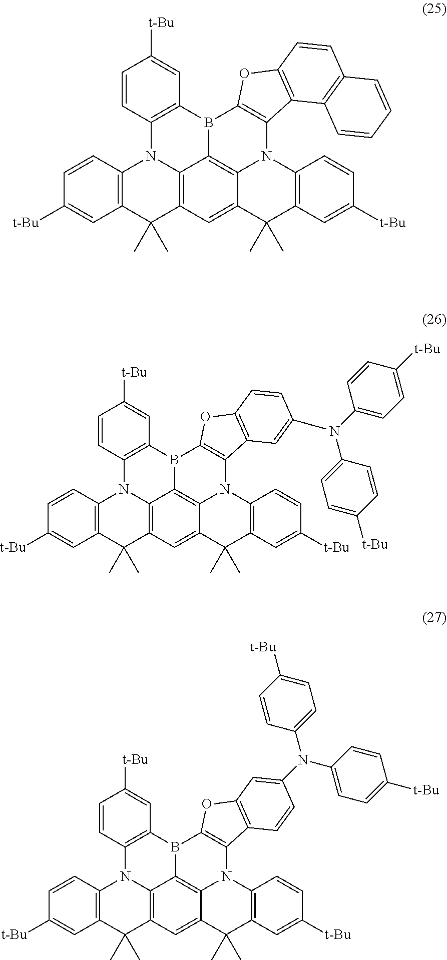 [SMILES: CC(C)(C)c1ccc2c(c1)B1c3oc4ccc5ccccc5c4c3N3c4ccc(C(C)(C)C)cc4C(C)(C)c4cc5c(c1c43)N2c1ccc(C(C)(C)C)cc1C5(C)C ; CC(C)(C)c1ccc(N(c2ccc(C(C)(C)C)cc2)c2ccc3oc4c(c3c2)N2c3ccc(C(C)(C)C)cc3C(C)(C)c3cc5c6c(c32)B4c2cc(C(C)(C)C)ccc2N6c2ccc(C(C)(C)C)cc2C5(C)C)cc1 ; CC(C)(C)c1ccc(N(c2ccc(C(C)(C)C)cc2)c2ccc3c4c(oc3c2)B2c3cc(C(C)(C)C)ccc3N3c5ccc(C(C)(C)C)cc5C(C)(C)c5cc6c(c2c53)N4c2ccc(C(C)(C)C)cc2C6(C)C)cc1]

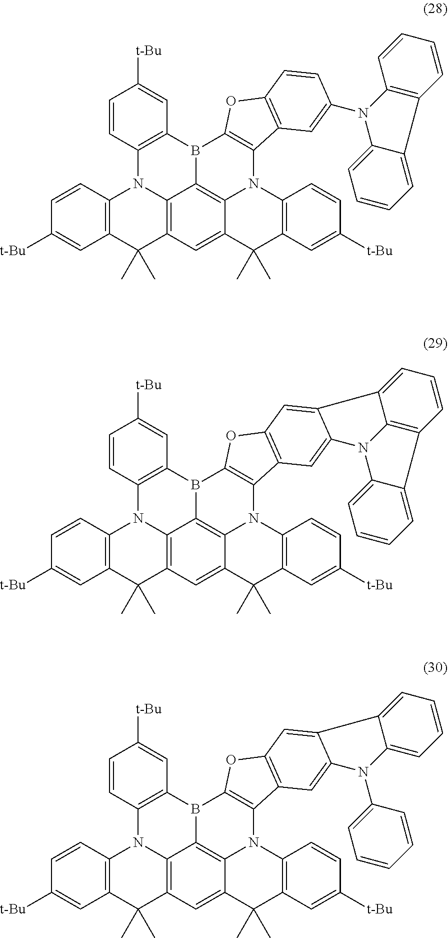 [SMILES: CC(C)(C)c1ccc2c(c1)B1c3oc4ccc(-n5c6ccccc6c6ccccc65)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3oc4cc5c6cccc7c8ccccc8n(c5cc4c3N3c4ccc(C(C)(C)C)cc4C(C)(C)c4cc5c(c1c43)N2c1ccc(C(C)(C)C)cc1C5(C)C)c76 ; CC(C)(C)c1ccc2c(c1)B1c3oc4cc5c6ccccc6n(-c6ccccc6)c5cc4c3N3c4ccc(C(C)(C)C)cc4C(C)(C)c4cc5c(c1c43)N2c1ccc(C(C)(C)C)cc1C5(C)C]

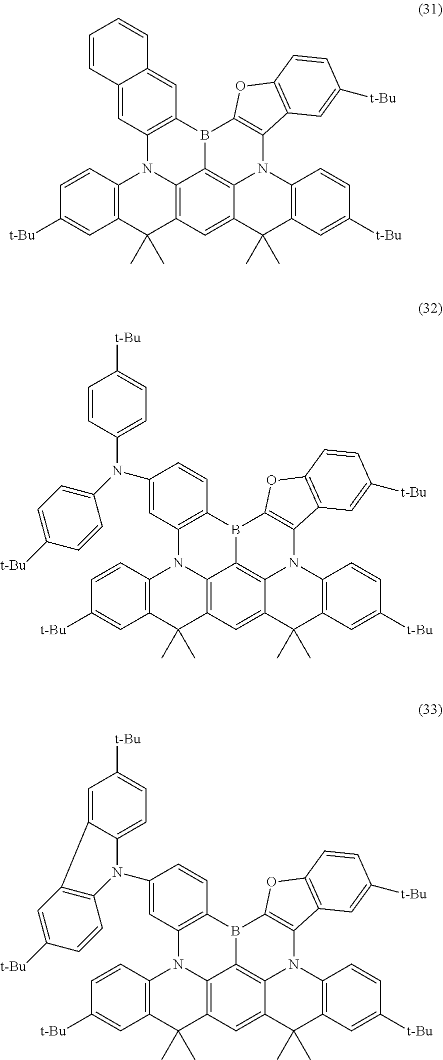 [SMILES: CC(C)(C)c1ccc2c(c1)C(C)(C)c1cc3c4c5c1N2c1cc2ccccc2cc1B5c1oc2ccc(C(C)(C)C)cc2c1N4c1ccc(C(C)(C)C)cc1C3(C)C ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2oc3ccc(C(C)(C)C)cc3c2N6c2ccc(C(C)(C)C)cc2C5(C)C)cc1 ; CC(C)(C)c1ccc2c(c1)C(C)(C)c1cc3c4c5c1N2c1cc(-n2c6ccc(C(C)(C)C)cc6c6cc(C(C)(C)C)ccc62)ccc1B5c1oc2ccc(C(C)(C)C)cc2c1N4c1ccc(C(C)(C)C)cc1C3(C)C]

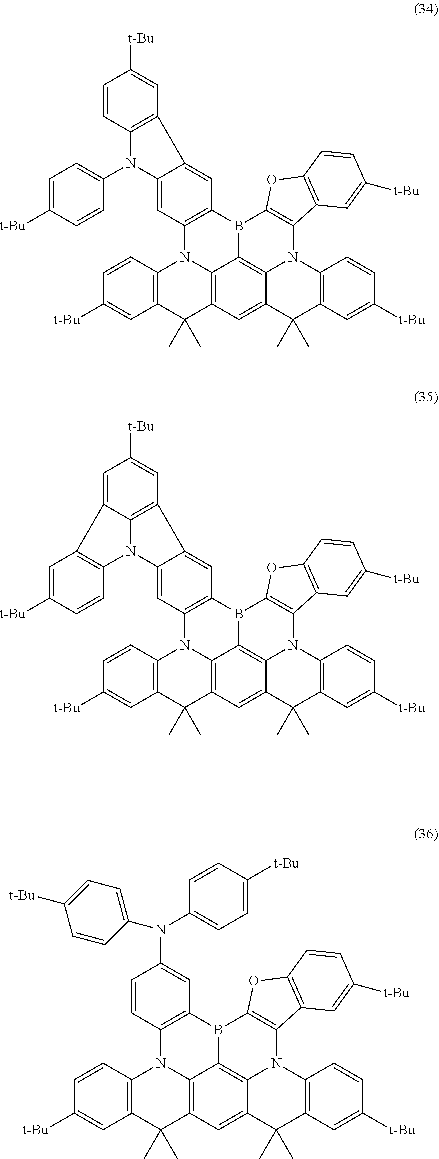 [SMILES: CC(C)(C)c1ccc(-n2c3ccc(C(C)(C)C)cc3c3cc4c(cc32)N2c3ccc(C(C)(C)C)cc3C(C)(C)c3cc5c6c(c32)B4c2oc3ccc(C(C)(C)C)cc3c2N6c2ccc(C(C)(C)C)cc2C5(C)C)cc1 ; CC(C)(C)c1ccc2c(c1)C(C)(C)c1cc3c4c5c1N2c1cc2c(cc1B5c1oc5ccc(C(C)(C)C)cc5c1N4c1ccc(C(C)(C)C)cc1C3(C)C)c1cc(C(C)(C)C)cc3c4cc(C(C)(C)C)ccc4n2c31 ; CC(C)(C)c1ccc(N(c2ccc(C(C)(C)C)cc2)c2ccc3c(c2)B2c4oc5ccc(C(C)(C)C)cc5c4N4c5ccc(C(C)(C)C)cc5C(C)(C)c5cc6c(c2c54)N3c2ccc(C(C)(C)C)cc2C6(C)C)cc1]

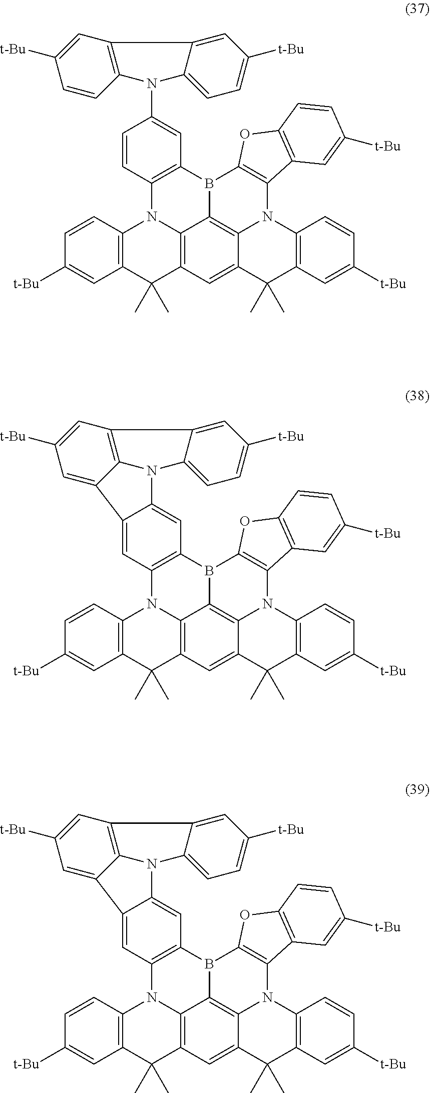 [SMILES: CC(C)(C)c1ccc2c(c1)C(C)(C)c1cc3c4c5c1N2c1ccc(-n2c6ccc(C(C)(C)C)cc6c6cc(C(C)(C)C)ccc62)cc1B5c1oc2ccc(C(C)(C)C)cc2c1N4c1ccc(C(C)(C)C)cc1C3(C)C ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1oc2ccc(C(C)(C)C)cc2c1N4c1ccc(C(C)(C)C)cc1C3(C)C)c76 ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1oc2ccc(C(C)(C)C)cc2c1N4c1ccc(C(C)(C)C)cc1C3(C)C)c76]

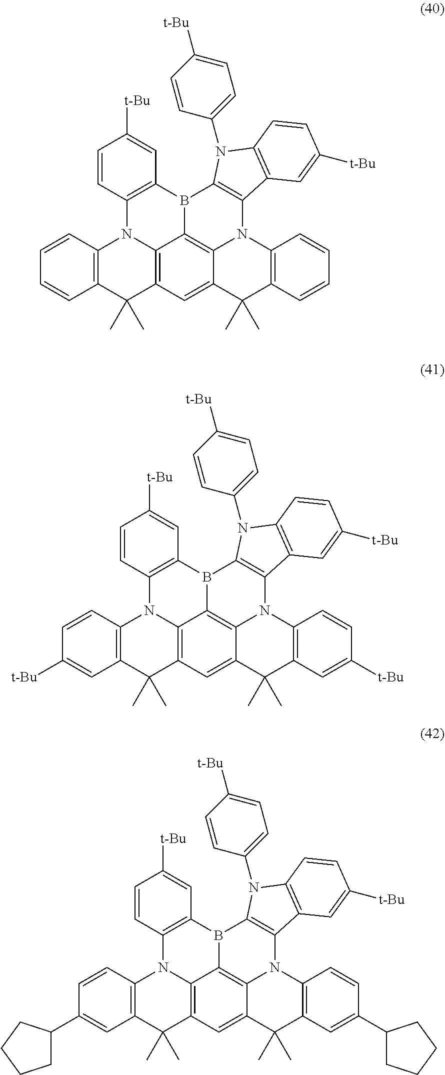 [SMILES: CC(C)(C)c1ccc(-n2c3c(c4cc(C(C)(C)C)ccc42)N2c4ccccc4C(C)(C)c4cc5c6c(c42)B3c2cc(C(C)(C)C)ccc2N6c2ccccc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4cc(C(C)(C)C)ccc42)N2c4ccc(C5CCCC5)cc4C(C)(C)c4cc5c6c(c42)B3c2cc(C(C)(C)C)ccc2N6c2ccc(C3CCCC3)cc2C5(C)C)cc1]

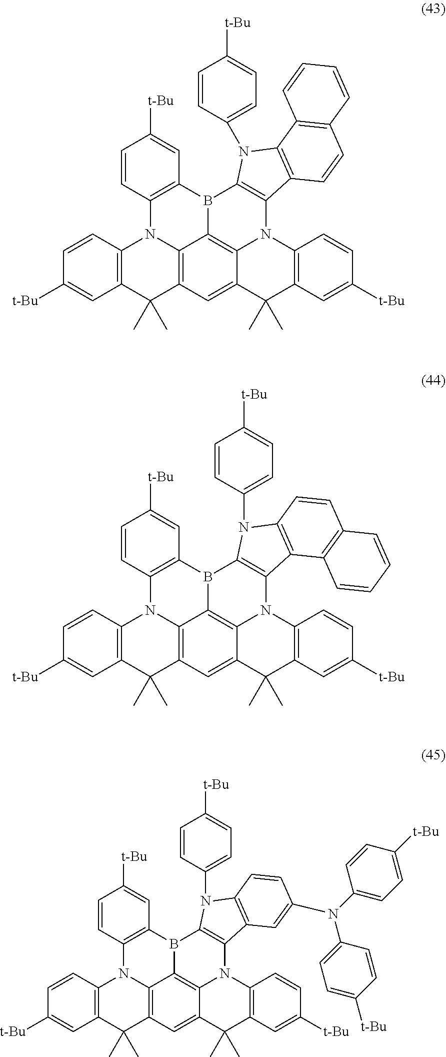 [SMILES: CC(C)(C)c1ccc(-n2c3c(c4ccc5ccccc5c42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4c5ccccc5ccc42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(N(c2ccc(C(C)(C)C)cc2)c2ccc3c(c2)c2c(n3-c3ccc(C(C)(C)C)cc3)B3c4cc(C(C)(C)C)ccc4N4c5ccc(C(C)(C)C)cc5C(C)(C)c5cc6c(c3c54)N2c2ccc(C(C)(C)C)cc2C6(C)C)cc1]

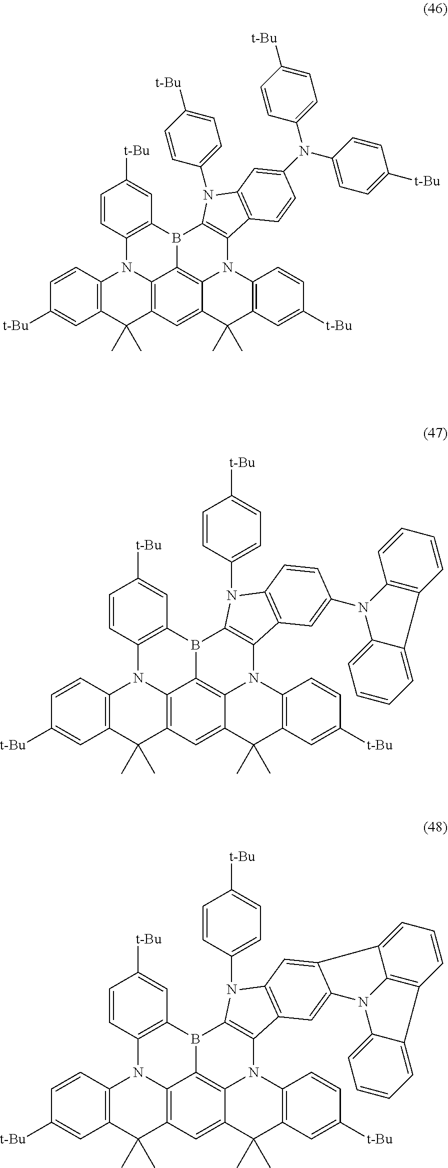 [SMILES: CC(C)(C)c1ccc(N(c2ccc(C(C)(C)C)cc2)c2ccc3c4c(n(-c5ccc(C(C)(C)C)cc5)c3c2)B2c3cc(C(C)(C)C)ccc3N3c5ccc(C(C)(C)C)cc5C(C)(C)c5cc6c(c2c53)N4c2ccc(C(C)(C)C)cc2C6(C)C)cc1 ; CC(C)(C)c1ccc(-n2c3c(c4cc(-n5c6ccccc6c6ccccc65)ccc42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4cc5c(cc42)c2cccc4c6ccccc6n5c42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1]

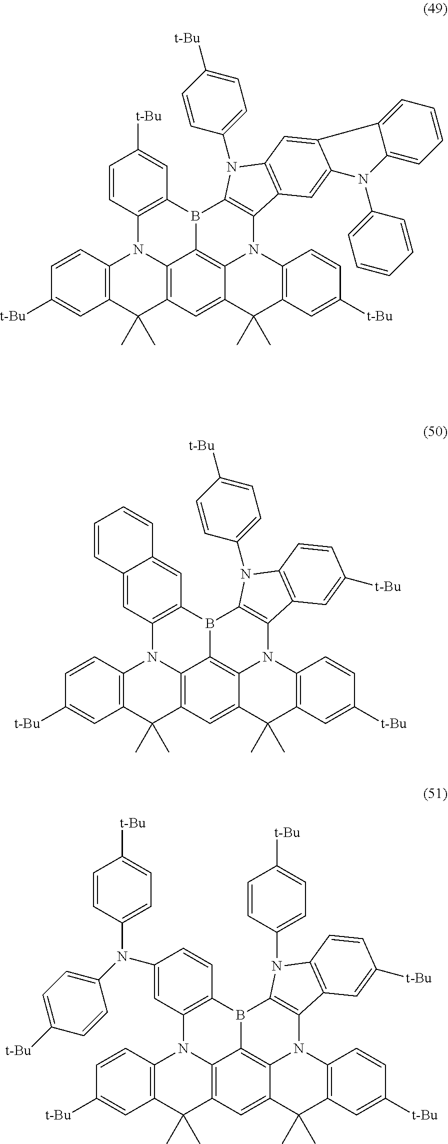 [SMILES: CC(C)(C)c1ccc(-n2c3c(c4cc5c(cc42)c2ccccc2n5-c2ccccc2)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc3ccccc3cc2N6c2ccc(C(C)(C)C)cc2C5(C)C)cc1 ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2c(c3cc(C(C)(C)C)ccc3n2-c2ccc(C(C)(C)C)cc2)N6c2ccc(C(C)(C)C)cc2C5(C)C)cc1]

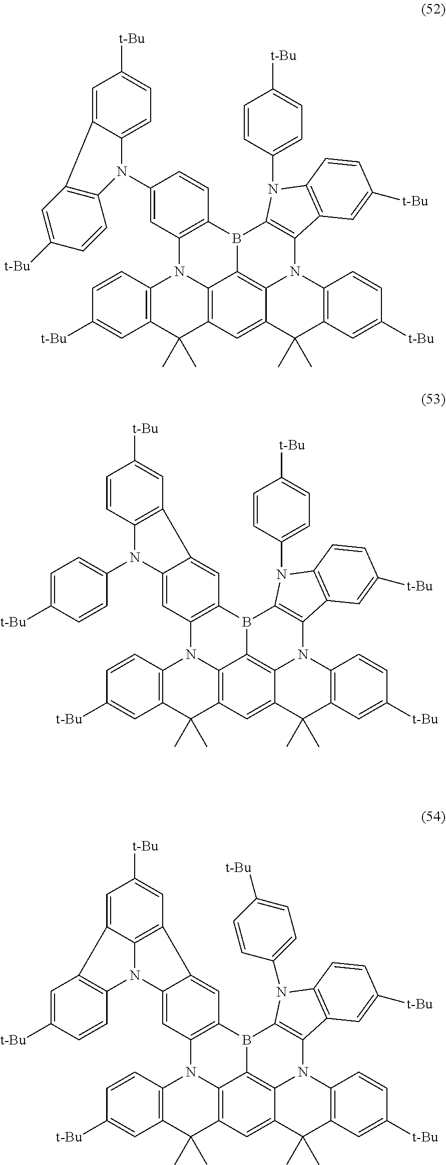 [SMILES: CC(C)(C)c1ccc(-n2c3c(c4cc(C(C)(C)C)ccc42)N2c4ccc(C(C)(C)C)cc4C(C)(C)c4cc5c6c(c42)B3c2ccc(-n3c4ccc(C(C)(C)C)cc4c4cc(C(C)(C)C)ccc43)cc2N6c2ccc(C(C)(C)C)cc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc3c4cc(C(C)(C)C)ccc4n(-c4ccc(C(C)(C)C)cc4)c3cc2N6c2ccc(C(C)(C)C)cc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc3c4cc(C(C)(C)C)cc7c8cc(C(C)(C)C)ccc8n(c3cc2N6c2ccc(C(C)(C)C)cc2C5(C)C)c74)cc1]

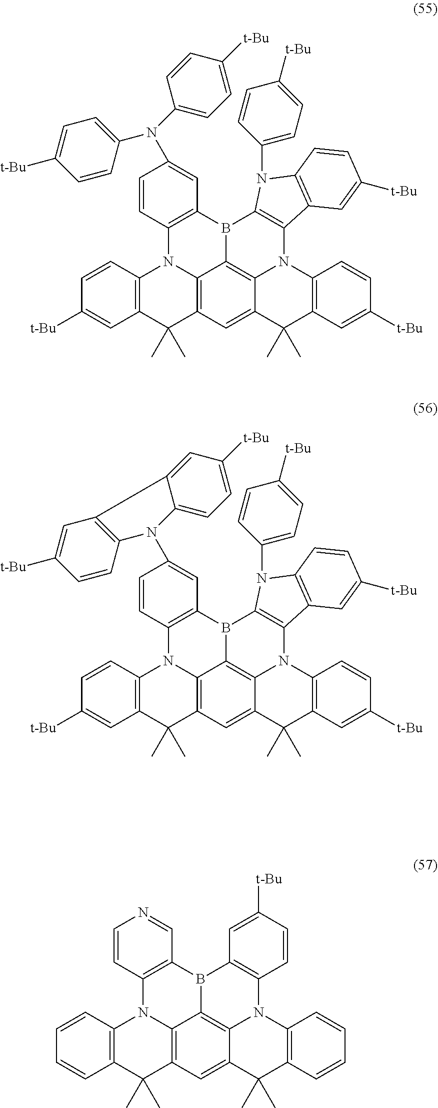 [SMILES: CC(C)(C)c1ccc(N(c2ccc(C(C)(C)C)cc2)c2ccc3c(c2)B2c4c5c(cc6c4N(c4ccc(C(C)(C)C)cc4C6(C)C)c4c2n(-c2ccc(C(C)(C)C)cc2)c2ccc(C(C)(C)C)cc42)C(C)(C)c2cc(C(C)(C)C)ccc2N35)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc(-n3c4ccc(C(C)(C)C)cc4c4cc(C(C)(C)C)ccc43)ccc2N6c2ccc(C(C)(C)C)cc2C5(C)C)cc1 ; CC(C)(C)c1ccc2c(c1)B1c3cnccc3N3c4ccccc4C(C)(C)c4cc5c(c1c43)N2c1ccccc1C5(C)C]

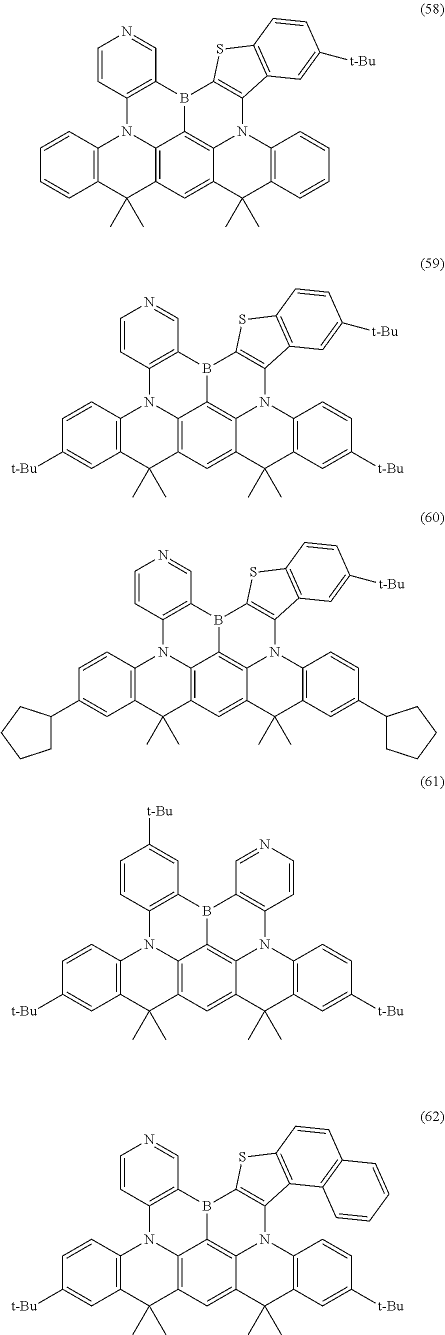 [SMILES: CC(C)(C)c1ccc2sc3c(c2c1)N1c2ccccc2C(C)(C)c2cc4c5c(c21)B3c1cnccc1N5c1ccccc1C4(C)C ; CC(C)(C)c1ccc2c(c1)C(C)(C)c1cc3c4c5c1N2c1ccncc1B5c1sc2ccc(C(C)(C)C)cc2c1N4c1ccc(C(C)(C)C)cc1C3(C)C ; CC(C)(C)c1ccc2sc3c(c2c1)N1c2ccc(C4CCCC4)cc2C(C)(C)c2cc4c5c(c21)B3c1cnccc1N5c1ccc(C2CCCC2)cc1C4(C)C ; CC(C)(C)c1ccc2c(c1)B1c3cnccc3N3c4ccc(C(C)(C)C)cc4C(C)(C)c4cc5c(c1c43)N2c1ccc(C(C)(C)C)cc1C5(C)C ; CC(C)(C)c1ccc2c(c1)C(C)(C)c1cc3c4c5c1N2c1ccncc1B5c1sc2ccc5ccccc5c2c1N4c1ccc(C(C)(C)C)cc1C3(C)C]

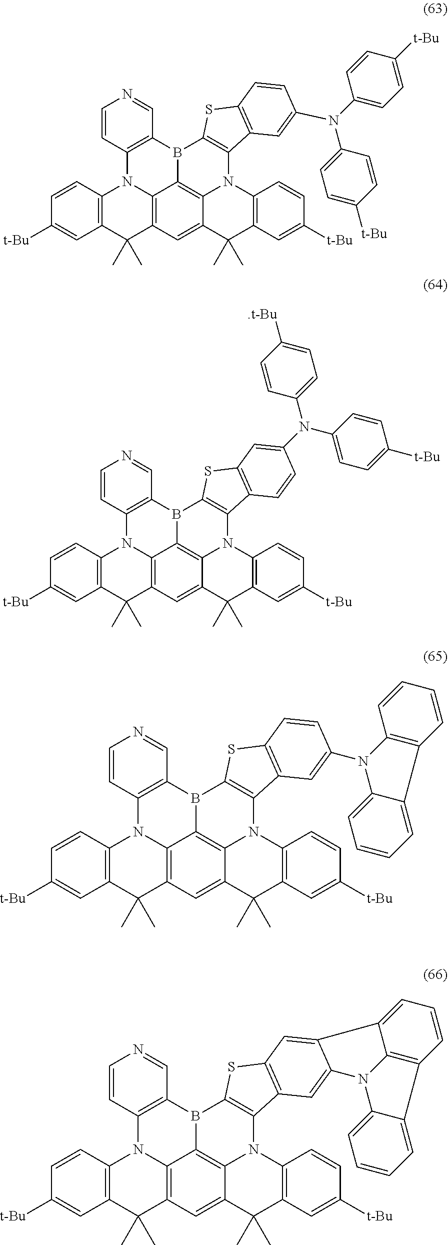

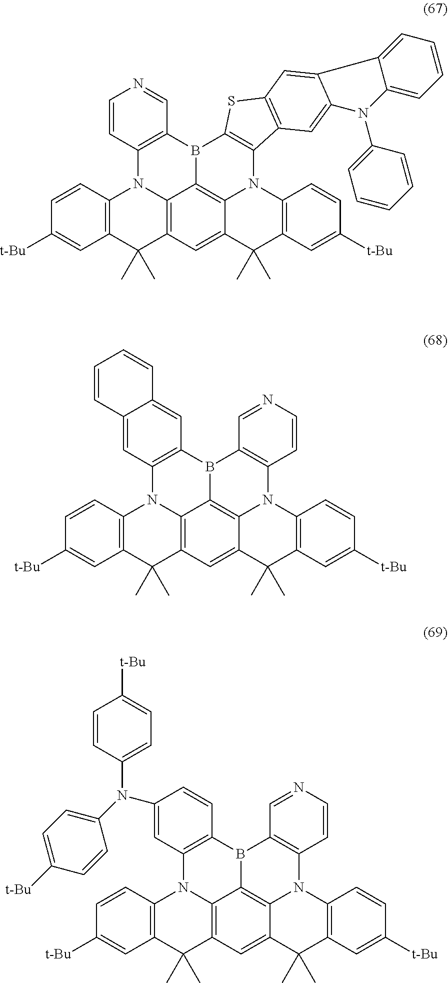 [SMILES: CC(C)(C)c1ccc2c(c1)C(C)(C)c1cc3c4c5c1N2c1ccncc1B5c1sc2cc5c6ccccc6n(-c6ccccc6)c5cc2c1N4c1ccc(C(C)(C)C)cc1C3(C)C ; CC(C)(C)c1ccc2c(c1)C(C)(C)c1cc3c4c5c1N2c1ccncc1B5c1cc2ccccc2cc1N4c1ccc(C(C)(C)C)cc1C3(C)C ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2cnccc2N6c2ccc(C(C)(C)C)cc2C5(C)C)cc1]

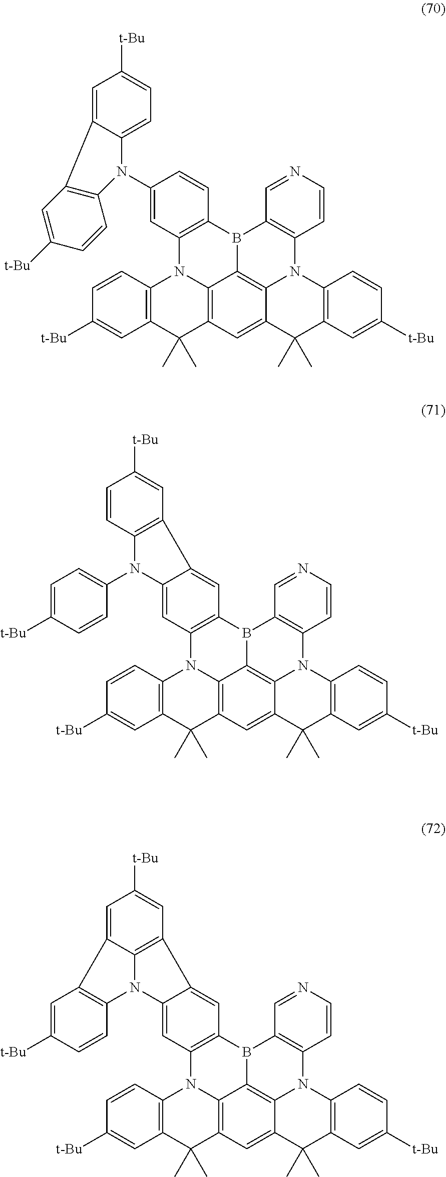 [SMILES: CC(C)(C)c1ccc2c(c1)C(C)(C)c1cc3c4c5c1N2c1ccncc1B5c1ccc(-n2c5ccc(C(C)(C)C)cc5c5cc(C(C)(C)C)ccc52)cc1N4c1ccc(C(C)(C)C)cc1C3(C)C ; CC(C)(C)c1ccc(-n2c3ccc(C(C)(C)C)cc3c3cc4c(cc32)N2c3ccc(C(C)(C)C)cc3C(C)(C)c3cc5c6c(c32)B4c2cnccc2N6c2ccc(C(C)(C)C)cc2C5(C)C)cc1 ; CC(C)(C)c1ccc2c(c1)C(C)(C)c1cc3c4c5c1N2c1ccncc1B5c1cc2c5cc(C(C)(C)C)cc6c7cc(C(C)(C)C)ccc7n(c2cc1N4c1ccc(C(C)(C)C)cc1C3(C)C)c65]

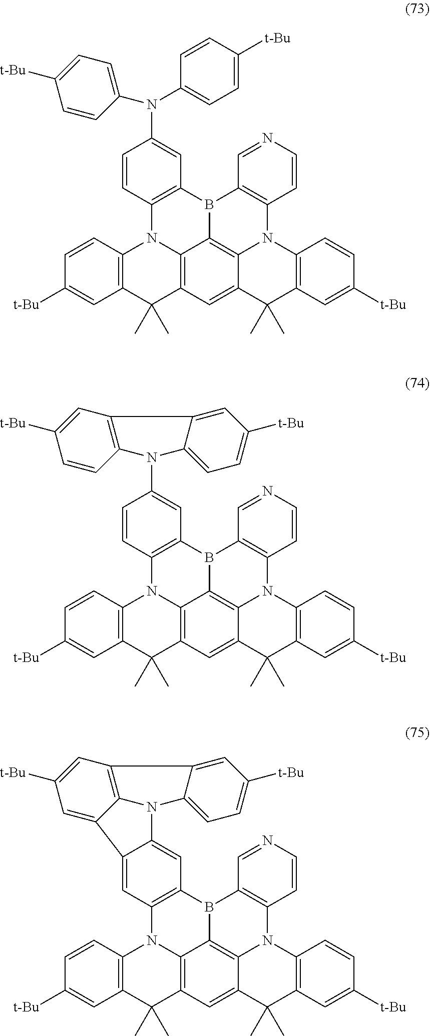 [SMILES: CC(C)(C)c1ccc(N(c2ccc(C(C)(C)C)cc2)c2ccc3c(c2)B2c4cnccc4N4c5ccc(C(C)(C)C)cc5C(C)(C)c5cc6c(c2c54)N3c2ccc(C(C)(C)C)cc2C6(C)C)cc1 ; CC(C)(C)c1ccc2c(c1)C(C)(C)c1cc3c4c5c1N2c1ccncc1B5c1cc(-n2c5ccc(C(C)(C)C)cc5c5cc(C(C)(C)C)ccc52)ccc1N4c1ccc(C(C)(C)C)cc1C3(C)C ; CC(C)(C)c1ccc2c(c1)C(C)(C)c1cc3c4c5c1N2c1ccncc1B5c1cc2c(cc1N4c1ccc(C(C)(C)C)cc1C3(C)C)c1cc(C(C)(C)C)cc3c4cc(C(C)(C)C)ccc4n2c31]

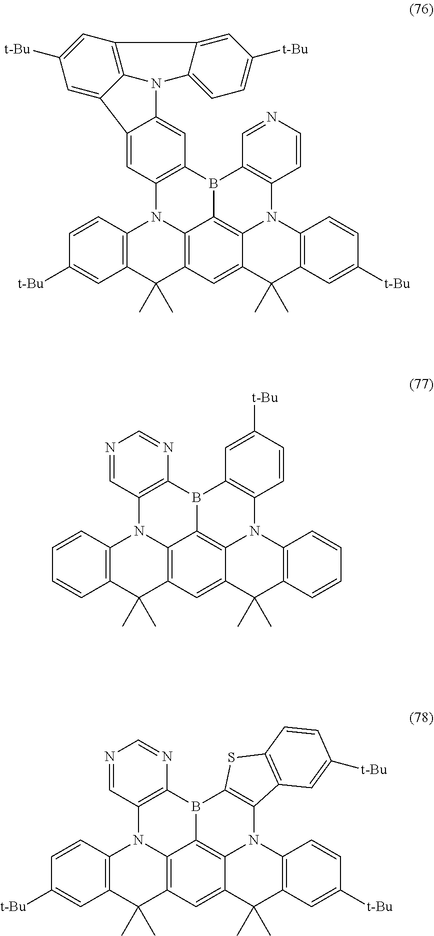 [SMILES: CC(C)(C)c1ccc2c(c1)C(C)(C)c1cc3c4c5c1N2c1ccncc1B5c1cc2c(cc1N4c1ccc(C(C)(C)C)cc1C3(C)C)c1cc(C(C)(C)C)cc3c4cc(C(C)(C)C)ccc4n2c31 ; CC(C)(C)c1ccc2c(c1)B1c3ncncc3N3c4ccccc4C(C)(C)c4cc5c(c1c43)N2c1ccccc1C5(C)C ; CC(C)(C)c1ccc2c(c1)C(C)(C)c1cc3c4c5c1N2c1cncnc1B5c1sc2ccc(C(C)(C)C)cc2c1N4c1ccc(C(C)(C)C)cc1C3(C)C]

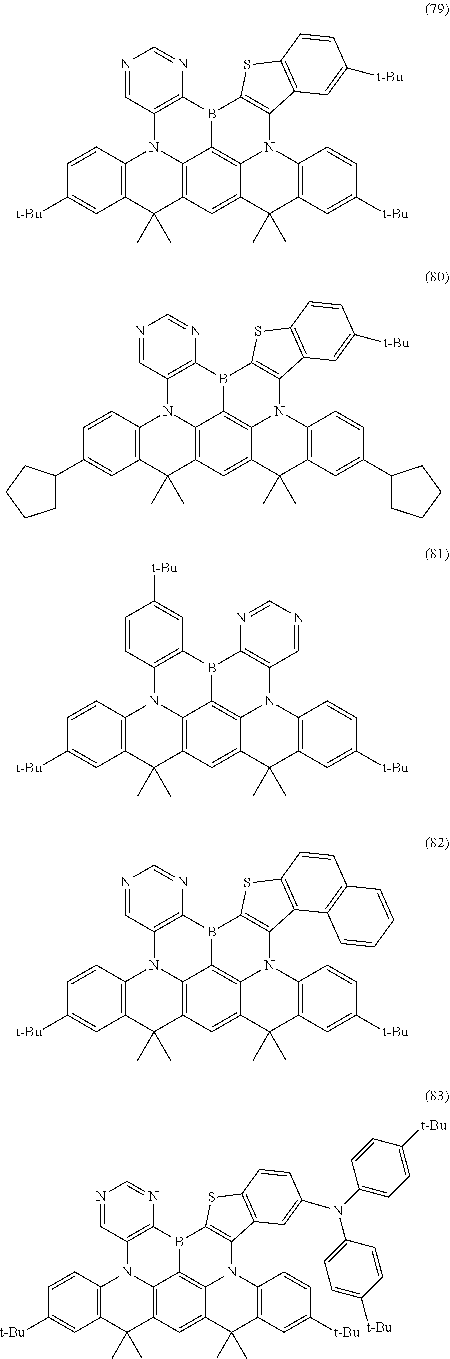

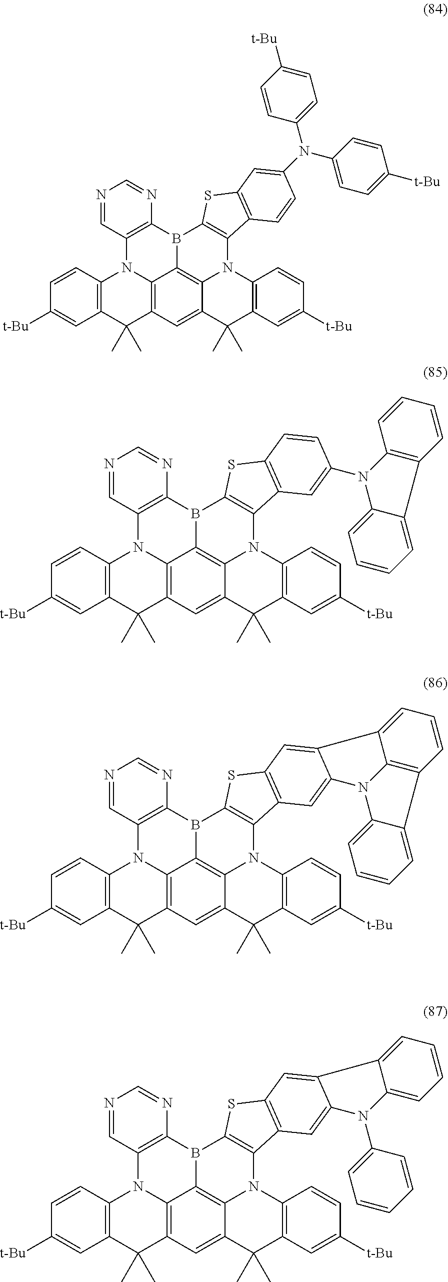 [SMILES: CC(C)(C)c1ccc(N(c2ccc(C(C)(C)C)cc2)c2ccc3c4c(sc3c2)B2c3ncncc3N3c5ccc(C(C)(C)C)cc5C(C)(C)c5cc6c(c2c53)N4c2ccc(C(C)(C)C)cc2C6(C)C)cc1 ; CC(C)(C)c1ccc2c(c1)C(C)(C)c1cc3c4c5c1N2c1cncnc1B5c1sc2ccc(-n5c6ccccc6c6ccccc65)cc2c1N4c1ccc(C(C)(C)C)cc1C3(C)C ; CC(C)(C)c1ccc2c(c1)C(C)(C)c1cc3c4c5c1N2c1cncnc1B5c1sc2cc5c6cccc7c8ccccc8n(c5cc2c1N4c1ccc(C(C)(C)C)cc1C3(C)C)c76 ; CC(C)(C)c1ccc2c(c1)C(C)(C)c1cc3c4c5c1N2c1cncnc1B5c1sc2cc5c6ccccc6n(-c6ccccc6)c5cc2c1N4c1ccc(C(C)(C)C)cc1C3(C)C]

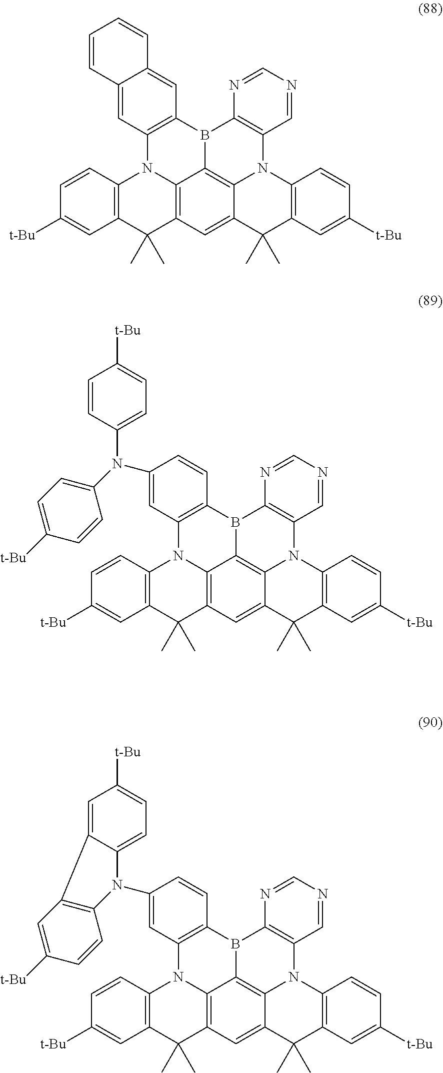 [SMILES: CC(C)(C)c1ccc2c(c1)C(C)(C)c1cc3c4c5c1N2c1cc2ccccc2cc1B5c1ncncc1N4c1ccc(C(C)(C)C)cc1C3(C)C ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2ncncc2N6c2ccc(C(C)(C)C)cc2C5(C)C)cc1 ; CC(C)(C)c1ccc2c(c1)C(C)(C)c1cc3c4c5c1N2c1cc(-n2c6ccc(C(C)(C)C)cc6c6cc(C(C)(C)C)ccc62)ccc1B5c1ncncc1N4c1ccc(C(C)(C)C)cc1C3(C)C]

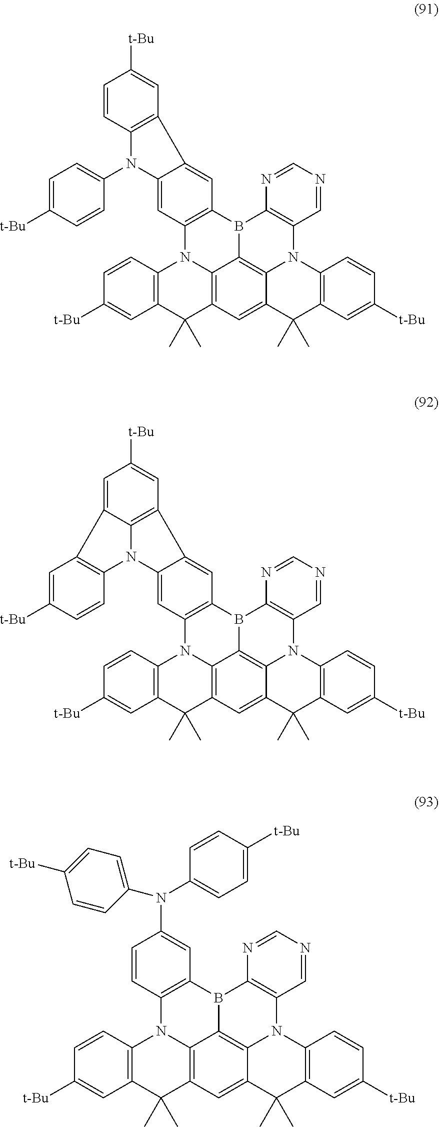 [SMILES: CC(C)(C)c1ccc(-n2c3ccc(C(C)(C)C)cc3c3cc4c(cc32)N2c3ccc(C(C)(C)C)cc3C(C)(C)c3cc5c6c(c32)B4c2ncncc2N6c2ccc(C(C)(C)C)cc2C5(C)C)cc1 ; CC(C)(C)c1ccc2c(c1)C(C)(C)c1cc3c4c5c1N2c1cc2c(cc1B5c1ncncc1N4c1ccc(C(C)(C)C)cc1C3(C)C)c1cc(C(C)(C)C)cc3c4cc(C(C)(C)C)ccc4n2c31 ; CC(C)(C)c1ccc(N(c2ccc(C(C)(C)C)cc2)c2ccc3c(c2)B2c4ncncc4N4c5ccc(C(C)(C)C)cc5C(C)(C)c5cc6c(c2c54)N3c2ccc(C(C)(C)C)cc2C6(C)C)cc1]

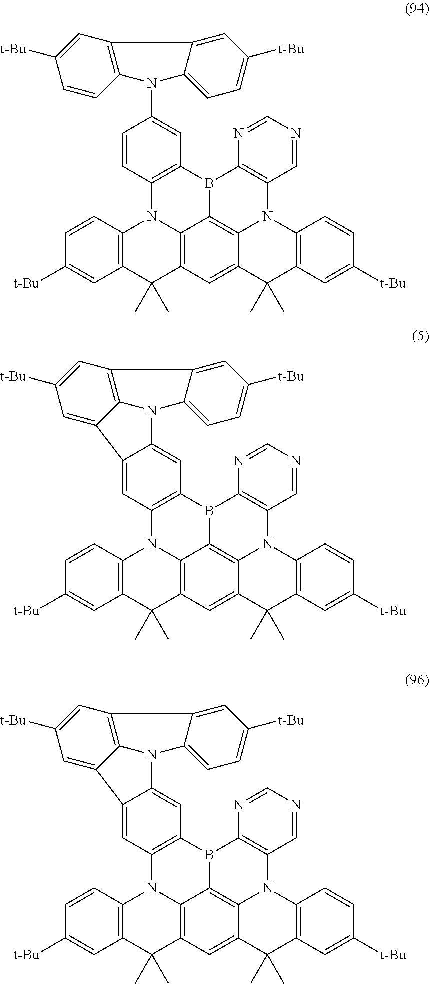 [SMILES: CC(C)(C)c1ccc2c(c1)C(C)(C)c1cc3c4c5c1N2c1ccc(-n2c6ccc(C(C)(C)C)cc6c6cc(C(C)(C)C)ccc62)cc1B5c1ncncc1N4c1ccc(C(C)(C)C)cc1C3(C)C ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1ncncc1N4c1ccc(C(C)(C)C)cc1C3(C)C)c76 ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1ncncc1N4c1ccc(C(C)(C)C)cc1C3(C)C)c76]

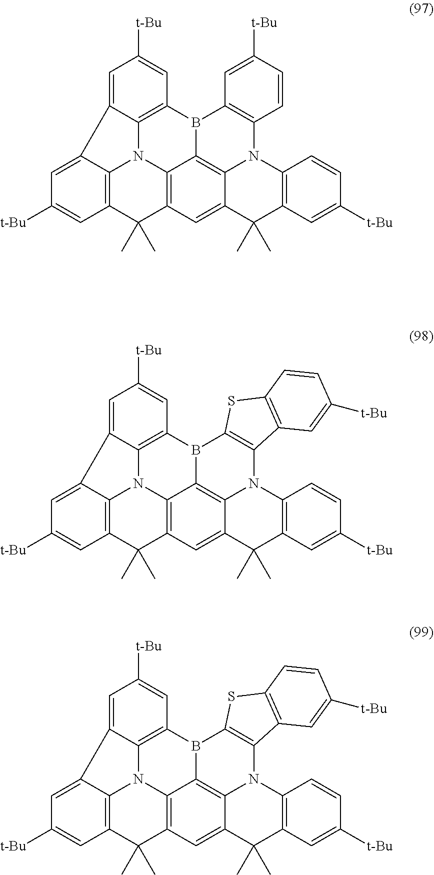 [SMILES: CC(C)(C)c1ccc2c(c1)B1c3c4c(cc5c3-n3c6c1cc(C(C)(C)C)cc6c1cc(C(C)(C)C)cc(c13)C5(C)C)C(C)(C)c1cc(C(C)(C)C)ccc1N24 ; CC(C)(C)c1ccc2c(c1)C(C)(C)c1cc3c4c5c1N2c1c(sc2ccc(C(C)(C)C)cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc(C(C)(C)C)cc12)B5c1cc(C(C)(C)C)cc2c5cc(C(C)(C)C)cc(c5n-4c12)C3(C)C]

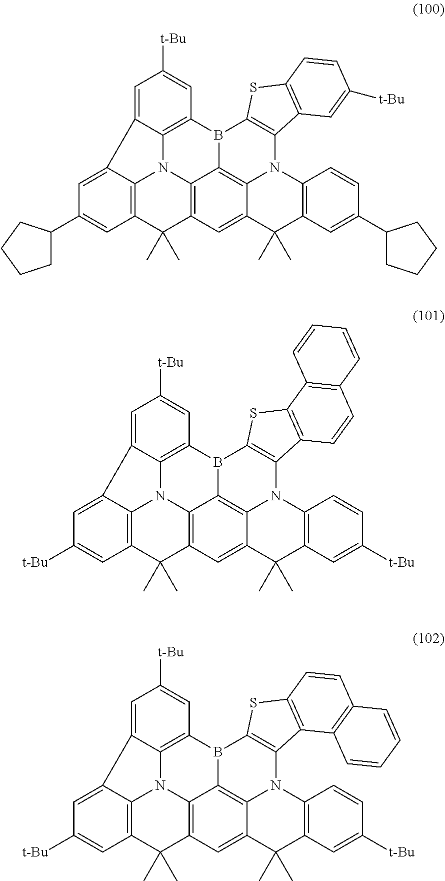 [SMILES: CC(C)(C)c1ccc2sc3c(c2c1)N1c2ccc(C4CCCC4)cc2C(C)(C)c2cc4c5c(c21)B3c1cc(C(C)(C)C)cc2c3cc(C6CCCC6)cc(c3n-5c12)C4(C)C ; CC(C)(C)c1ccc2c(c1)C(C)(C)c1cc3c4c5c1N2c1c(sc2c1ccc1ccccc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc6ccccc6c12)B5c1cc(C(C)(C)C)cc2c5cc(C(C)(C)C)cc(c5n-4c12)C3(C)C]

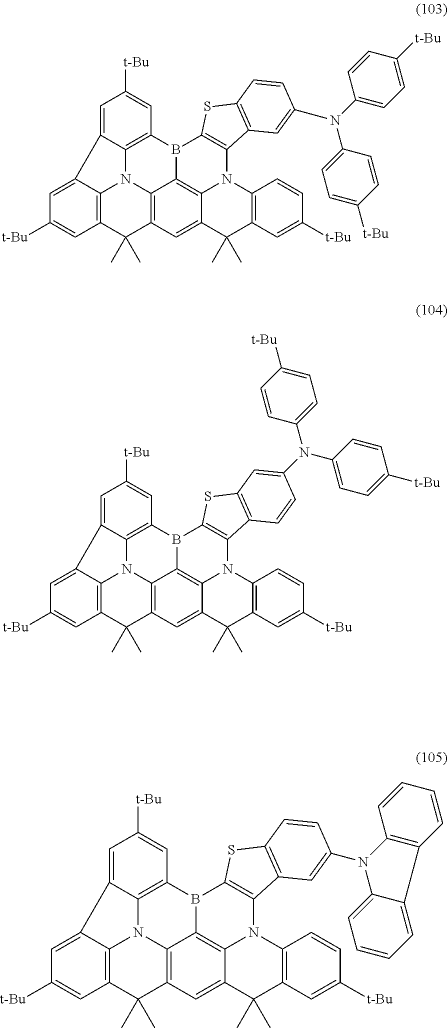 [SMILES: CC(C)(C)c1ccc(N(c2ccc(C(C)(C)C)cc2)c2ccc3sc4c(c3c2)N2c3ccc(C(C)(C)C)cc3C(C)(C)c3cc5c6c(c32)B4c2cc(C(C)(C)C)cc3c4cc(C(C)(C)C)cc(c4n-6c23)C5(C)C)cc1 ; CC(C)(C)c1ccc(N(c2ccc(C(C)(C)C)cc2)c2ccc3c4c(sc3c2)B2c3c5c(cc6c3-n3c7c2cc(C(C)(C)C)cc7c2cc(C(C)(C)C)cc(c23)C6(C)C)C(C)(C)c2cc(C(C)(C)C)ccc2N54)cc1 ; CC(C)(C)c1ccc2c(c1)C(C)(C)c1cc3c4c5c1N2c1c(sc2ccc(-n6c7ccccc7c7ccccc76)cc12)B5c1cc(C(C)(C)C)cc2c5cc(C(C)(C)C)cc(c5n-4c12)C3(C)C]

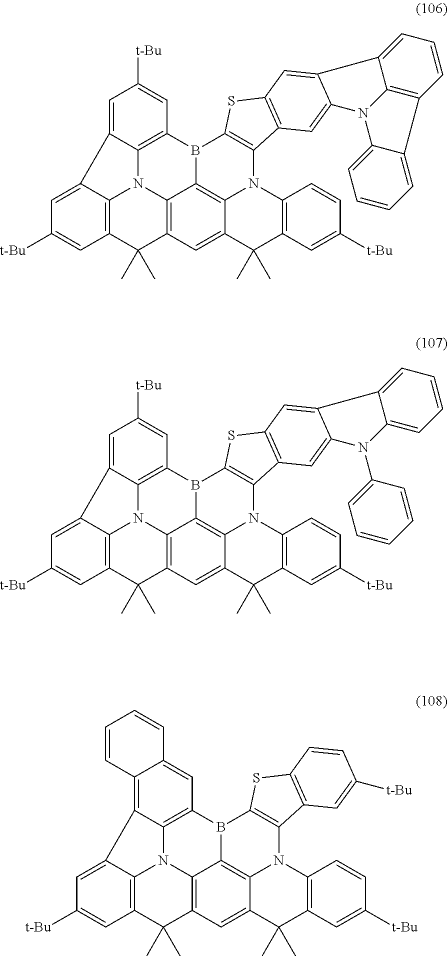 [SMILES: CC(C)(C)c1ccc2c(c1)C(C)(C)c1cc3c4c5c1N2c1c(sc2cc6c7cccc8c9ccccc9n(c6cc12)c87)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2cc6c7ccccc7n(-c7ccccc7)c6cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc(C(C)(C)C)cc12)B5c1cc2ccccc2c2c5cc(C(C)(C)C)cc(c5n-4c12)C3(C)C]

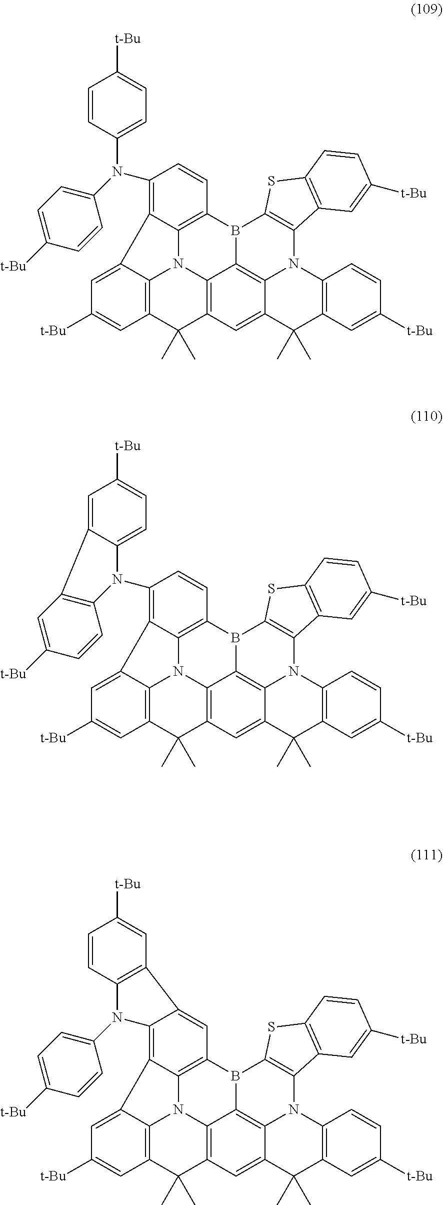 [SMILES: CC(C)(C)c1ccc(N(c2ccc(C(C)(C)C)cc2)c2ccc3c4c2c2cc(C(C)(C)C)cc5c2n4-c2c(cc4c6c2B3c2sc3ccc(C(C)(C)C)cc3c2N6c2ccc(C(C)(C)C)cc2C4(C)C)C5(C)C)cc1 ; CC(C)(C)c1ccc2c(c1)C(C)(C)c1cc3c4c5c1N2c1c(sc2ccc(C(C)(C)C)cc12)B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4sc5ccc(C(C)(C)C)cc5c4N8c4ccc(C(C)(C)C)cc4C6(C)C)C7(C)C)c32)cc1]

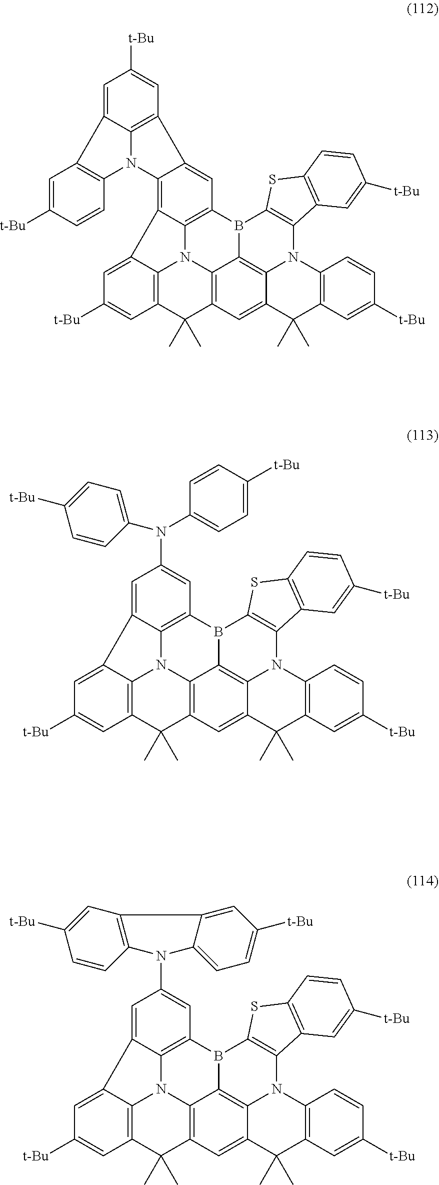 [SMILES: CC(C)(C)c1ccc2c(c1)C(C)(C)c1cc3c4c5c1N2c1c(sc2ccc(C(C)(C)C)cc12)B5c1cc2c5cc(C(C)(C)C)cc6c7cc(C(C)(C)C)ccc7n(c65)c2c2c5cc(C(C)(C)C)cc(c5n-4c12)C3(C)C ; CC(C)(C)c1ccc(N(c2ccc(C(C)(C)C)cc2)c2cc3c4c(c2)c2cc(C(C)(C)C)cc5c2n4-c2c(cc4c6c2B3c2sc3ccc(C(C)(C)C)cc3c2N6c2ccc(C(C)(C)C)cc2C4(C)C)C5(C)C)cc1 ; CC(C)(C)c1ccc2c(c1)C(C)(C)c1cc3c4c5c1N2c1c(sc2ccc(C(C)(C)C)cc12)B5c1cc(-n2c5ccc(C(C)(C)C)cc5c5cc(C(C)(C)C)ccc52)cc2c5cc(C(C)(C)C)cc(c5n-4c12)C3(C)C]

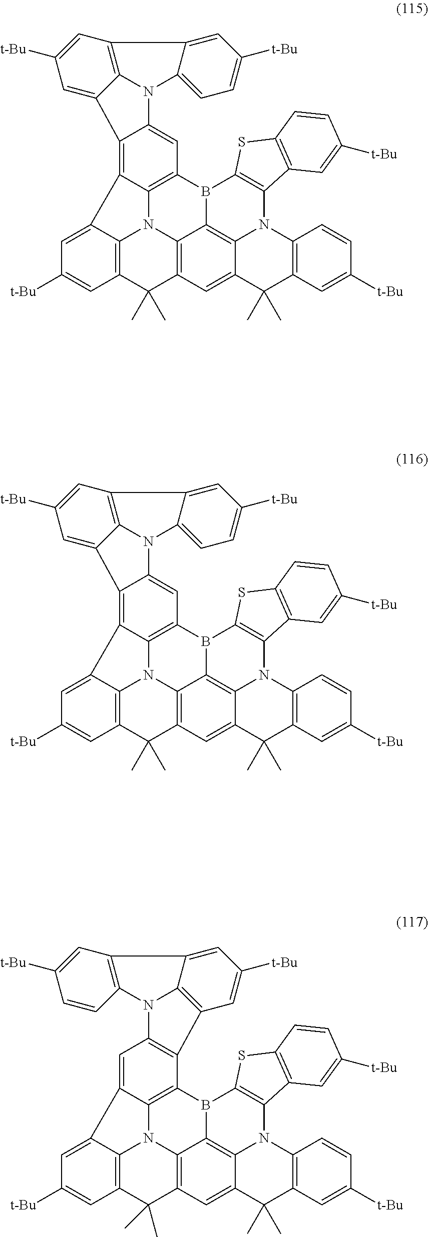 [SMILES: CC(C)(C)c1ccc2c(c1)C(C)(C)c1cc3c4c5c1N2c1c(sc2ccc(C(C)(C)C)cc12)B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1c(sc2ccc(C(C)(C)C)cc12)B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1c(sc2ccc(C(C)(C)C)cc12)B5c1c2c5cc(C(C)(C)C)cc6c7cc(C(C)(C)C)ccc7n(c2cc2c7cc(C(C)(C)C)cc(c7n-4c12)C3(C)C)c65]

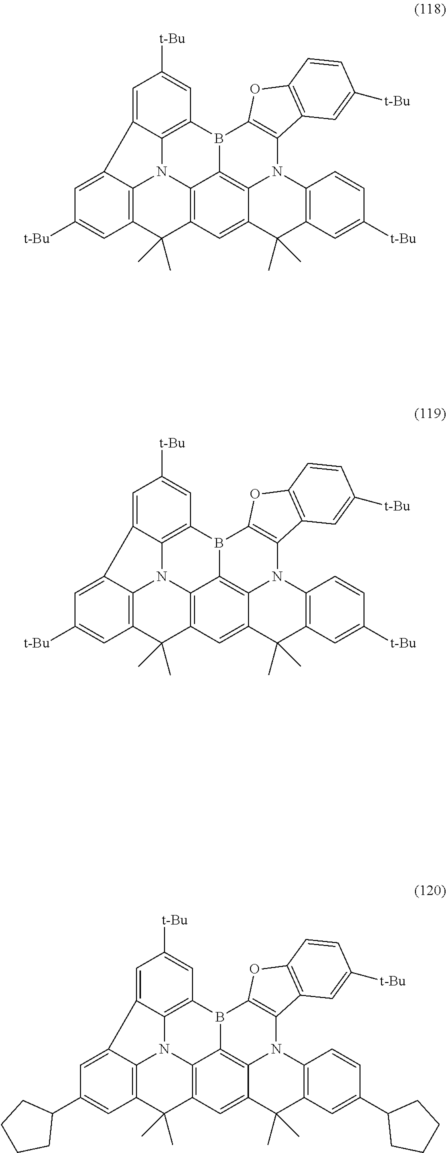 [SMILES: CC(C)(C)c1ccc2c(c1)C(C)(C)c1cc3c4c5c1N2c1c(oc2ccc(C(C)(C)C)cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1cc(C(C)(C)C)cc2c5cc(C(C)(C)C)cc(c5n-4c12)C3(C)C ; CC(C)(C)c1ccc2oc3c(c2c1)N1c2ccc(C4CCCC4)cc2C(C)(C)c2cc4c5c(c21)B3c1cc(C(C)(C)C)cc2c3cc(C6CCCC6)cc(c3n-5c12)C4(C)C]

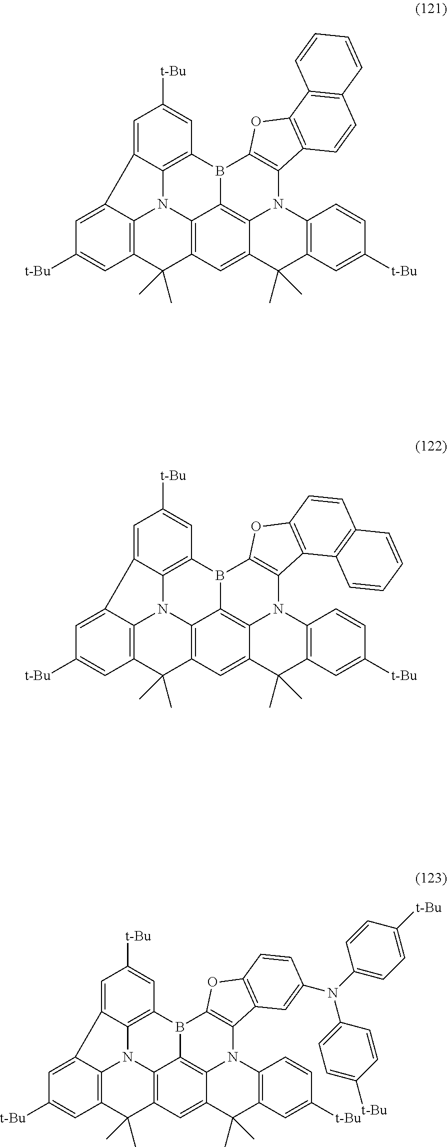 [SMILES: CC(C)(C)c1ccc2c(c1)C(C)(C)c1cc3c4c5c1N2c1c(oc2c1ccc1ccccc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2ccc6ccccc6c12)B5c1cc(C(C)(C)C)cc2c5cc(C(C)(C)C)cc(c5n-4c12)C3(C)C ; CC(C)(C)c1ccc(N(c2ccc(C(C)(C)C)cc2)c2ccc3oc4c(c3c2)N2c3ccc(C(C)(C)C)cc3C(C)(C)c3cc5c6c(c32)B4c2cc(C(C)(C)C)cc3c4cc(C(C)(C)C)cc(c4n-6c23)C5(C)C)cc1]

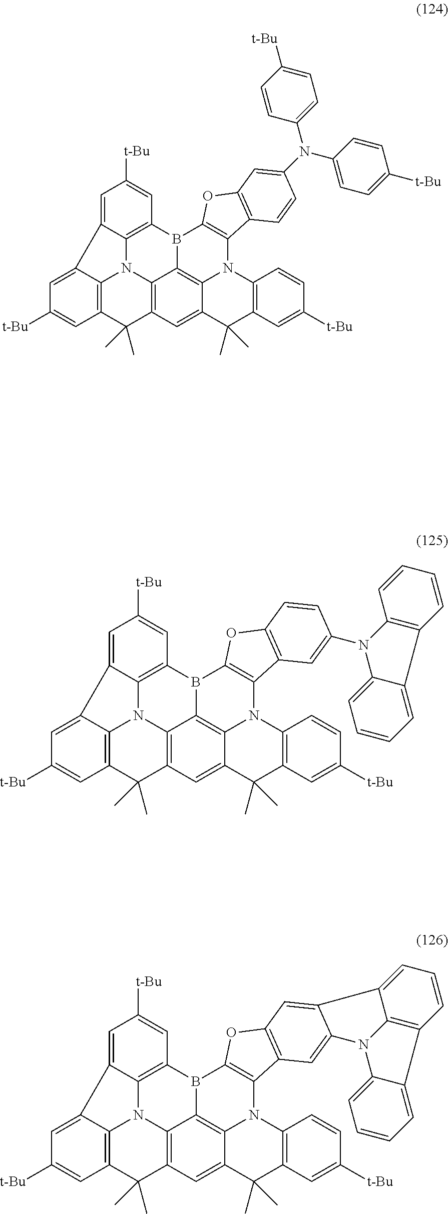 [SMILES: CC(C)(C)c1ccc(N(c2ccc(C(C)(C)C)cc2)c2ccc3c4c(oc3c2)B2c3c5c(cc6c3-n3c7c2cc(C(C)(C)C)cc7c2cc(C(C)(C)C)cc(c23)C6(C)C)C(C)(C)c2cc(C(C)(C)C)ccc2N54)cc1 ; CC(C)(C)c1ccc2c(c1)C(C)(C)c1cc3c4c5c1N2c1c(oc2ccc(-n6c7ccccc7c7ccccc76)cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2cc6c7cccc8c9ccccc9n(c6cc12)c87)B5c1cc(C(C)(C)C)cc2c5cc(C(C)(C)C)cc(c5n-4c12)C3(C)C]

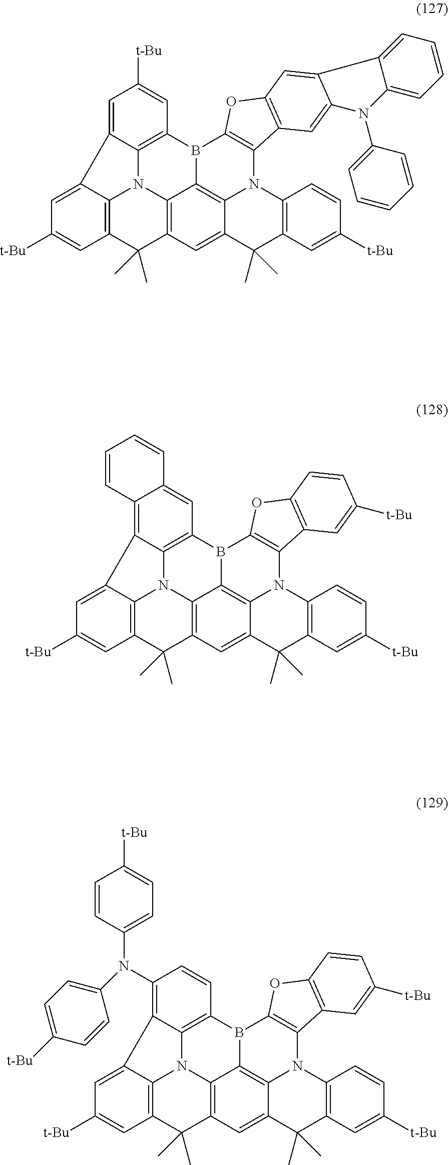 [SMILES: CC(C)(C)c1ccc2c(c1)C(C)(C)c1cc3c4c5c1N2c1c(oc2cc6c7ccccc7n(-c7ccccc7)c6cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1cc2ccccc2c2c5cc(C(C)(C)C)cc(c5n-4c12)C3(C)C ; CC(C)(C)c1ccc(N(c2ccc(C(C)(C)C)cc2)c2ccc3c4c2c2cc(C(C)(C)C)cc5c2n4-c2c(cc4c6c2B3c2oc3ccc(C(C)(C)C)cc3c2N6c2ccc(C(C)(C)C)cc2C4(C)C)C5(C)C)cc1]

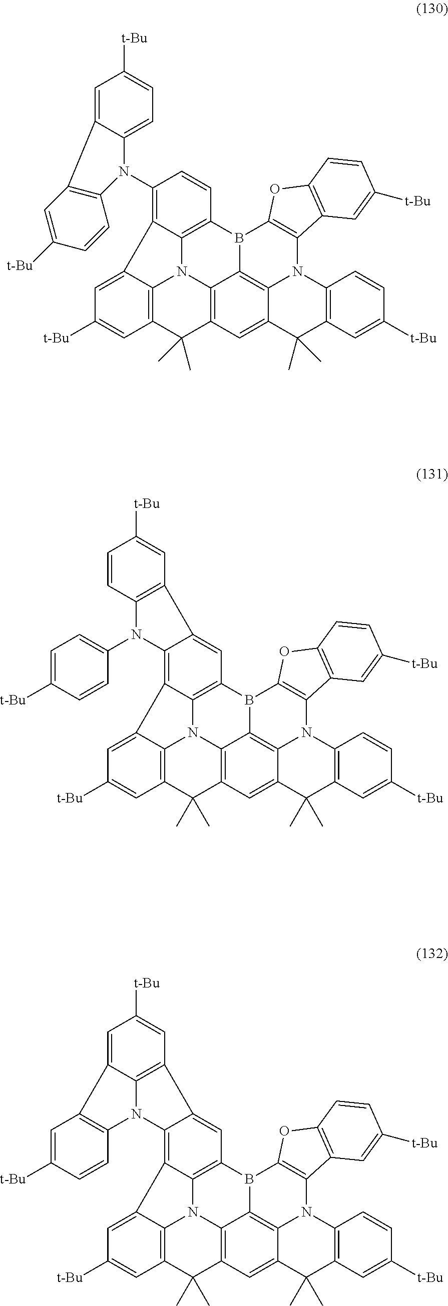 [SMILES: CC(C)(C)c1ccc2c(c1)C(C)(C)c1cc3c4c5c1N2c1c(oc2ccc(C(C)(C)C)cc12)B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4oc5ccc(C(C)(C)C)cc5c4N8c4ccc(C(C)(C)C)cc4C6(C)C)C7(C)C)c32)cc1 ; CC(C)(C)c1ccc2c(c1)C(C)(C)c1cc3c4c5c1N2c1c(oc2ccc(C(C)(C)C)cc12)B5c1cc2c5cc(C(C)(C)C)cc6c7cc(C(C)(C)C)ccc7n(c65)c2c2c5cc(C(C)(C)C)cc(c5n-4c12)C3(C)C]

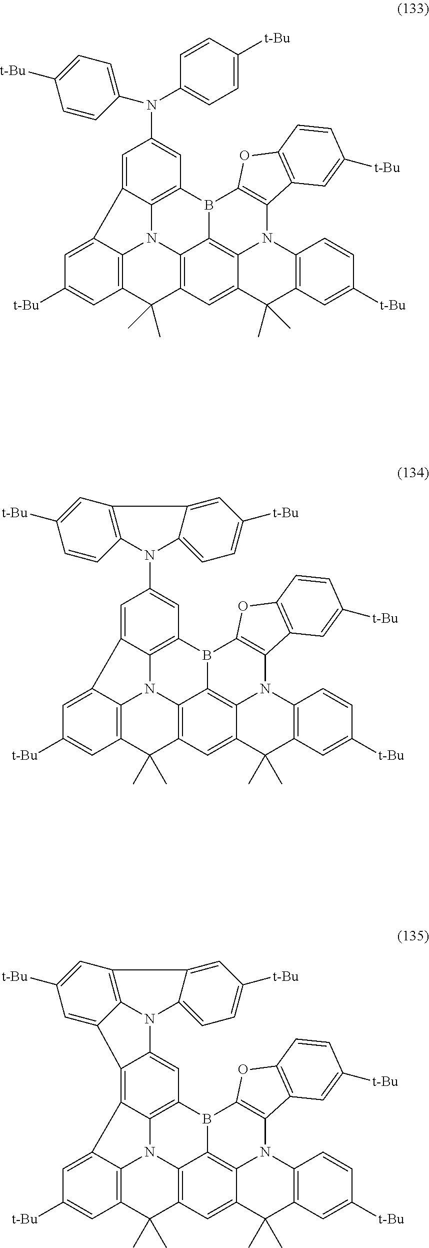 [SMILES: CC(C)(C)c1ccc(N(c2ccc(C(C)(C)C)cc2)c2cc3c4c(c2)c2cc(C(C)(C)C)cc5c2n4-c2c(cc4c6c2B3c2oc3ccc(C(C)(C)C)cc3c2N6c2ccc(C(C)(C)C)cc2C4(C)C)C5(C)C)cc1 ; CC(C)(C)c1ccc2c(c1)C(C)(C)c1cc3c4c5c1N2c1c(oc2ccc(C(C)(C)C)cc12)B5c1cc(-n2c5ccc(C(C)(C)C)cc5c5cc(C(C)(C)C)ccc52)cc2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1cc2c(c5cc(C(C)(C)C)cc6c7cc(C(C)(C)C)ccc7n2c65)c2c5cc(C(C)(C)C)cc(c5n-4c12)C3(C)C]

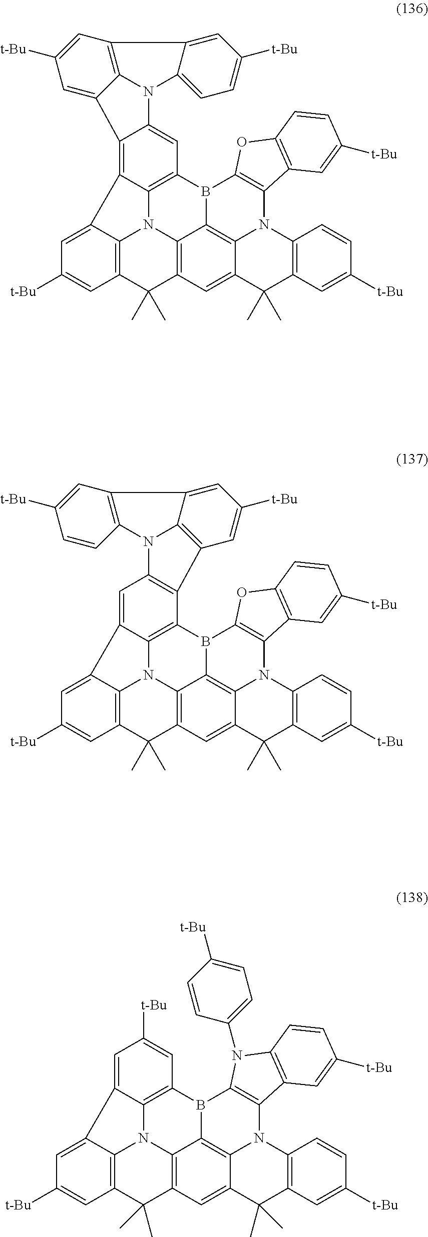 [SMILES: CC(C)(C)c1ccc2c(c1)C(C)(C)c1cc3c4c5c1N2c1c(oc2ccc(C(C)(C)C)cc12)B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1c2c5cc(C(C)(C)C)cc6c7cc(C(C)(C)C)ccc7n(c2cc2c7cc(C(C)(C)C)cc(c7n-4c12)C3(C)C)c65 ; CC(C)(C)c1ccc(-n2c3c(c4cc(C(C)(C)C)ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1]

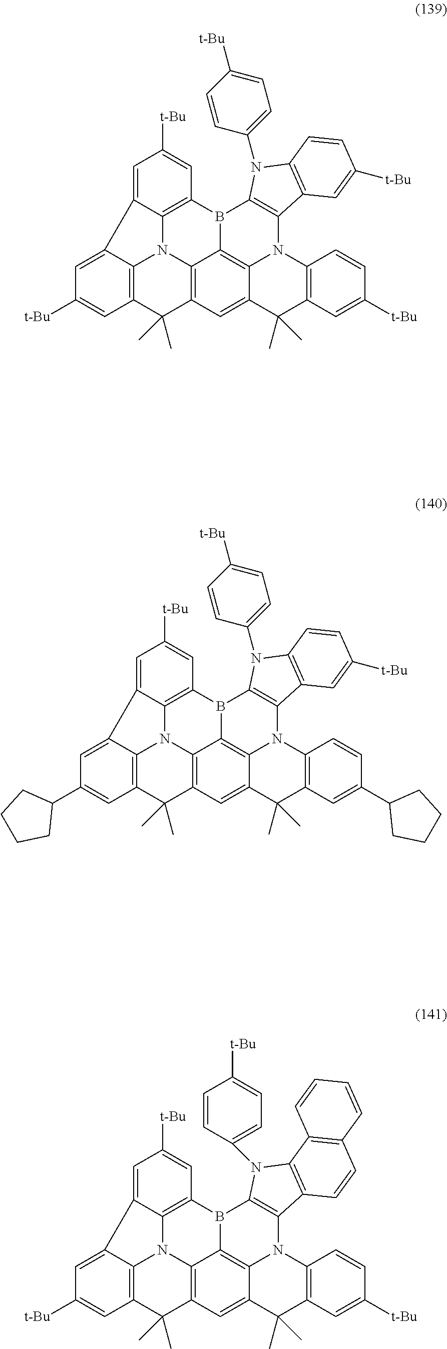 [SMILES: CC(C)(C)c1ccc(-n2c3c(c4cc(C(C)(C)C)ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(-n2c3c(c4cc(C(C)(C)C)ccc42)N2c4ccc(C5CCCC5)cc4C(C)(C)c4cc5c6c(c42)B3c2cc(C(C)(C)C)cc3c4cc(C7CCCC7)cc(c4n-6c23)C5(C)C)cc1 ; CC(C)(C)c1ccc(-n2c3c(c4ccc5ccccc5c42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1]

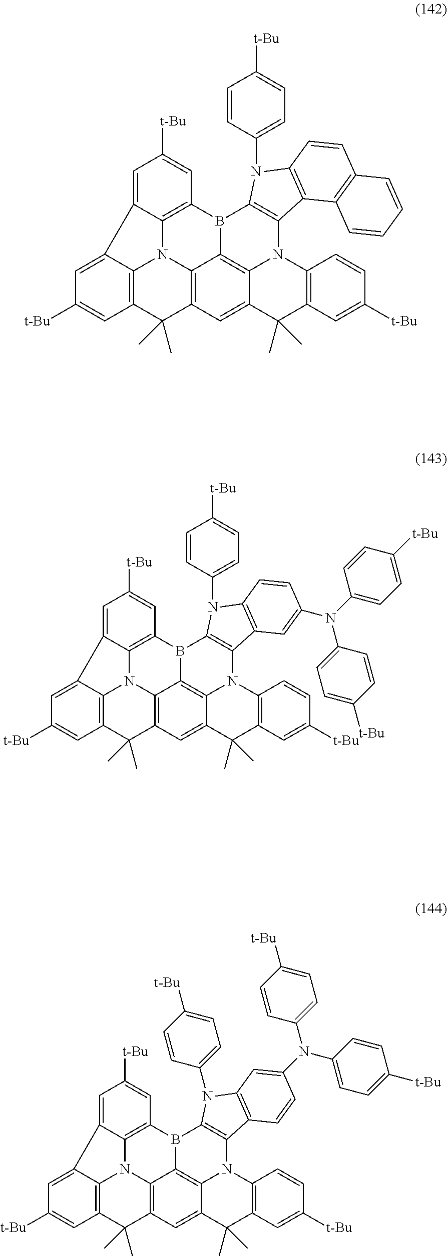 [SMILES: CC(C)(C)c1ccc(-n2c3c(c4c5ccccc5ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(N(c2ccc(C(C)(C)C)cc2)c2ccc3c(c2)c2c(n3-c3ccc(C(C)(C)C)cc3)B3c4c5c(cc6c4-n4c7c3cc(C(C)(C)C)cc7c3cc(C(C)(C)C)cc(c34)C6(C)C)C(C)(C)c3cc(C(C)(C)C)ccc3N52)cc1 ; CC(C)(C)c1ccc(N(c2ccc(C(C)(C)C)cc2)c2ccc3c4c(n(-c5ccc(C(C)(C)C)cc5)c3c2)B2c3c5c(cc6c3-n3c7c2cc(C(C)(C)C)cc7c2cc(C(C)(C)C)cc(c23)C6(C)C)C(C)(C)c2cc(C(C)(C)C)ccc2N54)cc1]

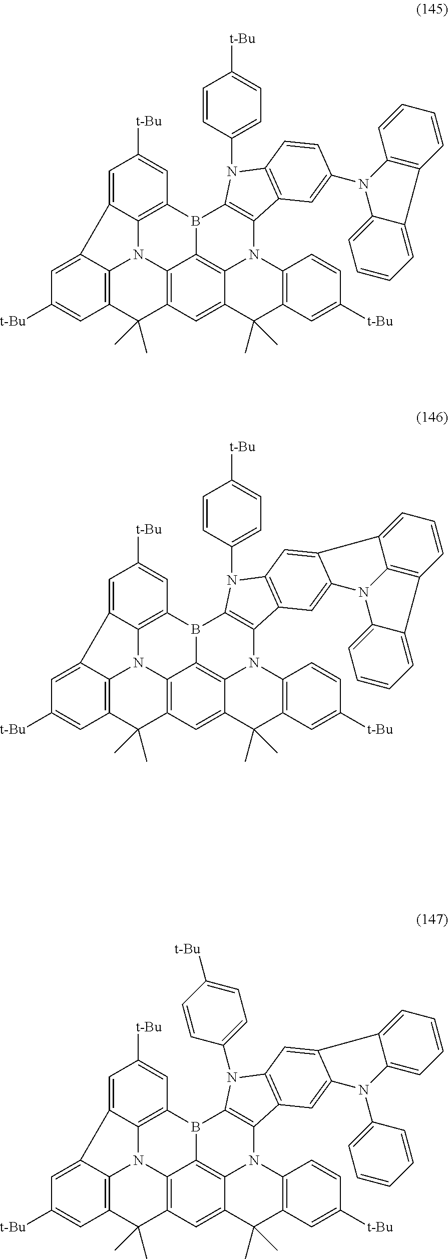 [SMILES: CC(C)(C)c1ccc(-n2c3c(c4cc(-n5c6ccccc6c6ccccc65)ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(-n2c3c(c4cc5c(cc42)c2cccc4c6ccccc6n5c42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(-n2c3c(c4cc5c(cc42)c2ccccc2n5-c2ccccc2)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1]

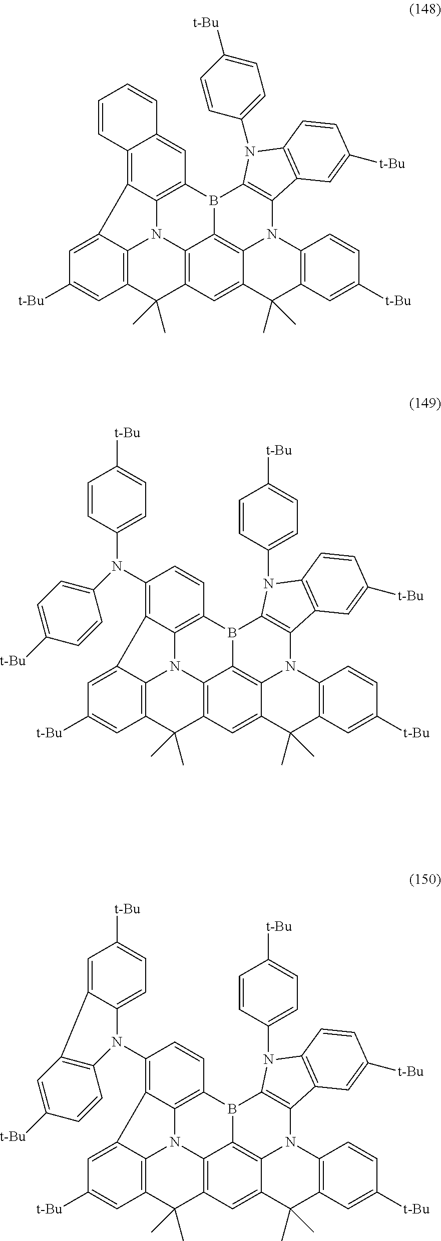 [SMILES: CC(C)(C)c1ccc(-n2c3c(c4cc(C(C)(C)C)ccc42)N2c4ccc(C(C)(C)C)cc4C(C)(C)c4cc5c6c(c42)B3c2cc3ccccc3c3c4cc(C(C)(C)C)cc(c4n-6c23)C5(C)C)cc1 ; CC(C)(C)c1ccc(N(c2ccc(C(C)(C)C)cc2)c2ccc3c4c2c2cc(C(C)(C)C)cc5c2n4-c2c(cc4c6c2B3c2c(c3cc(C(C)(C)C)ccc3n2-c2ccc(C(C)(C)C)cc2)N6c2ccc(C(C)(C)C)cc2C4(C)C)C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2ccc(-n3c4ccc(C(C)(C)C)cc4c4cc(C(C)(C)C)ccc43)c3c4cc(C(C)(C)C)cc(c4n-6c23)C5(C)C)cc1]

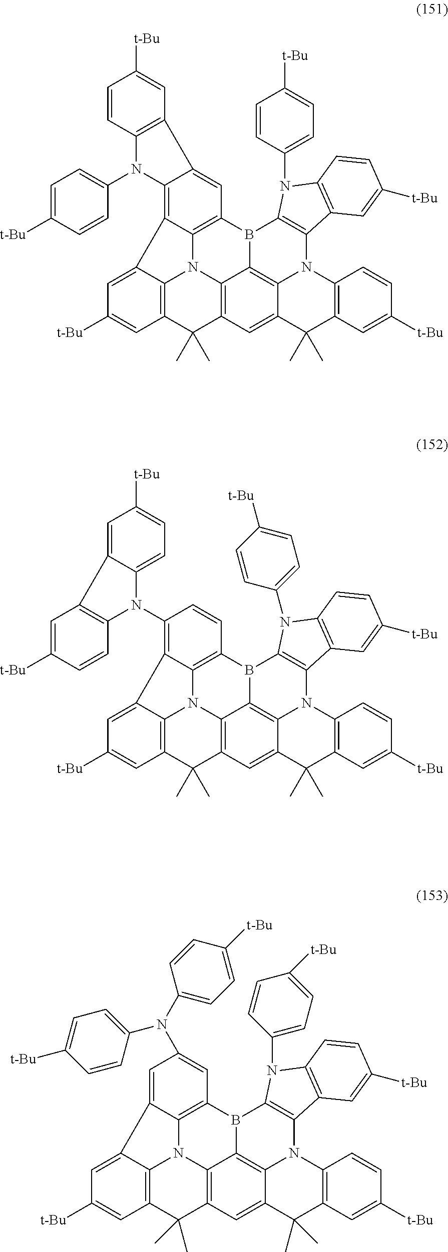

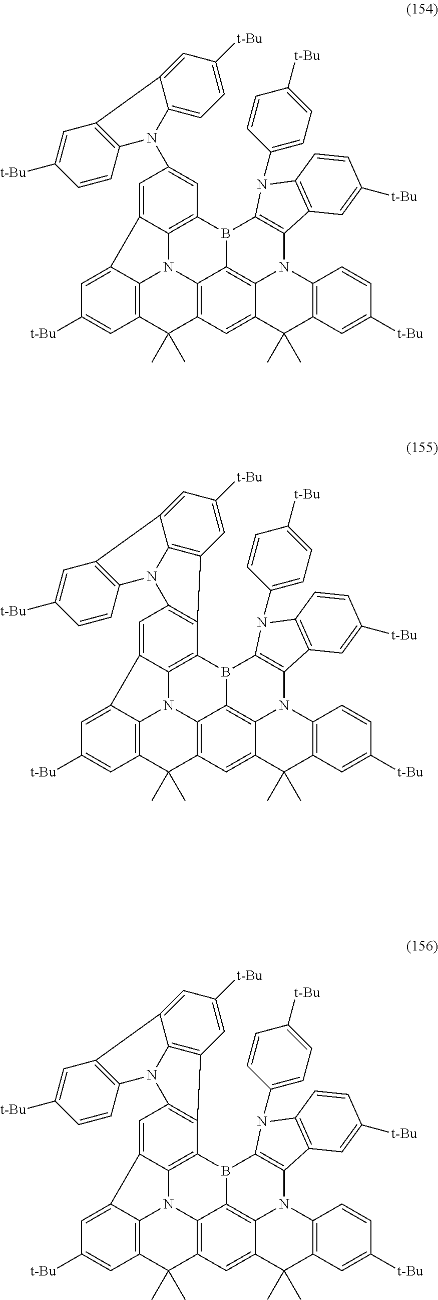

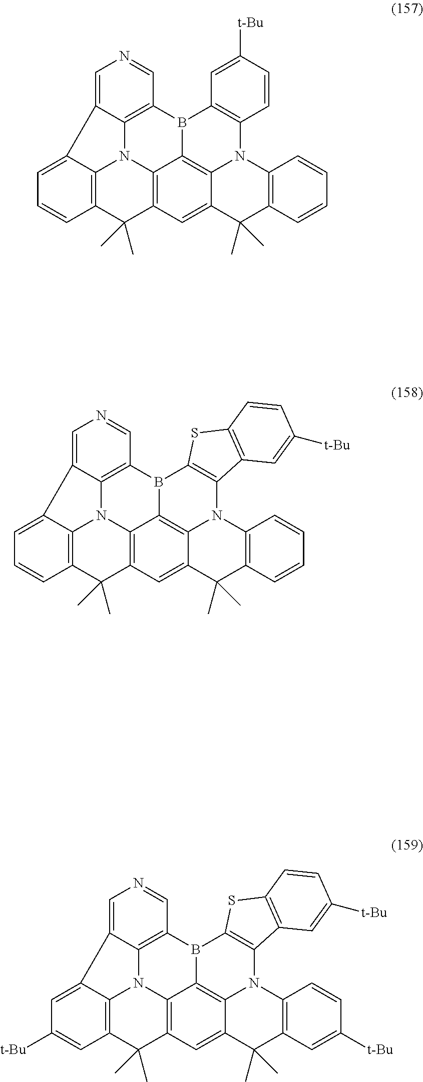 [SMILES: CC(C)(C)c1ccc2c(c1)B1c3c4c(cc5c3-n3c6c1cncc6c1cccc(c13)C5(C)C)C(C)(C)c1ccccc1N24 ; CC(C)(C)c1ccc2sc3c(c2c1)N1c2ccccc2C(C)(C)c2cc4c5c(c21)B3c1cncc2c3cccc(c3n-5c12)C4(C)C ; CC(C)(C)c1ccc2c(c1)C(C)(C)c1cc3c4c5c1N2c1c(sc2ccc(C(C)(C)C)cc12)B5c1cncc2c5cc(C(C)(C)C)cc(c5n-4c12)C3(C)C]

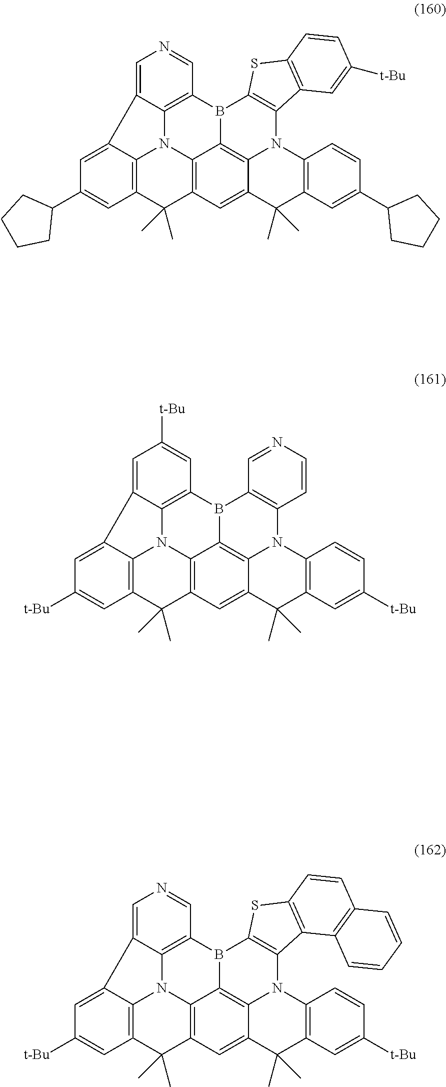 [SMILES: CC(C)(C)c1ccc2sc3c(c2c1)N1c2ccc(C4CCCC4)cc2C(C)(C)c2cc4c5c(c21)B3c1cncc2c3cc(C6CCCC6)cc(c3n-5c12)C4(C)C ; CC(C)(C)c1ccc2c(c1)C(C)(C)c1cc3c4c5c1N2c1ccncc1B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc6ccccc6c12)B5c1cncc2c5cc(C(C)(C)C)cc(c5n-4c12)C3(C)C]

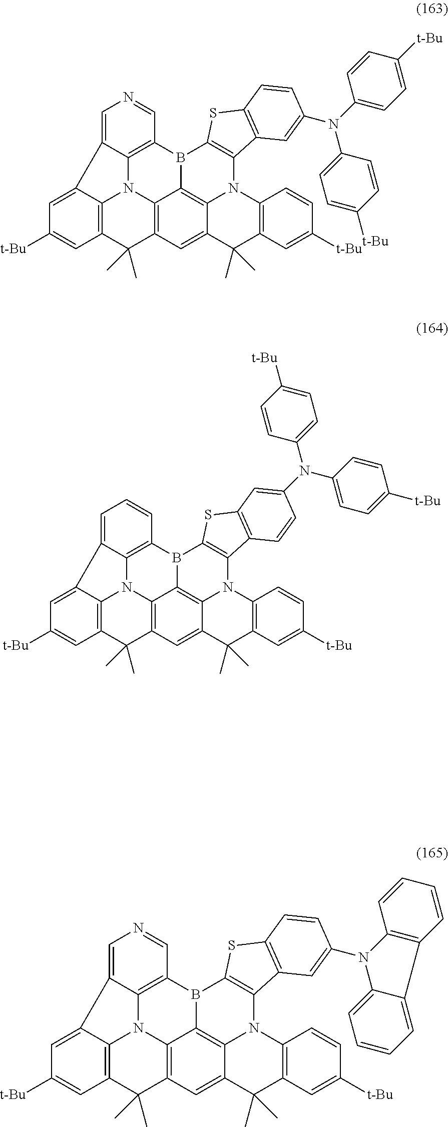 [SMILES: CC(C)(C)c1ccc(N(c2ccc(C(C)(C)C)cc2)c2ccc3sc4c(c3c2)N2c3ccc(C(C)(C)C)cc3C(C)(C)c3cc5c6c(c32)B4c2cncc3c4cc(C(C)(C)C)cc(c4n-6c23)C5(C)C)cc1 ; CC(C)(C)c1ccc(N(c2ccc(C(C)(C)C)cc2)c2ccc3c4c(sc3c2)B2c3c5c(cc6c3-n3c7c2cccc7c2cc(C(C)(C)C)cc(c23)C6(C)C)C(C)(C)c2cc(C(C)(C)C)ccc2N54)cc1 ; CC(C)(C)c1ccc2c(c1)C(C)(C)c1cc3c4c5c1N2c1c(sc2ccc(-n6c7ccccc7c7ccccc76)cc12)B5c1cncc2c5cc(C(C)(C)C)cc(c5n-4c12)C3(C)C]

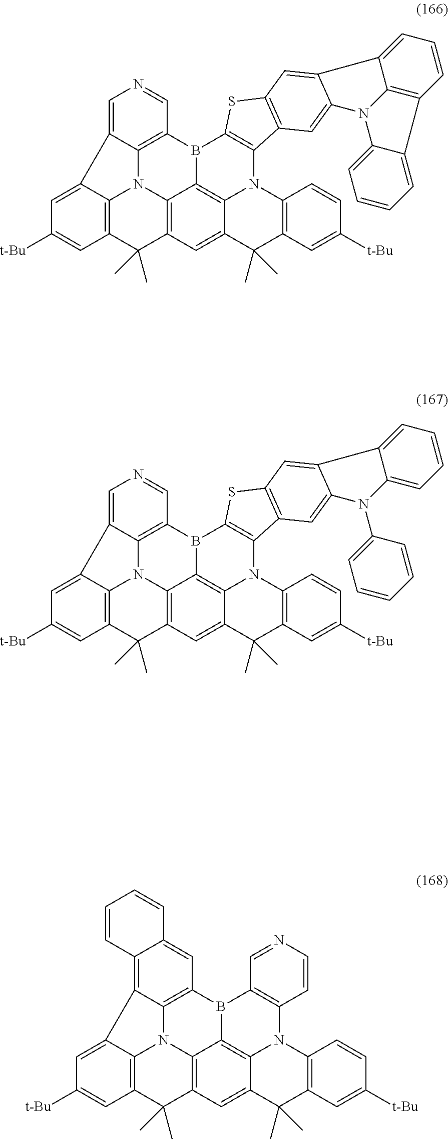 [SMILES: CC(C)(C)c1ccc2c(c1)C(C)(C)c1cc3c4c5c1N2c1c(sc2cc6c7cccc8c9ccccc9n(c6cc12)c87)B5c1cncc2c5cc(C(C)(C)C)cc(c5n-4c12)C3(C)C ; CC(C)(C)c1ccc2c(c1)C(C)(C)c1cc3c4c5c1N2c1c(sc2cc6c7ccccc7n(-c7ccccc7)c6cc12)B5c1cncc2c5cc(C(C)(C)C)cc(c5n-4c12)C3(C)C ; CC(C)(C)c1ccc2c(c1)C(C)(C)c1cc3c4c5c1N2c1ccncc1B5c1cc2ccccc2c2c5cc(C(C)(C)C)cc(c5n-4c12)C3(C)C]

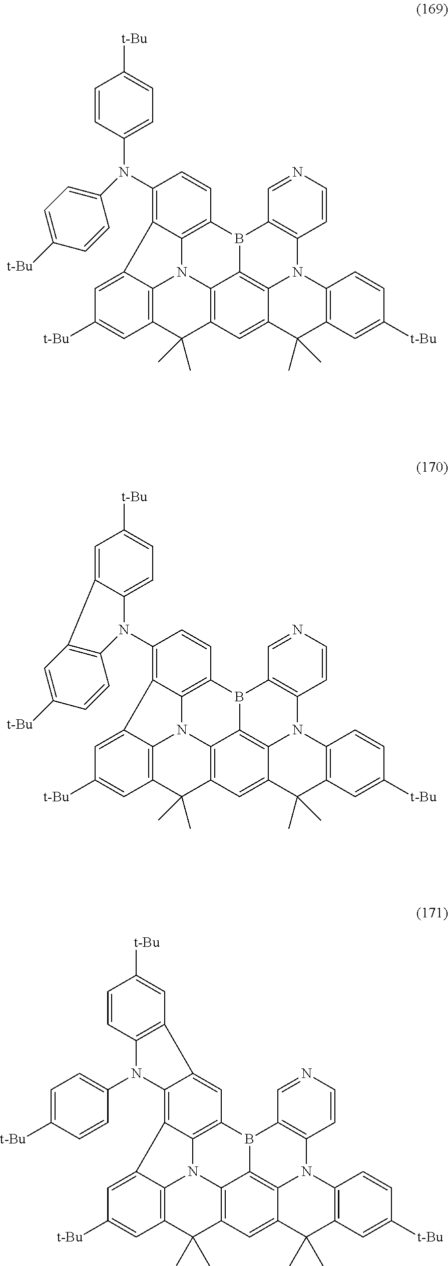 [SMILES: CC(C)(C)c1ccc(N(c2ccc(C(C)(C)C)cc2)c2ccc3c4c2c2cc(C(C)(C)C)cc5c2n4-c2c(cc4c6c2B3c2cnccc2N6c2ccc(C(C)(C)C)cc2C4(C)C)C5(C)C)cc1 ; CC(C)(C)c1ccc2c(c1)C(C)(C)c1cc3c4c5c1N2c1ccncc1B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4cnccc4N8c4ccc(C(C)(C)C)cc4C6(C)C)C7(C)C)c32)cc1]

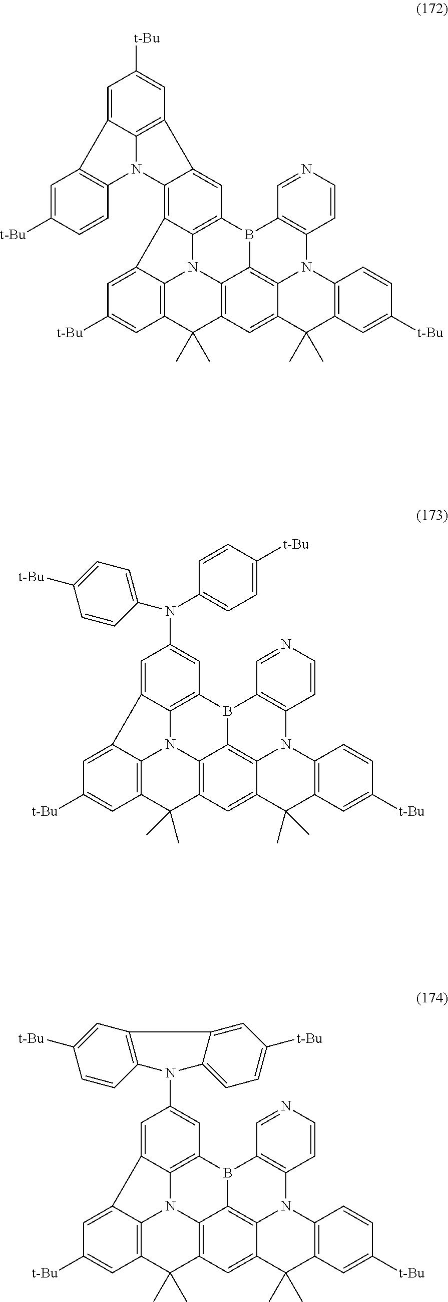 [SMILES: CC(C)(C)c1ccc2c(c1)C(C)(C)c1cc3c4c5c1N2c1ccncc1B5c1cc2c5cc(C(C)(C)C)cc6c7cc(C(C)(C)C)ccc7n(c65)c2c2c5cc(C(C)(C)C)cc(c5n-4c12)C3(C)C ; CC(C)(C)c1ccc(N(c2ccc(C(C)(C)C)cc2)c2cc3c4c(c2)c2cc(C(C)(C)C)cc5c2n4-c2c(cc4c6c2B3c2cnccc2N6c2ccc(C(C)(C)C)cc2C4(C)C)C5(C)C)cc1 ; CC(C)(C)c1ccc2c(c1)C(C)(C)c1cc3c4c5c1N2c1ccncc1B5c1cc(-n2c5ccc(C(C)(C)C)cc5c5cc(C(C)(C)C)ccc52)cc2c5cc(C(C)(C)C)cc(c5n-4c12)C3(C)C]

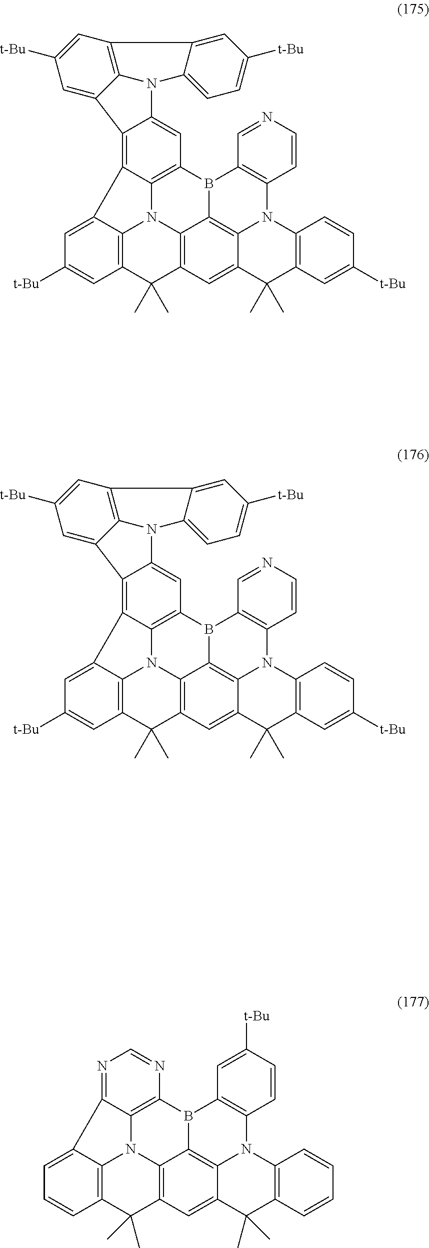 [SMILES: CC(C)(C)c1ccc2c(c1)C(C)(C)c1cc3c4c5c1N2c1ccncc1B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1ccncc1B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)B1c3c4c(cc5c3-n3c6c(cccc6c6ncnc1c63)C5(C)C)C(C)(C)c1ccccc1N24]

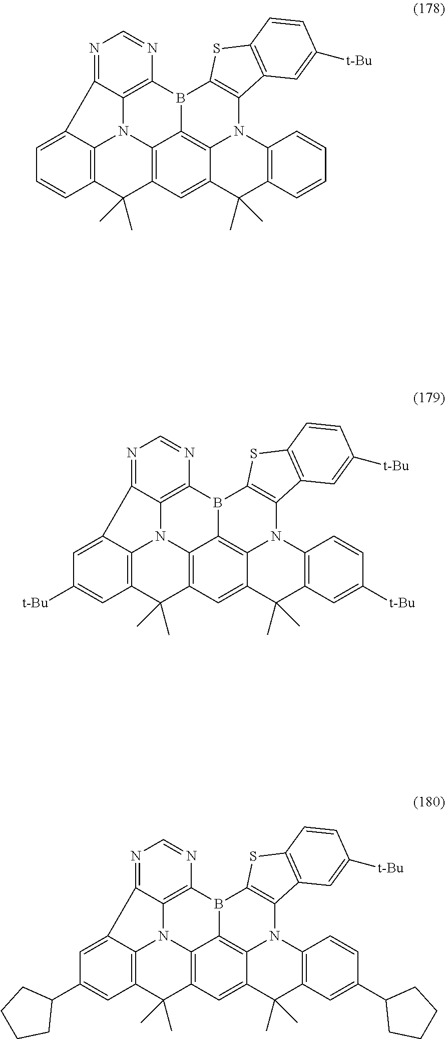 [SMILES: CC(C)(C)c1ccc2sc3c(c2c1)N1c2ccccc2C(C)(C)c2cc4c5c(c21)B3c1ncnc2c3cccc(c3n-5c12)C4(C)C ; CC(C)(C)c1ccc2c(c1)C(C)(C)c1cc3c4c5c1N2c1c(sc2ccc(C(C)(C)C)cc12)B5c1ncnc2c5cc(C(C)(C)C)cc(c5n-4c12)C3(C)C ; CC(C)(C)c1ccc2sc3c(c2c1)N1c2ccc(C4CCCC4)cc2C(C)(C)c2cc4c5c(c21)B3c1ncnc2c3cc(C6CCCC6)cc(c3n-5c12)C4(C)C]

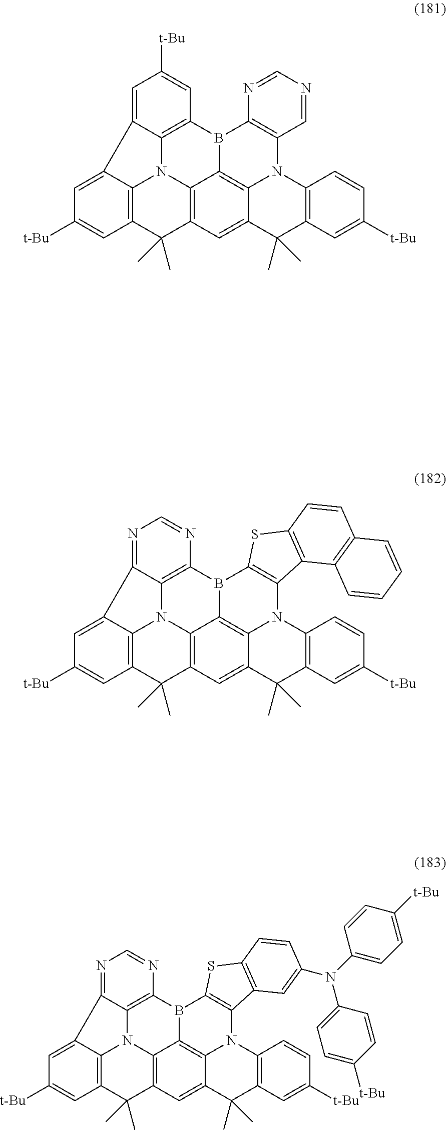 [SMILES: CC(C)(C)c1ccc2c(c1)C(C)(C)c1cc3c4c5c1N2c1cncnc1B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc6ccccc6c12)B5c1ncnc2c5cc(C(C)(C)C)cc(c5n-4c12)C3(C)C ; CC(C)(C)c1ccc(N(c2ccc(C(C)(C)C)cc2)c2ccc3sc4c(c3c2)N2c3ccc(C(C)(C)C)cc3C(C)(C)c3cc5c6c(c32)B4c2ncnc3c4cc(C(C)(C)C)cc(c4n-6c23)C5(C)C)cc1]

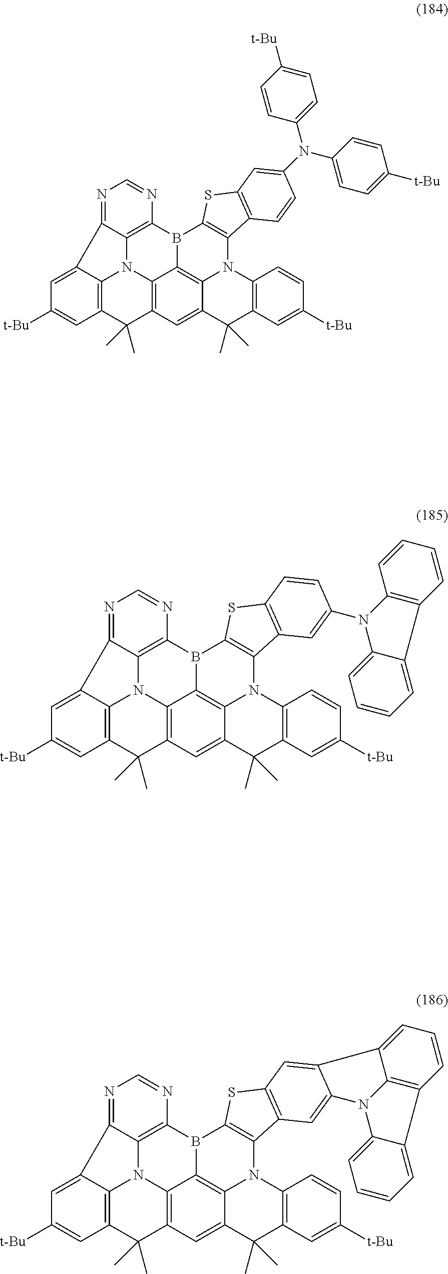 [SMILES: CC(C)(C)c1ccc(N(c2ccc(C(C)(C)C)cc2)c2ccc3c4c(sc3c2)B2c3c5c(cc6c3-n3c7c(cc(C(C)(C)C)cc7c7ncnc2c73)C6(C)C)C(C)(C)c2cc(C(C)(C)C)ccc2N54)cc1 ; CC(C)(C)c1ccc2c(c1)C(C)(C)c1cc3c4c5c1N2c1c(sc2ccc(-n6c7ccccc7c7ccccc76)cc12)B5c1ncnc2c5cc(C(C)(C)C)cc(c5n-4c12)C3(C)C ; CC(C)(C)c1ccc2c(c1)C(C)(C)c1cc3c4c5c1N2c1c(sc2cc6c7cccc8c9ccccc9n(c6cc12)c87)B5c1ncnc2c5cc(C(C)(C)C)cc(c5n-4c12)C3(C)C]

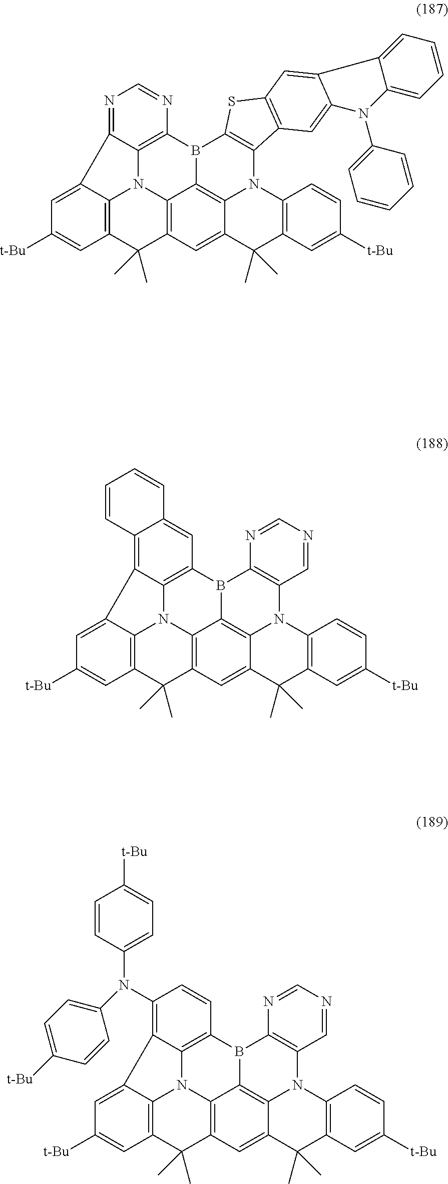 [SMILES: CC(C)(C)c1ccc2c(c1)C(C)(C)c1cc3c4c5c1N2c1c(sc2cc6c7ccccc7n(-c7ccccc7)c6cc12)B5c1ncnc2c5cc(C(C)(C)C)cc(c5n-4c12)C3(C)C ; CC(C)(C)c1ccc2c(c1)C(C)(C)c1cc3c4c5c1N2c1cncnc1B5c1cc2ccccc2c2c5cc(C(C)(C)C)cc(c5n-4c12)C3(C)C ; CC(C)(C)c1ccc(N(c2ccc(C(C)(C)C)cc2)c2ccc3c4c2c2cc(C(C)(C)C)cc5c2n4-c2c(cc4c6c2B3c2ncncc2N6c2ccc(C(C)(C)C)cc2C4(C)C)C5(C)C)cc1]

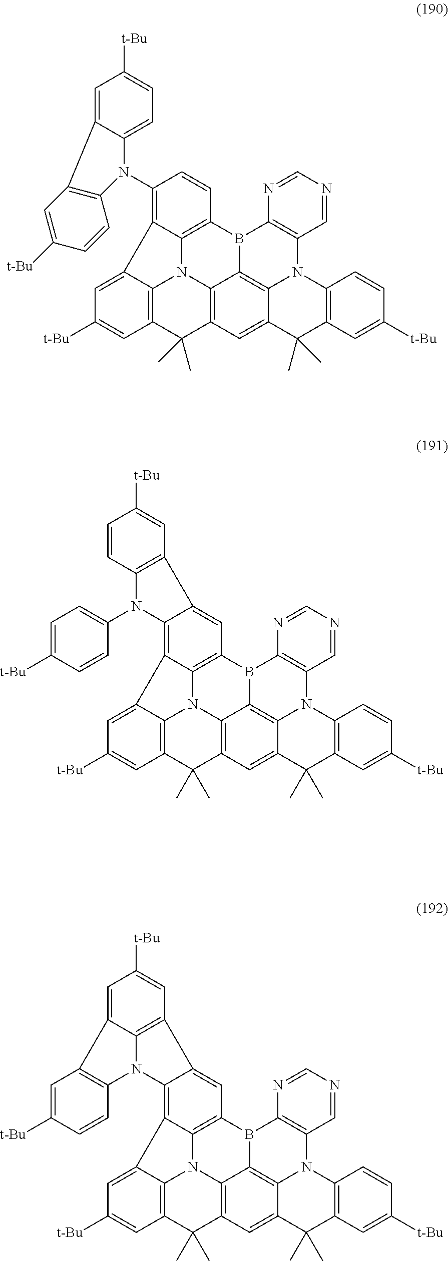 [SMILES: CC(C)(C)c1ccc2c(c1)C(C)(C)c1cc3c4c5c1N2c1cncnc1B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4ncncc4N8c4ccc(C(C)(C)C)cc4C6(C)C)C7(C)C)c32)cc1 ; CC(C)(C)c1ccc2c(c1)C(C)(C)c1cc3c4c5c1N2c1cncnc1B5c1cc2c5cc(C(C)(C)C)cc6c7cc(C(C)(C)C)ccc7n(c65)c2c2c5cc(C(C)(C)C)cc(c5n-4c12)C3(C)C]

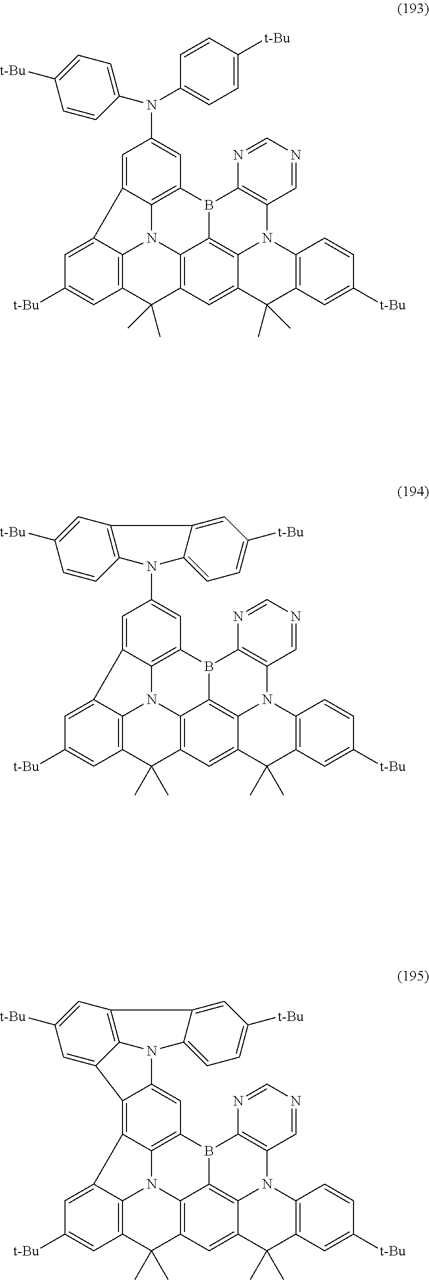 [SMILES: CC(C)(C)c1ccc(N(c2ccc(C(C)(C)C)cc2)c2cc3c4c(c2)c2cc(C(C)(C)C)cc5c2n4-c2c(cc4c6c2B3c2ncncc2N6c2ccc(C(C)(C)C)cc2C4(C)C)C5(C)C)cc1 ; CC(C)(C)c1ccc2c(c1)C(C)(C)c1cc3c4c5c1N2c1cncnc1B5c1cc(-n2c5ccc(C(C)(C)C)cc5c5cc(C(C)(C)C)ccc52)cc2c5cc(C(C)(C)C)cc(c5n-4c12)C3(C)C ; CC(C)(C)c1ccc2c(c1)C(C)(C)c1cc3c4c5c1N2c1cncnc1B5c1cc2c(c5cc(C(C)(C)C)cc6c7cc(C(C)(C)C)ccc7n2c65)c2c5cc(C(C)(C)C)cc(c5n-4c12)C3(C)C]

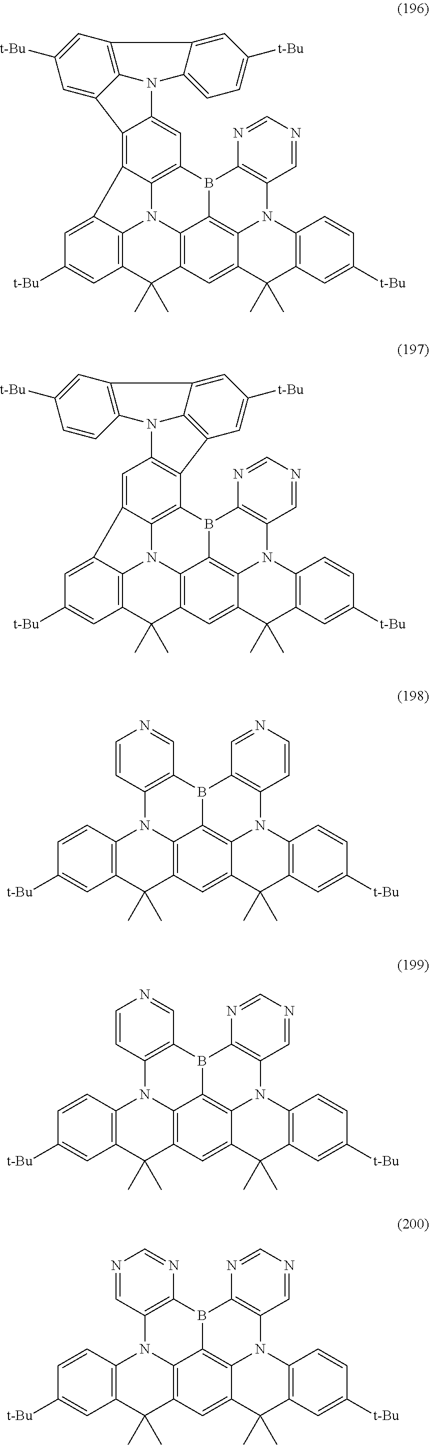

The present disclosure further provides an organic electroluminescent device, which comprises an organic electroluminescent material having at least one functional layer containing a B—N structure.

For example, the organic electroluminescent material containing a B—N structure is used as an emission layer material.

For example, the organic electroluminescent material containing a B—N structure is used as a doping material or a sensitizer material of the emission layer.

Use of the aforementioned organic electroluminescent material in an electroluminescent device is provided.

The electroluminescent device comprises at least one functional layer containing the aforementioned organic electroluminescent material.

The organic electroluminescent material is used as an emission layer material.

The organic electroluminescent material is used as a doping material or a sensitizer material of the emission layer.

A lighting or display element comprises an electroluminescent device prepared from the aforementioned organic electroluminescent material.

The present disclosure provides an organic electroluminescent material containing a B—N structure and use thereof. Based on a conventional B—N resonance structure, in such materials, an aromatic ring that does not participate in the resonance is fixed to a resonance ring by means of a dimethyl-substituted methylene group to form a larger rigid structure, thereby decreasing non-radiative vibration, reducing delayed fluorescence lifetime and reducing efficiency roll-off. Moreover, the introduction of the dimethyl-substituted methylene distorts the B—N planar skeleton, which can reduce fluorescence quenching at high concentrations, thereby obtaining relatively high efficiency. In addition, when Cy1 and Cy2 are different, especially after a heteroatom is introduced, this type of asymmetric structure can further distort the molecular plane, reduce film aggregation and quenching, and achieve a higher current efficiency.

### BRIEF DESCRIPTION OF DRAWINGS

FIG. 1 is a structural diagram of an electroluminescent device of the present disclosure, in which 10 represents glass substrate, 20 represents anode, 30 represents hole injection layer, 40 represents hole transport layer, 50 represents electron blocking layer, 60 represents emission layer, 70 represents electron transport layer, 80 represents electron injection layer, and 90 represents cathode.

FIG. 2 is a fluorescence emission diagram of an organic electroluminescent material in Example 1 of the present disclosure.

### DETAILED DESCRIPTION

The synthesis method of materials is not specified in the present disclosure. The present disclosure is described in detail in conjunction with the following embodiments, but not limited thereto. Unless otherwise specified, all raw materials used in the following syntheses are commercially available products.

### EXAMPLE 1

### Synthesis of Compound Structure 1

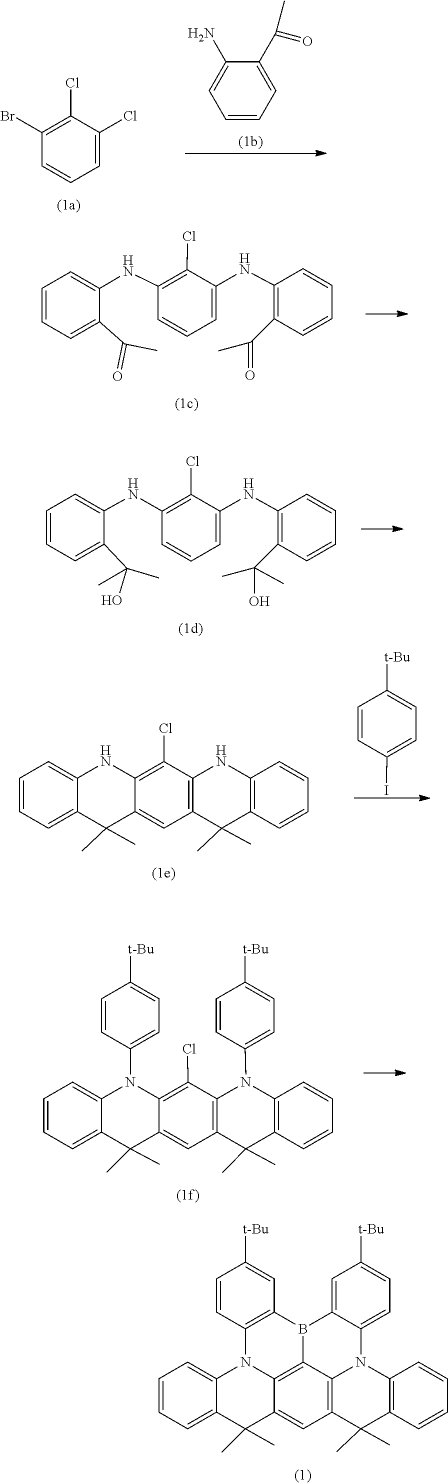

### Synthesis of Compound (1c)

(1a) (15 g), (1b) (22.5 g), Pd₂(dba)₃ (1.2 g), Brett-phos (3.0 g), Cs₂CO₃ (75 g) and magnetrons were added to a 1 L single-necked reaction flask, into which 450 mL of dry toluene was poured to form a reaction mixture; and then the reaction flask was connected to a reflux condenser. After pumped and ventilated with nitrogen for three times, the reaction mixture was heated to 105° C. to react for 24 h. The reaction solution was directly spin-dried, and silica gel was dissolved and mixed with DCM. After the organic phase was chromatographed on silica gel, a small amount of solvent was spin-evaporated. The resulting compound was cooled and added with 100 mL of HEX, and then filtered to give a product. The yield was 45%. ¹H NMR (400 MHz, Chloroform-d) δ 10.67 (s, 2H), 7.85 (d, J=7.9 Hz, 2H), 7.41-7.31 (m, 2H), 7.28 (d, J=8.5 Hz, 2H), 7.26-7.20 (m, 2H), 7.16 (m, 2H), 6.87-6.76 (m, 2H).

### Synthesis of Compound (1d)

A three-necked reaction flask was baked with a baking gun for 0.5 h, and cooled down to room temperature, then nitrogen was introduced for evacuation and ventilation. THF was added to the system, and methylmagnesium bromide was injected with a syringe and stirred evenly. Under a nitrogen atmosphere, (1c) (4.0 g) was added to the reaction system and warmed to 45° C. for reaction for 1 h. After cooled down to room temperature, the reaction mixture was poured into a single-necked flask, directly spin-dried, and subjected to column separation. The spin-dried solid was beaten with 10 times the amount of methanol to give 8.7 g of product. The yield was 72%. ¹H NMR (400 MHz, Chloroform-d) δ 8.22 (s, 2H), 7.43 (d, J=8.1 Hz, 2H), 7.31 (d, J=7.8 Hz, 2H), 7.20 (t, J=7.7 Hz, 2H), 6.95 (dt, J=15.5, 7.8 Hz, 3H), 6.82 (d, J=8.2 Hz, 2H), 1.69 (s, 12H).

### Synthesis of Compound (1e)

(1d) (15.9 g) and acetic acid (170 mL) were added to a three-necked reaction flask, stirred and heated to 70° C. until completely dissolved: concentrated hydrochloric acid (65 mL) was slowly added to the system and reacted for 1 h. After cooled down to room temperature, the reaction system was added with 5 times the amount of deionized water, and then filtered with suction. The filter cake was mixed with silica gel for column separation. The resulting solid was recrystallized with dichloromethane and methanol to give 14.8 g of product. The yield was 78%. ¹H NMR (400 MHz, Chloroform-d) δ 7.39 (d, J=7.8 Hz, 2H), 7.31 (s, 1H), 7.17-7.07 (m, 2H), 6.98-6.89 (m, 2H), 6.80 (dt, J=7.9, 1.3 Hz, 2H), 6.64 (s, 2H), 1.59 (d, J=1.3 Hz, 12H).

### Synthesis of Compound (1f)

1e (6.0 g), Pd(OAc)₂ (0.36 g), P(t-Bu)₃BF₄ (2.4 g), and t-BuONa (6.0 g) were added to a 500 mL single-necked reaction flask to be pumped and ventilated three times: under a nitrogen atmosphere, 4-tert-butyl iodobenzene (10.2 g) and 300 mL of toluene were added, and then pumped and ventilated five times, heated to 115° C., and reacted for 24 h. When cooled down to room temperature, the reaction mixture was directly spin-dried and subjected to column separation. The resulting crude product was beaten with methanol and filtered, and the filter cake was dried to give 8.35 g of product. The yield was 75%. ¹H NMR (400 MHz, Chloroform-d) δ 7.65 (d, J=7.9 Hz, 2H), 7.49 (s, 1H), 7.45 (d, J=7.8 Hz, 2H), 7.32-7.12 (m, 8H), 7.04 (d, J=8.4 Hz, 4H), 1.56 (d, J=6.5 Hz, 12H), 1.35-1.19 (m, 18H).

### Synthesis of Compound (1)

After a 1000 mL three-necked flask, a dropping funnel, and a condenser were assembled, the flask was baked twice, then cooled down to room temperature; 1f (8.2 g) was added to the reaction flask, into which 250 mL of tert-butylbenzene was poured, followed by being pumped and ventilated three times; t-BuLi (30 mL, 1.3 M) was added to the dropping funnel with a syringe: and the system was placed at −40° C. and stirred for 0.5 h, and naturally was warmed to room temperature after t-BuLi was added dropwise, and then placed in an oil bath at 90° C. and reacted for 2 h. The reaction system was cooled down to room temperature and then cooled down to −30° C., and further warmed to room temperature after BBr₃ (4.5 mL) was added dropwise with a syringe, and stirred overnight. The system was cooled to 0° C. again, and warmed to room temperature after DIEA (13 mL) was added dropwise with a syringe, and then warmed to 120° C. and reacted for 24 h. When cooled down to room temperature, the reaction mixture was directly subjected to column separation, and the obtained sample was dissolved in DCM with the addition of methanol, and the resulting mixture was allowed to stand to precipitate a yellow powder, and then the power was filtered. The filter cake was baked at 100° C. for 5 h to give 1.5 of product. The yield was 20%. ¹H NMR (400 MHz, Chloroform-d) δ 8.77 (d, J=2.6 Hz, 2H), 8.09 (d, J=8.8 Hz, 2H), 7.80 (s, 1H), 7.75-7.62 (m, 4H), 7.61-7.54 (m, 2H), 7.18 (p, J=7.6 Hz, 4H), 1.56-1.51 (m, 18H), 1.28 (d, J=8.7 Hz, 12H).

### EXAMPLE 2

### Synthesis of Compound Structure 2

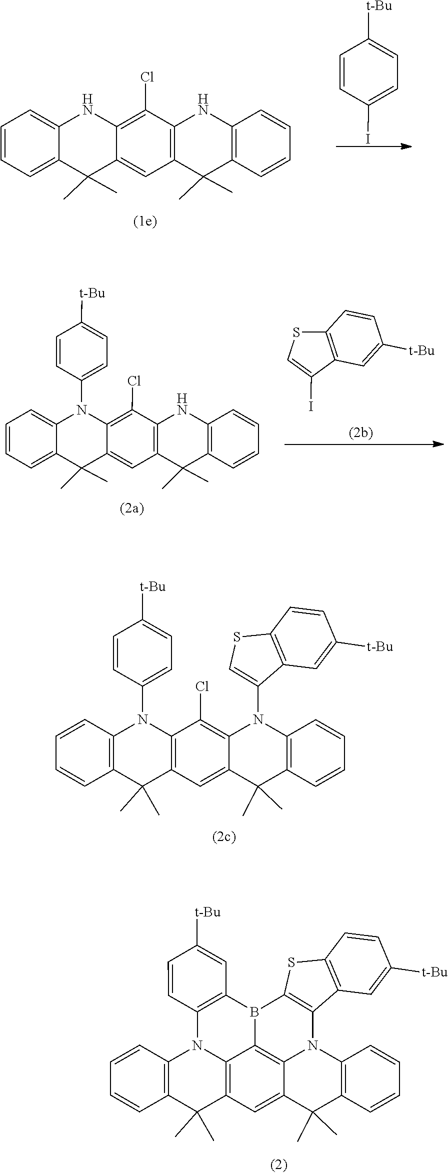 [SMILES: CC1(C)c2ccccc2Nc2c1cc1c(c2Cl)Nc2ccccc2C1(C)C ; CC(C)(C)c1ccc(I)cc1 ; CC(C)(C)c1ccc(N2c3ccccc3C(C)(C)c3cc4c(c(Cl)c32)Nc2ccccc2C4(C)C)cc1 ; CC(C)(C)c1ccc2scc(I)c2c1 ; CC(C)(C)c1ccc(N2c3ccccc3C(C)(C)c3cc4c(c(Cl)c32)N(c2csc3ccc(C(C)(C)C)cc23)c2ccccc2C4(C)C)cc1 ; CC(C)(C)c1ccc2c(c1)B1c3sc4ccc(C(C)(C)C)cc4c3N3c4ccccc4C(C)(C)c4cc5c(c1c43)N2c1ccccc1C5(C)C]

### Synthesis of Compound (2a)

1e (6.0 g), Pd(OAc)₂ (0.18 g), P(t-Bu)₃BF₄ (1.2 g) and t-BuONa (3.0 g) were added to a 500 mL single-necked flask to be pumped and ventilated three times; under a nitrogen atmosphere, 4-tert-butyl iodobenzene (5.1 g) and 300 mL of toluene were added, and pumped and ventilated five times, and warmed to 115° C. and reacted for 24 h. When cooled down to room temperature, the reaction mixture was directly subjected to column separation. The obtained crude product was beaten with methanol and filtered. The filter cake was dried to obtain 6.1 g of product. The yield was 75%. ¹H NMR (400 MHz, Chloroform-d) δ 7.65 (d, J=7.9 Hz, 1H), 7.49 (s, 1H), 7.45 (d, J=7.8 Hz, 1H), 7.32-7.12 (m, 6 H), 7.04 (d, J=8.4 Hz, 4H), 6.64 (s, 1H), 1.56 (d, J=6.5 Hz, 12H), 1.35-1.19 (m, 9H).

### Synthesis of Compound (2c)

2c (8.0 g), 2b (7.5 g), Pd(OAc)₂ (0.18 g), P(t-Bu)₃BF₄ (1.2 g) and t-BuONa (3.0 g) were added to a 500-mL single-necked flask to be pumped and ventilated three times; under a nitrogen atmosphere, 300 mL of toluene was added, pumped and ventilated five times, and warmed to 115° C. and reacted for 24 h. When cooled to room temperature, the reaction mixture was directly subjected to column separation to give 8.7 g of product. The yield was 79%. ¹H NMR (400 MHz, Chloroform-d) δ 7.65 (d, J=7.9 Hz, 1H), 7.49 (s, 1H), 7.45 (m, 2H), 7.32-7.12 (m, 8 H), 7.04 (m, 6H), 1.56 (d, J=6.5 Hz, 12H), 1.35-1.19 (m, 9H).

### Synthesis of Compound (2)

The synthesis method was the same as that for compound (1), and the feeding amounts were as follows: 2c (8.7 g), t-BuLi (34 mL), BBr₃ (5 mL), DIEA (15 mL), t-BuPh (300 mL). The product obtained was 2.1 g of yellow powder, and the yield was 25%. ¹H NMR (400 MHz, Chloroform-d) δ 8.6 (s, 1H), 8.09 (d, J=8.8 Hz, 2H), 7.80 (s, 1H), 7.75-7.62 (m, 5H), 7.61-7.54 (m, 2H), 7.18 (m, 4H), 1.56-1.51 (m, 18H), 1.28 (d, J=8.7 Hz, 12H).

### EXAMPLE 3

### Synthesis of Compound Structure 3

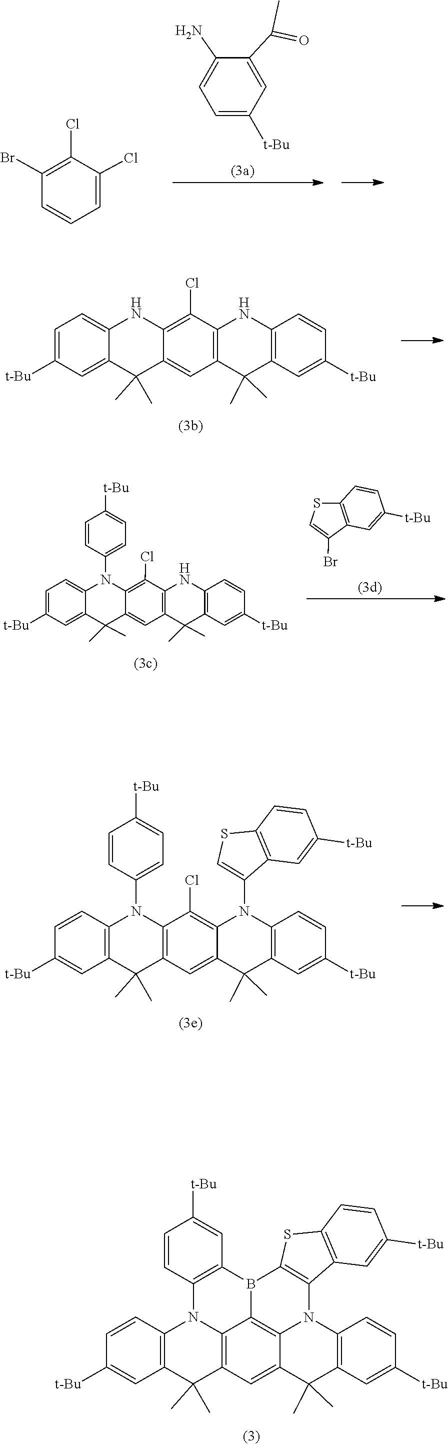

The synthesis method of compound (3b) was the same as that of compound (1e), except that the raw material (1b) was replaced by (3a). The synthesis method of compound (3) was the same as that of compound (2), except that the raw material (1e) was replaced by (3b). ¹H NMR (400 MHz, Chloroform-d) δ 8.6 (s, 1H), 8.09 (d, J=8.8 Hz, 2H), 7.80 (s, 1H), 7.75-7.62 (m, 3H), 7.61-7.54 (m, 2H), 7.18 (m, 4H), 1.56-1.51 (m, 36H), 1.28 (d, J=8.7 Hz, 12H).

### EXAMPLE 4

### Synthesis of Compound Structure 7

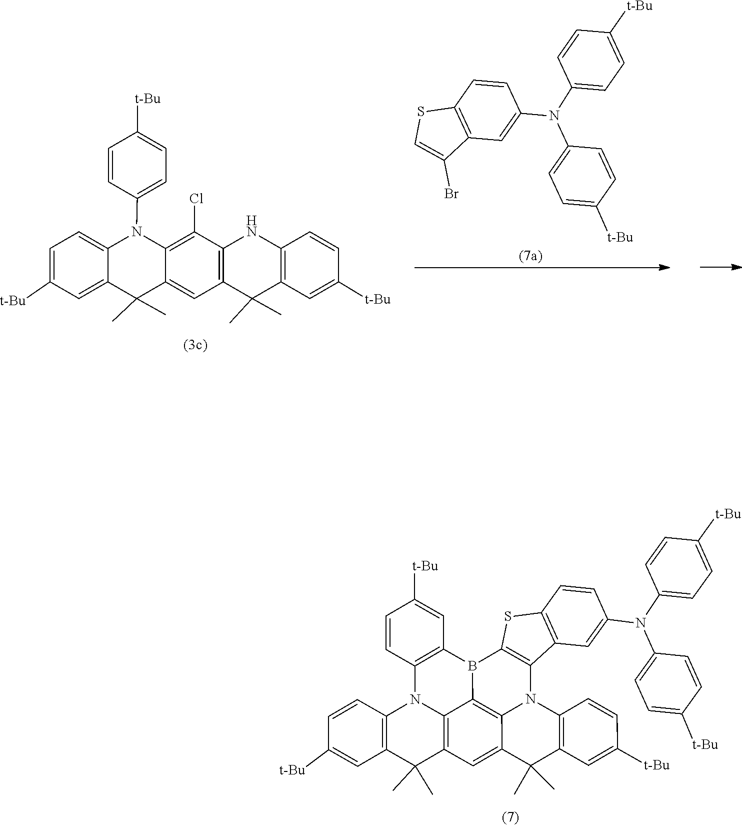 [SMILES: CC(C)(C)c1ccc(N2c3ccc(C(C)(C)C)cc3C(C)(C)c3cc4c(c(Cl)c32)Nc2ccc(C(C)(C)C)cc2C4(C)C)cc1 ; CC(C)(C)c1ccc(N(c2ccc(C(C)(C)C)cc2)c2ccc3scc(Br)c3c2)cc1 ; CC(C)(C)c1ccc(N(c2ccc(C(C)(C)C)cc2)c2ccc3sc4c(c3c2)N2c3ccc(C(C)(C)C)cc3C(C)(C)c3cc5c6c(c32)B4c2cc(C(C)(C)C)ccc2N6c2ccc(C(C)(C)C)cc2C5(C)C)cc1]

The synthesis method of compound (7) was the same as that of compound (3), except that the raw material (3d) was replaced by (7a). ¹H NMR (400 MHz, Chloroform-d) δ 8.6 (s, 1H), 8.09 (m, 3H), 7.80 (s, 1H), 7.75-7.62 (m, 8H), 7.61-7.54 (m, 4H), 7.18 (m, 4H), 1.56-1.51 (m, 36H), 1.28 (d, J=8.7 Hz, 12H).

### EXAMPLE 5

### Synthesis of Compound Structure 19

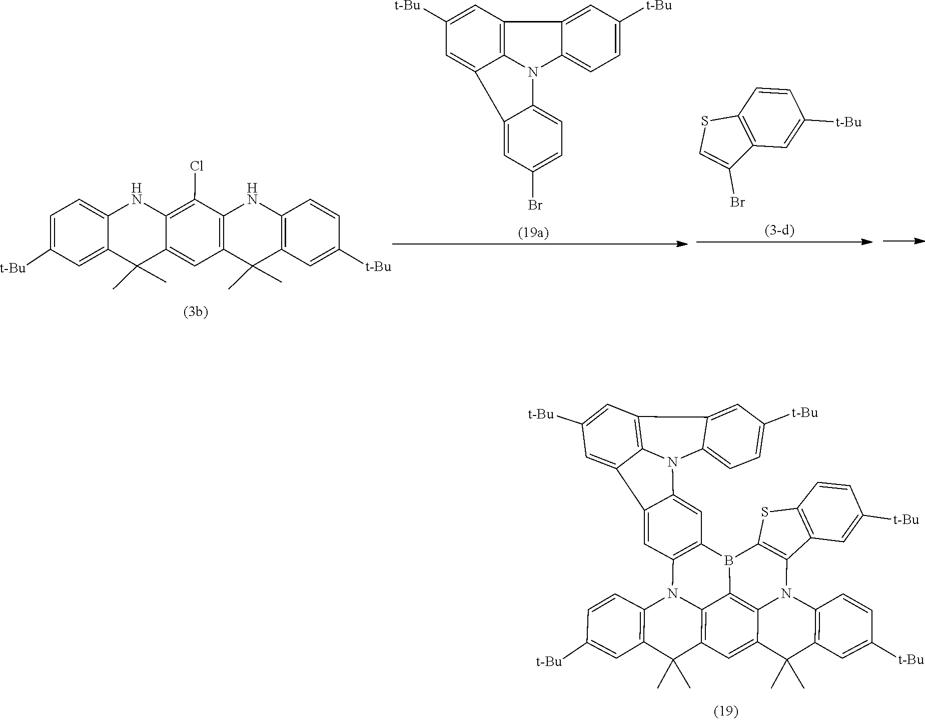 [SMILES: CC(C)(C)c1ccc2c(c1)C(C)(C)c1cc3c(c(Cl)c1N2)Nc1ccc(C(C)(C)C)cc1C3(C)C ; CC(C)(C)c1ccc2c(c1)c1cc(C(C)(C)C)cc3c4cc(Br)ccc4n2c31 ; CC(C)(C)c1ccc2scc(Br)c2c1 ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1sc2ccc(C(C)(C)C)cc2c1N4c1ccc(C(C)(C)C)cc1C3(C)C)c76]

The synthesis method of compound (19) was the same as that of compound (3), except that the raw material 4-tert-butyliodobenzene was replaced by (19a). ¹H NMR (400 MHZ, Chloroform-d) δ 8.6 (s, 1H), 8.09 (m, 2H), 7.80 (s, 1H), 7.75-7.62 (m, 6H), 7.61-7.54 (m, 4H), 7.18 (m, 3H), 1.56-1.51 (m, 36H), 1.28 (d, J=8.7 Hz, 12H).

### EXAMPLE 6

### Synthesis of Compound Structure 21

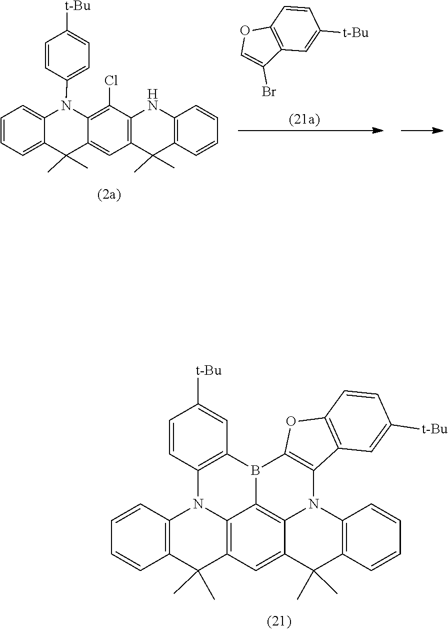 [SMILES: CC(C)(C)c1ccc(N2c3ccccc3C(C)(C)c3cc4c(c(Cl)c32)Nc2ccccc2C4(C)C)cc1 ; CC(C)(C)c1ccc2occ(Br)c2c1 ; CC(C)(C)c1ccc2c(c1)B1c3oc4ccc(C(C)(C)C)cc4c3N3c4ccccc4C(C)(C)c4cc5c(c1c43)N2c1ccccc1C5(C)C]

The synthesis method of compound (21) was the same as that of compound (2), except that the raw material (2b) was replaced by (21a). ¹H NMR (400 MHz, Chloroform-d) ¹H NMR (400 MHz, Chloroform-d) δ 8.6 (s, 1H), 8.07 (d, J=8.8 Hz, 2H), 7.80 (s, 1H), 7.78-7.58 (m, 5H), 7.58-7.51 (m, 2H), 7.12 (m, 4H), 1.56-1.51 (m, 18H), 1.28 (d, J=8.7 Hz, 12H).

### EXAMPLE 7

### Synthesis of Compound Structure 57

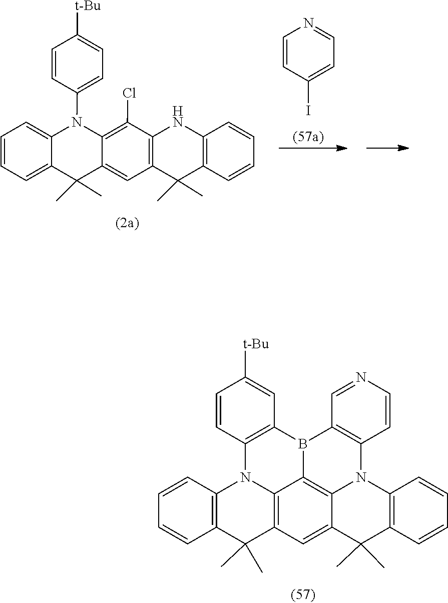 [SMILES: CC(C)(C)c1ccc(N2c3ccccc3C(C)(C)c3cc4c(c(Cl)c32)Nc2ccccc2C4(C)C)cc1 ; Ic1ccncc1 ; CC(C)(C)c1ccc2c(c1)B1c3cnccc3N3c4ccccc4C(C)(C)c4cc5c(c1c43)N2c1ccccc1C5(C)C]

The synthesis method of compound (57) was the same as that of compound (2), except that the raw material (2b) was replaced by (57a). ¹H NMR (400 MHz, Chloroform-d) ¹H NMR (400 MHz, Chloroform-d) δ 8.9 (s, 1H), 8.6 (s, 1H), 8.09 (m, 2H), 7.85 (s, 1H), 7.78-7.58 (m, 5H), 7.58-7.51 (m, 2H), 7.12 (m, 3H), 1.56-1.51 (m, 9H), 1.28 (d, J=8.7 Hz, 12H).

### EXAMPLE 8

### Synthesis of Compound Structure 97

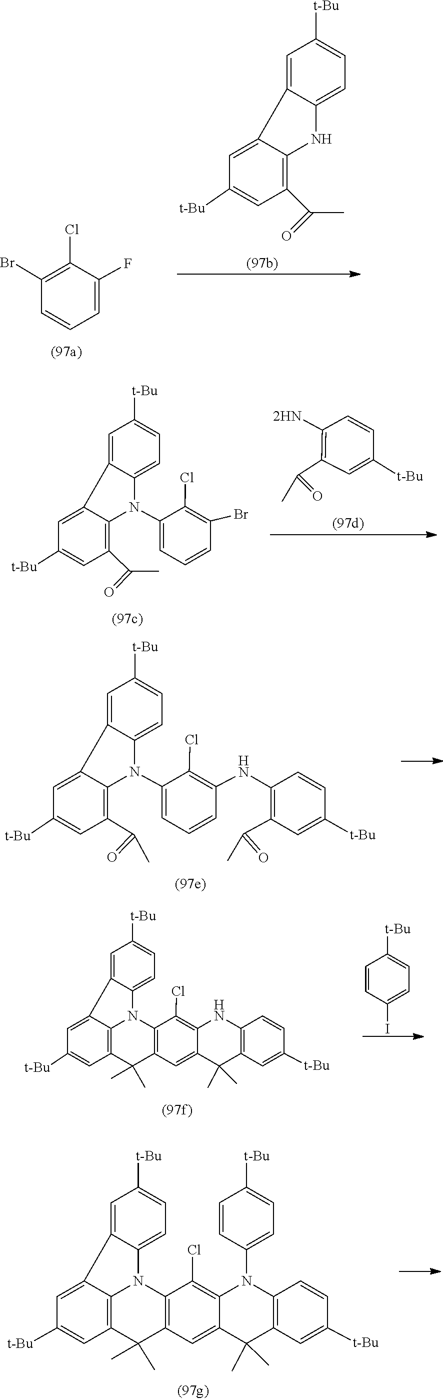

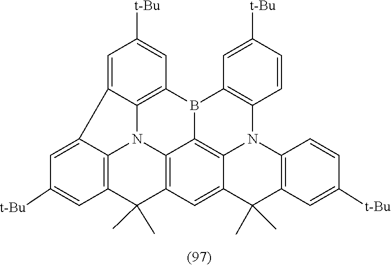 [SMILES: CC(C)(C)c1ccc2c(c1)B1c3c4c(cc5c3-n3c6c1cc(C(C)(C)C)cc6c1cc(C(C)(C)C)cc(c13)C5(C)C)C(C)(C)c1cc(C(C)(C)C)ccc1N24]

### Synthesis of Compound (97c)

(97) (15 g), NaH (2.0 g) and 200 mL of DMF were added to a 500 mL single-necked reaction flask, stirred, pumped and ventilated with nitrogen three times, and reacted for 0.5 h; then (97a) and (9.8 g) were added to the reaction solution for reaction at 100° C. for 12 h. The reaction solution was cooled down to room temperature with the addition of deionized water and filtered, and the filter cake was dried and subjected to column separation to give 20 g of product. The yield was 85%. ¹H NMR (400 MHz, Chloroform-d) δ 8.35 (d, J=2.1 Hz, 1H), 8.00 (d, J=2.5 Hz, 1H), 7.86 (d, J=7.9 Hz, 1H), 7.82 (d, J=2.0 Hz, 1H), 7.56 (dd, J=6.4, 1.3 Hz, 1H), 7.51 (dd, J=7.5, 1.1 Hz, 1H), 7.37 (dd, J=7.5, 6.2 Hz, 1H), 7.27 (dd, J=7.8, 2.5 Hz, 1H), 2.72 (s, 3H), 1.36 (m, J=13.2 Hz, 18H).

### Synthesis of Compound (97e)

(97c) (15 g), (97d) (5.7 g), Pd₂(dba)₃ (0.53 g), Brett-phos (0.78 g), Cs₂CO₃ (19.1 g) and magnetrons were added to a 1 L single-necked reaction flask, into which 450 mL of dry toluene was poured, and then the reaction flask was connected to a reflux condenser. After pumped and ventilated with nitrogen for three times, the reaction mixture was heated to 105° C. to react for 24 h. The reaction solution was directly spin-dried, and silica gel was dissolved and mixed with DCM. After the organic phase was chromatographed on silica gel, a small amount of solvent was spin-evaporated. The resulting compound was cooled and added with HEX, and filtered to give a product. The yield was 67%. ¹H NMR (400 MHz, Chloroform-d) δ 8.46 (s, 1H), 8.35 (m, 1H), 8.00 (d, J=2.5 Hz, 1H), 7.90-7.77 (m, 3H), 7.46 (m, 1H), 7.44-7.35 (m, 2H), 7.27 (m, 2H), 7.22 (d, J=7.5 Hz, 1H), 2.72 (s, 3H), 2.45 (s, 3H), 1.45-1.23 (m, 27H).

### Synthesis of Compound (97f)

A three-necked reaction flask was baked with a baking gun for 0.5 h, and cooled down to room temperature, then nitrogen was introduced for evacuation and ventilation. THF was added to the system, and methylmagnesium bromide (3 eq) was injected with a syringe and stirred evenly. Under a nitrogen atmosphere, (97e) (10.0 g) was added to the reaction system, warmed to 45° C., and reacted for 1 h. When cooled down to room temperature, the reaction mixture was poured into a single-necked flask, directly spin-dried, and subjected to column separation. The obtained solid was added to acetic acid (100 mL), stirred and heated to 70° C. until completely dissolved; concentrated hydrochloric acid (35 mL) was added to the system slowly and reacted for 1 h. When cooled down to room temperature, the reaction solution was added with 5 times the amount of deionized water for suction filtration. The filter cake was mixed with silica gel and subjected to column separation. The obtained solid was recrystallized with dichloromethane and methanol to give 7.1 g of product. The yield was 71%. ¹H NMR (400 MHz, Chloroform-d) δ 8.62 (s, 1H), 8.18 (d, J=2.1 Hz, 1H), 7.98 (m, H), 7.67 (m, 1H), 7.36 (d, J=2.2 Hz, 1H), 7.27-7.22 (m, 2H), 7.18 (m, 1H), 7.13 (s, 1H), 6.78 (m, 1H), 1.60 (m, 12H), 1.33 (m, 27H).

### Synthesis of Compound (97g)

The synthesis method of compound (97g) was the same as that of compound (2a), except that the raw material (97f) was replaced by (1e). ¹H NMR (400 MHz, Chloroform-d) δ 8.18 (d, J=2.1 Hz, 1H), 7.98 (m, 1H), 7.67 (m, 1H), 7.36 (d, J=2.2 Hz, 1H), 7.29-7.21 (m, 3H), 7.21-7.17 (m, 2H), 7.14 (s, 1H), 7.11-7.06 (m, 2H), 6.86 (d, J=5.9 Hz, 1H), 1.61 (d, J=5.9 Hz, 12H), 1.34 (d, J=6.0 Hz, 27H), 1.31 (s, 9H).

The synthesis method of compound (97) was the same as that of compound (1), except that the raw material (1f) was replaced by (97g). ¹H NMR (400 MHz, Chloroform-d) δ 8.76 (s, 1H), 8.19 (s, 1H), 7.50 (d, J=2.2 Hz, 1H), 7.41 (m, 1H), 7.30 (s, 1H), 7.25-7.16 (m, 4H), 7.05 (d, J=6.4 Hz, 1H), 6.88 (m, 1H), 1.63 (m, 12H), 1.40-1.24 (m, 36H).

### EXAMPLE 9

### Synthesis of Compound Structure 98

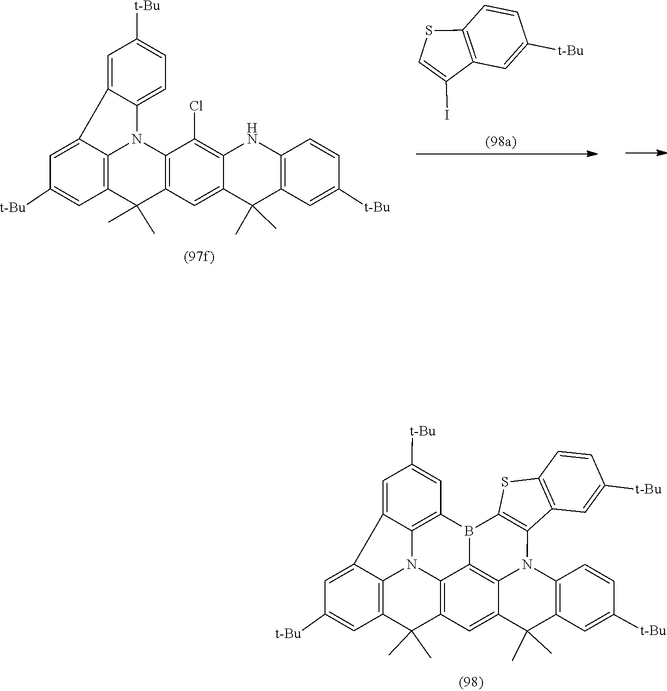 [SMILES: CC(C)(C)c1ccc2c(c1)C(C)(C)c1cc3c(c(Cl)c1N2)-n1c2ccc(C(C)(C)C)cc2c2cc(C(C)(C)C)cc(c21)C3(C)C ; CC(C)(C)c1ccc2scc(I)c2c1 ; CC(C)(C)c1ccc2c(c1)C(C)(C)c1cc3c4c5c1N2c1c(sc2ccc(C(C)(C)C)cc12)B5c1cc(C(C)(C)C)cc2c5cc(C(C)(C)C)cc(c5n-4c12)C3(C)C]

The synthesis method of compound (98) was the same as that of compound (97), except that the raw material 4-tert-butyliodobenzene was replaced by compound (98a). ¹H NMR (400 MHz, Chloroform-d) δ 8.76 (s, 1H), 8.19 (m, 1H), 7.82 (d, J=1.7 Hz, 1H), 7.73 (m, 1H), 7.50 (m, 1H), 7.36 (m, 1H), 7.32-7.25 (m, 2H), 7.18 (d, J=5.5 Hz, 2H), 6.92 (m, 1H), 1.61 (d, J=13.2 Hz, 12H), 1.38-1.30 (m, 36H).

### EXAMPLE 10

### Synthesis of Compound Structure 119

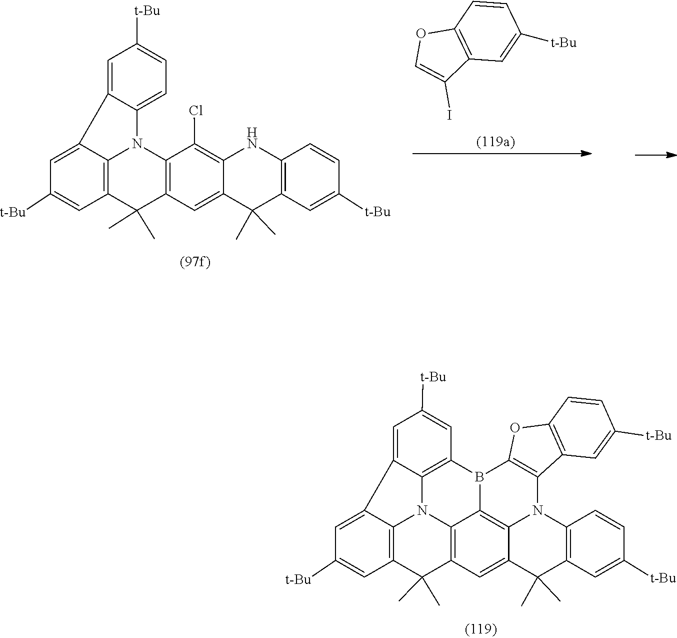 [SMILES: CC(C)(C)c1ccc2c(c1)C(C)(C)c1cc3c(c(Cl)c1N2)-n1c2ccc(C(C)(C)C)cc2c2cc(C(C)(C)C)cc(c21)C3(C)C ; CC(C)(C)c1ccc2occ(I)c2c1 ; CC(C)(C)c1ccc2c(c1)C(C)(C)c1cc3c4c5c1N2c1c(oc2ccc(C(C)(C)C)cc12)B5c1cc(C(C)(C)C)cc2c5cc(C(C)(C)C)cc(c5n-4c12)C3(C)C]

The synthesis method of compound (119) was the same as that of compound (97), except that the raw material 4-tert-butyliodobenzene was replaced by (119a). ¹H NMR (400 MHz, Chloroform-d) δ 8.766 (d, J=2.2 Hz, 1H), 8.10 (m, 1H), 7.69 (m, 1H), 7.50 (m, 1H), 7.37 (d, J=8.0 Hz, 1H), 7.33-7.26 (m, 2H), 7.22-7.15 (m, 3H), 6.97-6.88 (m, 1H), 1.61 (d, J=13.2 Hz, 12H), 1.42-1.23 (m, 36H).

Those skilled in the art should be aware that the aforementioned preparation methods are only illustrative examples and improvements can be made to obtain other compound structures of the present disclosure.

### EXAMPLE 11

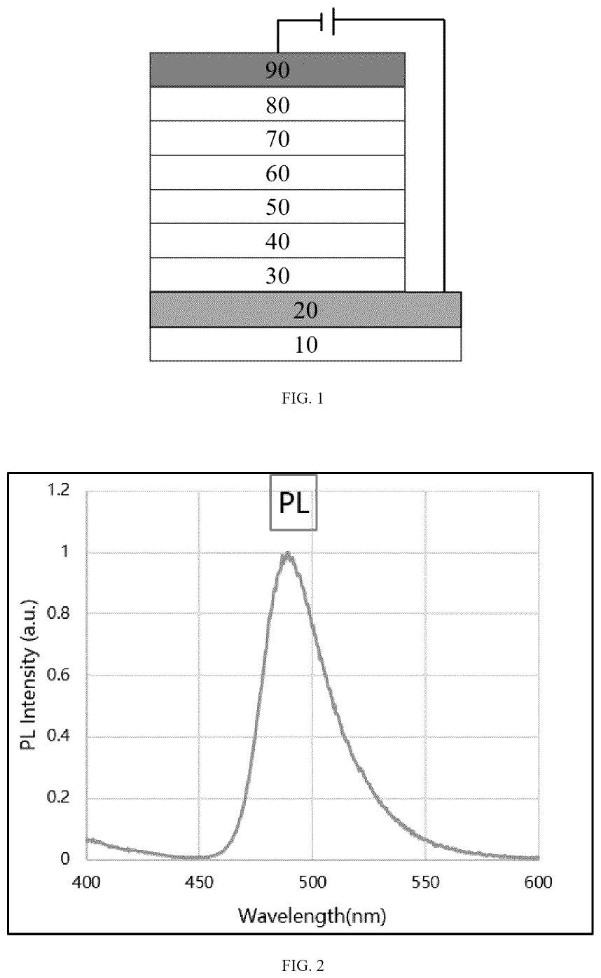

An organic electroluminescent bottom-emitting device was prepared using the organic electroluminescent material of the present disclosure, and the device structure was shown in FIG. 1. Firstly, a transparent conductive ITO glass substrate 10 (with an anode 20 thereon) was washed with deionized water, ethanol, acetone, and deionized water in sequence, dried at 80° C., and then treated with oxygen plasma for 30 min. Then, a 20 nm thick HATCN was evaporated in an evaporator under a vacuum of <4*10⁻⁴ Pa as a hole injection layer 30; a compound HTL was evaporated to form a 40 nm thick hole transport layer 40; a 10 nm thick EBL (an electron blocking layer) 50 was evaporated on the hole transport layer: then a 25 nm thick EML (a host material: a guest material=97:3%, an emission layer) 60 was evaporated, and the guest material in the emission layer was the compound structure (1) of the present disclosure; a 40 nm thick ETL (an electron transport layer) 70 was evaporated on the emission layer, and the electron transport layer was composed of two materials including ETL1 and LiQ. 1 nm metal ytterbium was evaporated as an electron injection layer 80 and 100 nm Ag was evaporated as a device cathode 90.

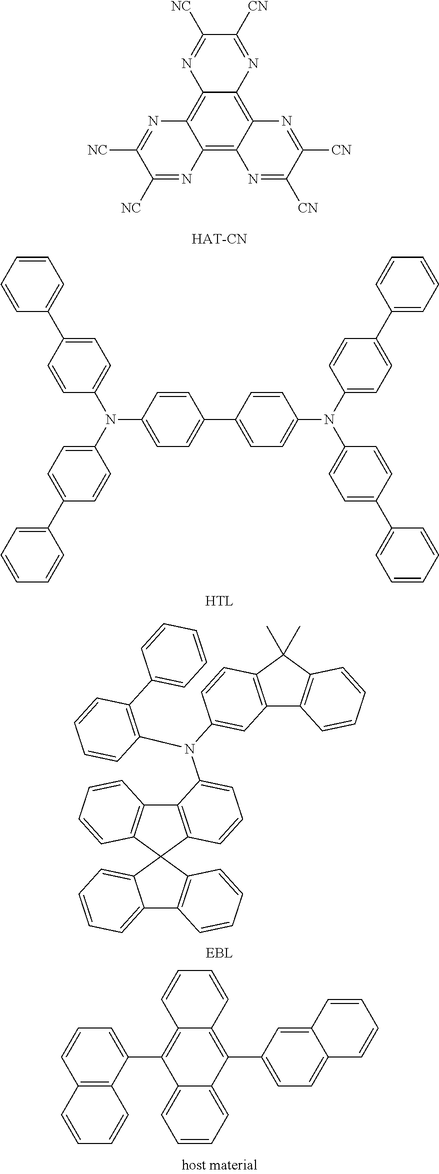

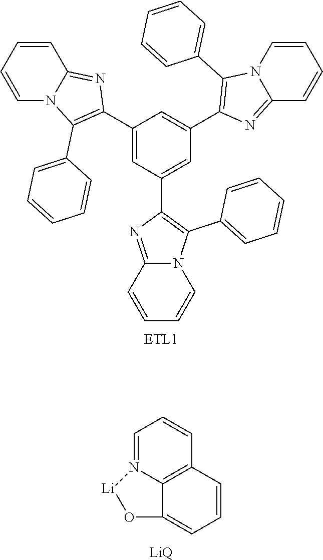

### EXAMPLES 12 TO 20 AND COMPARATIVE EXAMPLE 1

The organic electroluminescent devices of Examples 12 to 20 and Comparative Example 1 were made according to the same method as that of Example 11, with the difference that the guest materials in the emission layer were the compound structure 2, structure 3, structure 7, structure 19, structure 21, structure 57, structure 97, structure 98, structure 119 and Comparative Example 1 in the present disclosure, respectively.

The chemical structure of the material of Comparative Example 1 is shown in the figure below:

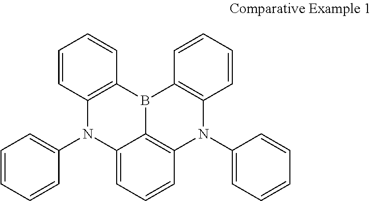 [SMILES: c1ccc(N2c3ccccc3B3c4ccccc4N(c4ccccc4)c4cccc2c43)cc1]

The F-2700 fluorescence spectrometer was used to test the fluorescence spectra of Examples 1 to 10 and Comparative Example 1. The results were as shown in Table 1:

TABLE 1

| | Maximum | Full-width |
|---|---|---|
| | luminescence | at half |
| No. | wavelength (nm) | maximum (nm) |
| Comparative Example 1 | 459 | 27 |
| Example 1 | 490 | 33 |
| Example 2 | 493 | 25 |
| Example 3 | 494 | 25 |
| Example 4 | 496 | 23 |
| Example 5 | 509 | 23 |
| Example 6 | 525 | 29 |
| Example 7 | 472 | 31 |
| Example 8 | 495 | 28 |
| Example 9 | 496 | 25 |
| Example 10 | 531 | 27 |

The electrical and optical properties of the electroluminescent devices of Examples 11 to 20 and Comparative Example 1 were measured at 0.4 mA, as shown in Table 2.

TABLE 2

| | | Current | Maximum | Full-width |
|---|---|---|---|---|
| | Voltage | efficiency | luminescence | at half |
| No. | (V) | (cd/A) | wavelength (nm) | maximum (nm) |
| Comparative | 3.2 | 4.1 | 463 | 33 |
| Example 1 | | | | |
| Example 11 | 3.1 | 6.7 | 500 | 35 |
| Example 12 | 3.2 | 9.2 | 501 | 28 |
| Example 13 | 3.2 | 8.9 | 501 | 28 |
| Example 14 | 3.2 | 8.5 | 505 | 25 |
| Example 15 | 3.2 | 8.7 | 504 | 24 |
| Example 16 | 3.3 | 7.9 | 537 | 32 |
| Example 17 | 3.3 | 7.1 | 515 | 30 |
| Example 18 | 3.2 | 7.5 | 516 | 25 |
| Example 19 | 3.2 | 9.9 | 552 | 23 |
| Example 20 | 3.1 | 9.7 | 545 | 30 |

As shown in Table 2, under the same conditions, when the organic electroluminescent material of the present disclosure was used in an organic electroluminescent device, the current efficiency was significantly higher than that of Comparative Example 1. Moreover, the device had a narrow full-width at half maximum, which was more conducive to improving the efficiency and color purity in the top-emitting device to achieve a better display effect. In addition, compared with Example 11, the asymmetric organic electroluminescent material of Examples 12 to 20 of the present disclosure had a higher current efficiency.

1. An organic electroluminescent material containing a B—N structure, having a structural formula as shown in formula (A) or (B): 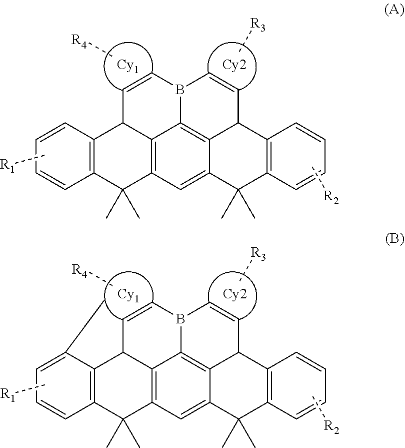
wherein Cy1 and Cy2 each are independently selected from an aryl group having 6-30 carbon atoms, or a substituted or unsubstituted heteroaryl group having 5-30 carbon atoms;
R₁ to R₄ each are independently selected from one of the substituents selected from the group consisting of hydrogen, deuterium, cyano, nitro, halogen, hydroxyl, alkylthio having 1 to 4 carbon atoms, alkyl having 1 to 30 carbon atoms, cycloalkyl having 1 to 20 carbon atoms, aryloxy having 6 to 30 carbon atoms, alkoxy having 1 to 30 carbon atoms, alkylamino having 1 to 30 carbon atoms, arylamino having 6 to 30 carbon atoms, arylamino having 6 to 30 carbon atoms, arylalkylamino having 6 to 30 carbon atoms, heteroarylamino having 2 to 24 carbon atoms, alkylsilyl having 1 to 30 carbon atoms, arylsilyl having 6 to 30 carbon atoms, alkenyl having 2 to 30 carbon atoms, alkynyl having 2 to 24 carbon atoms, arylalkyl having 7 to 30 carbon atoms, aryl having 6 to 30 carbon atoms, heteroaryl having 5 to 60 carbon atoms, or heteroarylalkyl having 6 to 30 carbon atoms, respectively; or R₁ to R₄ are connected to an aromatic ring skeleton by any one of a single bond, a substituted or unsubstituted alkyl chain having 1 to 30 carbon atoms, a substituted or unsubstituted alkylthio chain having 1 to 30 carbon atoms, a substituted or unsubstituted alkoxy chain having 1 to 30 carbon atoms, —C—C—, —C═C—, —C═N—, —C═P—, —C≡C—, 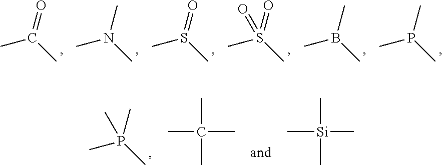
to form a ring,
the substitution is a substitution by halogen, C1-C4 alkyl, or C6-C10 aryl;
the heteroatom in the heteroaryl and heteroarylalkyl is at least one of O, S, N, P, Si, Se.

2. The organic electroluminescent material according to claim 1, wherein Cy1 and Cy2 each are independently selected from an aryl group having 6 to 20 carbon atoms, or a substituted or unsubstituted heteroaryl group having 5 to 20 carbon atoms;
R₁ to R₄ each are independently selected from one of the substituents selected from the group consisting of hydrogen, deuterium, cyano, nitro, halogen, alkyl having 1 to 10 carbon atoms, cycloalkyl having 1 to 20 carbon atoms, aryloxy having 6 to 20 carbon atoms, alkoxy having 1 to 10 carbon atoms, alkylamino having 1 to 10 carbon atoms, arylamino having 6 to 20 carbon atoms, arylamino having 6 to 20 carbon atoms, arylalkylamino having 6 to 20 carbon atoms, heteroarylamino having 2 to 20 carbon atoms, alkylsilyl having 1 to 10 carbon atoms, arylsilyl having 6 to 20 carbon atoms, alkenyl having 2 to 10 carbon atoms, alkynyl having 2 to 10 carbon atoms, arylalkyl having 7 to 20 carbon atoms, aryl having 6 to 20 carbon atoms, heteroaryl having 5 to 30 carbon atoms, or heteroarylalkyl having 6 to 20 carbon atoms, respectively, or R₁ to R₄ are connected to an aromatic ring skeleton by any one of a single bond, a substituted or unsubstituted alkyl chain having 1 to 30 carbon atoms, a substituted or unsubstituted alkylthio chain having 1 to 30 carbon atoms, a substituted or unsubstituted alkoxy chain having 1 to 30 carbon atoms, —C—C—, —C═C—, —C═N—, —C═P—, —C≡C—, 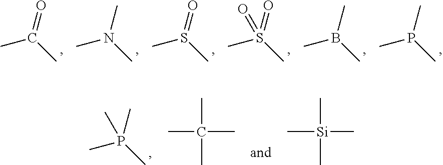
to form a ring.

3. The organic electroluminescent material according to claim 2, wherein the aryl group is selected from one or more of the group consisting of phenyl, naphthyl, anthracenyl, binaphthyl, phenanthrenyl, dihydrophenanthrene, pyrenyl, perylene, tetracene, pentacene, benzoperylene, benzocyclopentadienyl, spirofluorenyl and fluorenyl.

4. The organic electroluminescent material according to claim 2, wherein the heteroaryl group is selected from one of more of the group consisting of pyrrolyl, imidazolyl, thienyl, furanyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indole, isoindole, benzimidazole, naphthimidazole, phenanthroimidazole, benzotriazole, purine, benzoxazole, naphthoxazole, phenanthroxazole, benzothiadiazolyl, benzoselenadiazolyl, benzotriazolyl, quinolyl, isoquinolyl, benzopyrazinyl, benzothiophenyl, benzofuranyl, benzopyrrolyl, carbazolyl, acridinyl, dibenzothiophenyl, dibenzofuranyl, silyfluorenyl, dibenzothiophene-5,5-dioxy, naphthothiadiazolyl, naphthoselenadiazolyl and 10,15-dihydro-5H-diindolo[3,2-a: 3′,2′-c]carbazole.

5. The organic electroluminescent material according to claim 2, wherein R₁ to R₄ each are independently selected from the group consisting of hydrogen, deuterium, cyano, methyl, ethyl, propyl, butyl, 1-methylbutyl, 1-ethylbutyl, pentyl, hexyl, 1-methylpentyl, 2-methylpentyl, 4-methyl-2-pentyl, 3,3-dimethylbutyl, 2-ethylbutyl, heptyl, cyclopentyl, cyclohexyl, vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, methoxy, ethoxy, propoxy, isobutoxy, sec-butoxy, pentyloxy, isopentyloxy, hexyloxy, silyl, trimethylsilyl, triethylsilyl, triphenylsilyl, trimethoxysilyl, dimethoxyphenylsilyl, diphenylmethylsilyl, diphenylvinylsilyl, methylcyclobutylsilyl, dimethylfurylsilylphenyl, biphenyl, terphenyl, naphthyl, anthracenyl, phenanthrenyl, pyrenyl, perylene, tetraphenyl, fluorenyl, acenaphathcenyl, triphenylene, fluoranthenyl, thienyl, furanyl, pyrrolyl, imidazolyl, triazolyl, pyridyl, bipyridyl, pyrimidyl, triazinyl, acridinyl, pyridazinyl, pyrazinyl, quinolyl, quinazolinyl, quinoxalinyl, phthalazinyl, pyridopyrimidinyl, pyridopyrazinyl, pyrazinopyrazinyl, isoquinolyl, indolyl, carbazolyl, benzimidazolyl, benzothiazolyl, benzocarbazolyl, benzothiophenyl, dibenzothiophenyl, benzofuranyl, dibenzofuranyl, phenanthrolinyl, thiazolyl, isoxazolyl, thiadiazolyl and phenothiazinyl, respectively.

6. The organic electroluminescent material according to claim 1, wherein Cy1 and Cy2 are different, and R₃ and R₄ are not both hydrogen.

7. The organic electroluminescent material according to claim 6, wherein the structural formula thereof is as shown in one of formulas (A1) to (A6) and formulas (B1) to (B6): 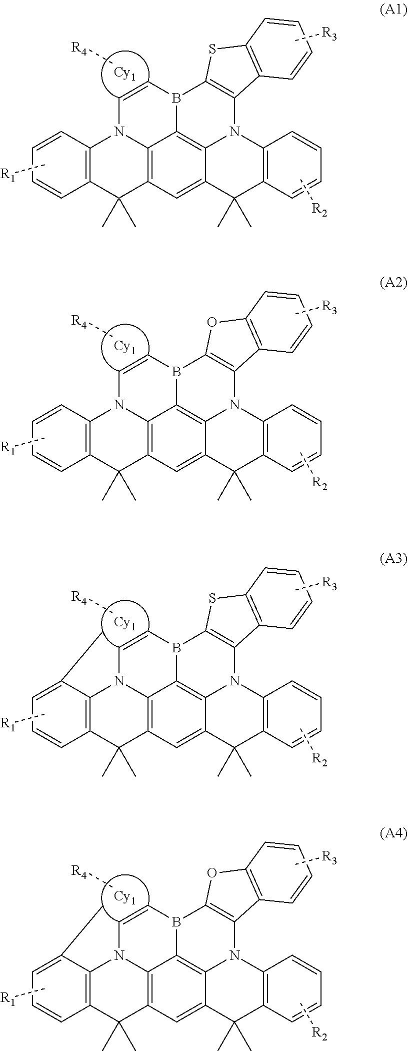 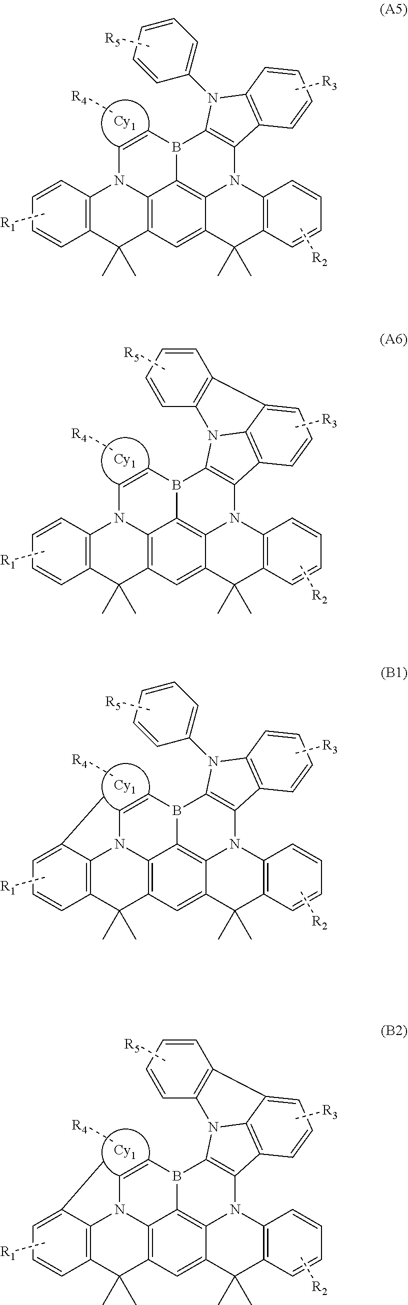 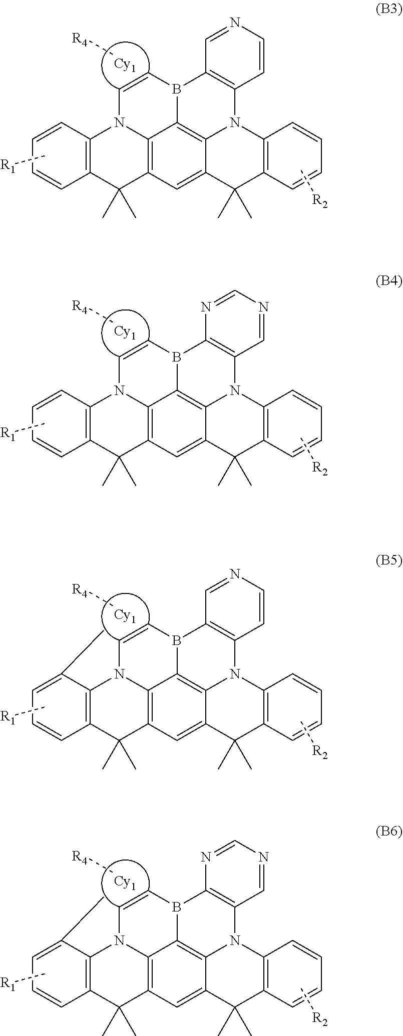
the definition of R₅ in the structural formulas (A1) to (A6) and (B1) to (B6) is the same as the definition of R₃ in the structural formulas (A) and (B).

8. The organic electroluminescent material according to claim 7, wherein R₁ to R₅ each are independently selected from one of the group consisting of a hydrogen atom, a deuterium atom, a fluorine atom, cyano, straight or branched C1-8 alkyl, C6-10 substituted or unsubstituted aryl, C5-20 substituted or unsubstituted heteroaryl, respectively, or R₁ to R₅ each are independently connected to an aromatic ring skeleton, respectively, to form a ring; a heteroatom in the heteroaryl group is selected from one or more of the group consisting of N, O or S, and the substitution in the aryl or heteroaryl group is a substitution by C1-C4 alkyl.

9. The organic electroluminescent material according to claim 7, wherein R₁ to R₅ each are independently selected from the group consisting of a hydrogen atom, a deuterium atom, straight or branched C1-4 alkyl, phenyl, naphthyl, carbazole, indolocarbazole, indole (3,2,1-JK) carbazole, respectively, or R₁ to R₅ each are independently connected to an aromatic ring skeleton, respectively, to form a ring.

10. The organic electroluminescent material according to claim 7, wherein Cy1 is independently selected from an aryl group having 6-10 carbon atoms, or a substituted or unsubstituted heteroaryl group having 5-10 carbon atoms; and wherein the heteroatom is N, S, or Se under the condition of Cy1 being a heteroaryl group.

11. The organic electroluminescent material according to claim 10, wherein Cy1 is independently selected from an aryl group having 6-10 carbon atoms.

12. The organic electroluminescent material according to claim 1, wherein the structure thereof is represented by one of the following formulas:

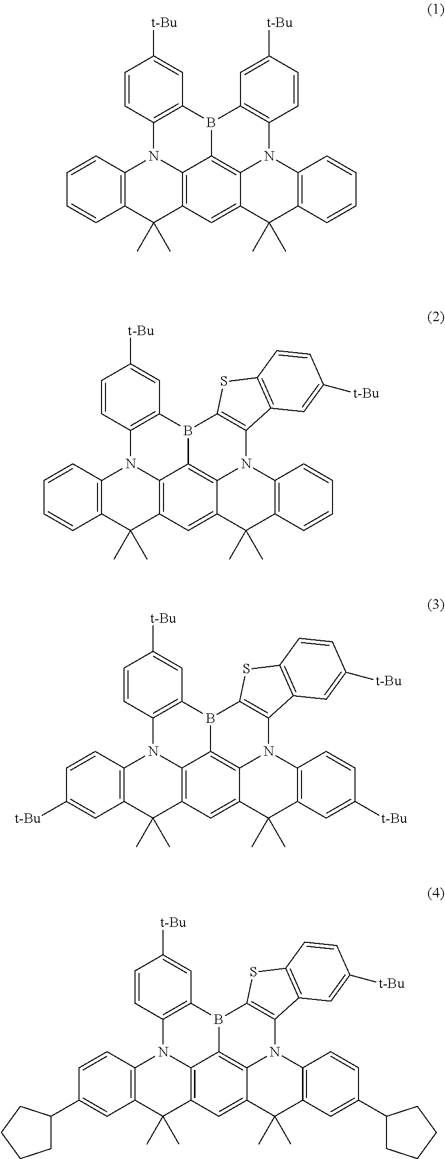 [SMILES: CC(C)(C)c1ccc2c(c1)B1c3cc(C(C)(C)C)ccc3N3c4ccccc4C(C)(C)c4cc5c(c1c43)N2c1ccccc1C5(C)C ; CC(C)(C)c1ccc2c(c1)B1c3sc4ccc(C(C)(C)C)cc4c3N3c4ccccc4C(C)(C)c4cc5c(c1c43)N2c1ccccc1C5(C)C ; CC(C)(C)c1ccc2c(c1)B1c3sc4ccc(C(C)(C)C)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3sc4ccc(C(C)(C)C)cc4c3N3c4ccc(C5CCCC5)cc4C(C)(C)c4cc5c(c1c43)N2c1ccc(C2CCCC2)cc1C5(C)C]

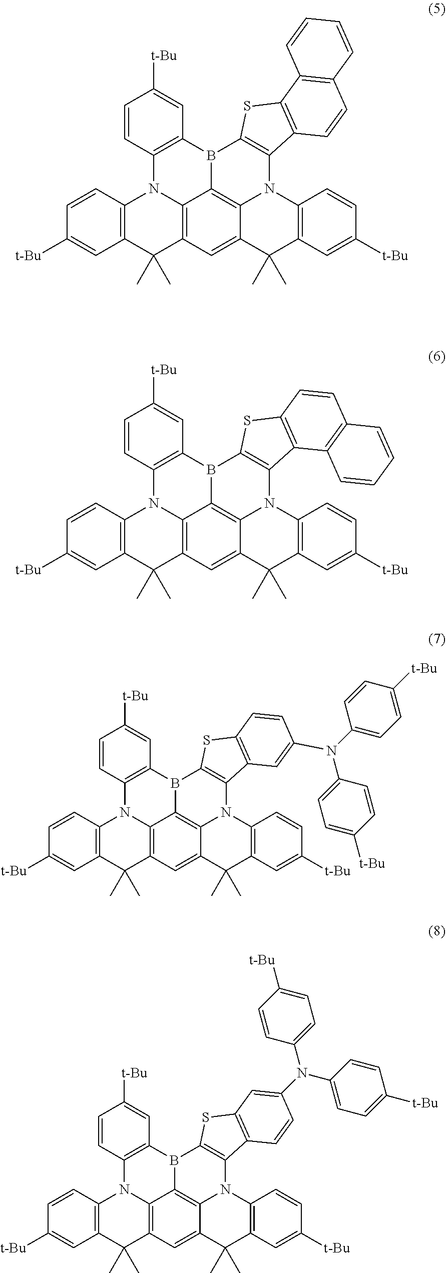

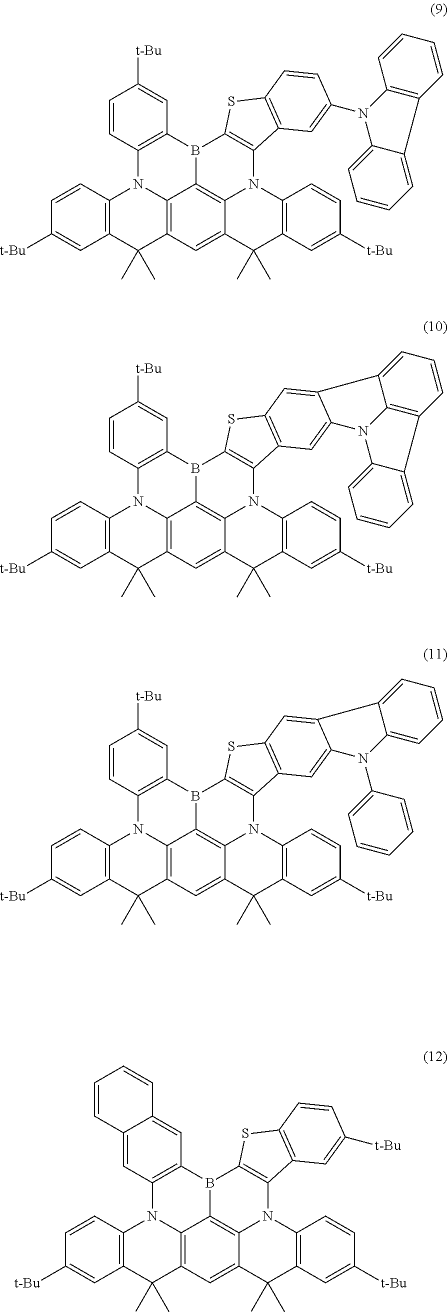 [SMILES: CC(C)(C)c1ccc2c(c1)B1c3sc4ccc(-n5c6ccccc6c6ccccc65)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3sc4cc5c6cccc7c8ccccc8n(c5cc4c3N3c4ccc(C(C)(C)C)cc4C(C)(C)c4cc5c(c1c43)N2c1ccc(C(C)(C)C)cc1C5(C)C)c76 ; CC(C)(C)c1ccc2c(c1)B1c3sc4cc5c6ccccc6n(-c6ccccc6)c5cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)C(C)(C)c1cc3c4c5c1N2c1cc2ccccc2cc1B5c1sc2ccc(C(C)(C)C)cc2c1N4c1ccc(C(C)(C)C)cc1C3(C)C]

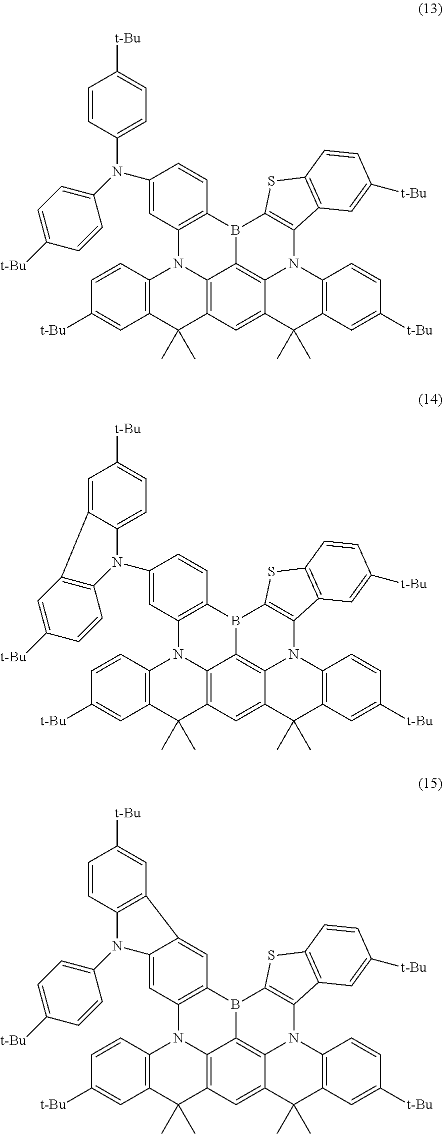 [SMILES: CC(C)(C)c1ccc(N(c2ccc(C(C)(C)C)cc2)c2ccc3c(c2)N2c4ccc(C(C)(C)C)cc4C(C)(C)c4cc5c6c(c42)B3c2sc3ccc(C(C)(C)C)cc3c2N6c2ccc(C(C)(C)C)cc2C5(C)C)cc1 ; CC(C)(C)c1ccc2c(c1)C(C)(C)c1cc3c4c5c1N2c1cc(-n2c6ccc(C(C)(C)C)cc6c6cc(C(C)(C)C)ccc62)ccc1B5c1sc2ccc(C(C)(C)C)cc2c1N4c1ccc(C(C)(C)C)cc1C3(C)C ; CC(C)(C)c1ccc(-n2c3ccc(C(C)(C)C)cc3c3cc4c(cc32)N2c3ccc(C(C)(C)C)cc3C(C)(C)c3cc5c6c(c32)B4c2sc3ccc(C(C)(C)C)cc3c2N6c2ccc(C(C)(C)C)cc2C5(C)C)cc1]

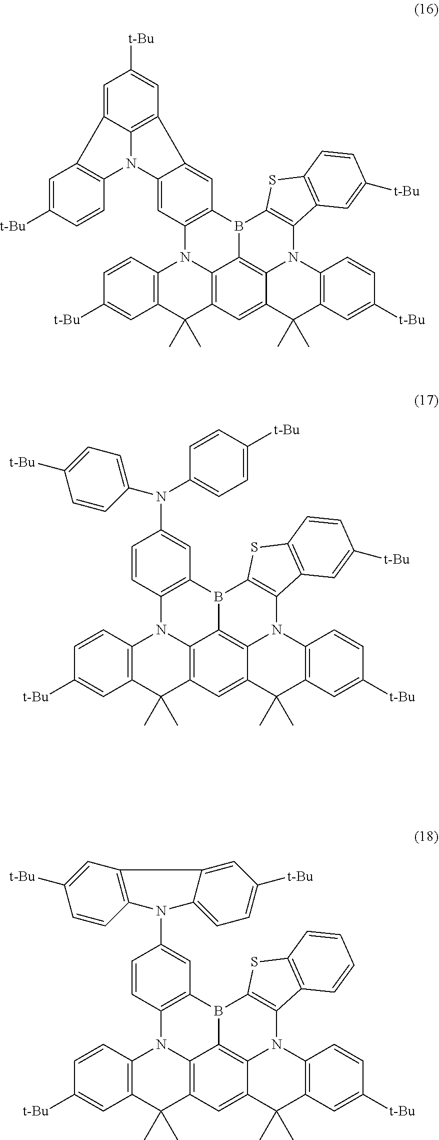 [SMILES: CC(C)(C)c1ccc2c(c1)C(C)(C)c1cc3c4c5c1N2c1cc2c(cc1B5c1sc5ccc(C(C)(C)C)cc5c1N4c1ccc(C(C)(C)C)cc1C3(C)C)c1cc(C(C)(C)C)cc3c4cc(C(C)(C)C)ccc4n2c31 ; CC(C)(C)c1ccc(N(c2ccc(C(C)(C)C)cc2)c2ccc3c(c2)B2c4sc5ccc(C(C)(C)C)cc5c4N4c5ccc(C(C)(C)C)cc5C(C)(C)c5cc6c(c2c54)N3c2ccc(C(C)(C)C)cc2C6(C)C)cc1 ; CC(C)(C)c1ccc2c(c1)C(C)(C)c1cc3c4c5c1N2c1ccc(-n2c6ccc(C(C)(C)C)cc6c6cc(C(C)(C)C)ccc62)cc1B5c1sc2ccccc2c1N4c1ccc(C(C)(C)C)cc1C3(C)C]

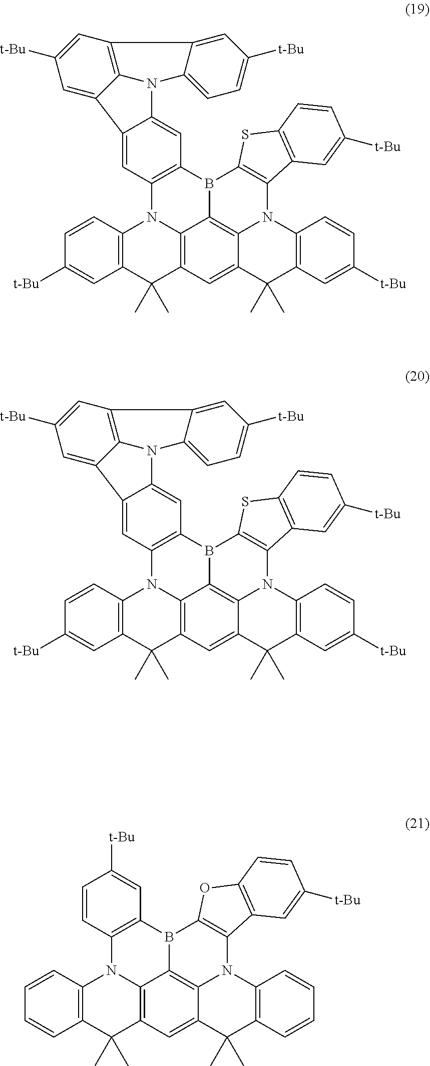 [SMILES: CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1sc2ccc(C(C)(C)C)cc2c1N4c1ccc(C(C)(C)C)cc1C3(C)C)c76 ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1sc2ccc(C(C)(C)C)cc2c1N4c1ccc(C(C)(C)C)cc1C3(C)C)c76 ; CC(C)(C)c1ccc2c(c1)B1c3oc4ccc(C(C)(C)C)cc4c3N3c4ccccc4C(C)(C)c4cc5c(c1c43)N2c1ccccc1C5(C)C]

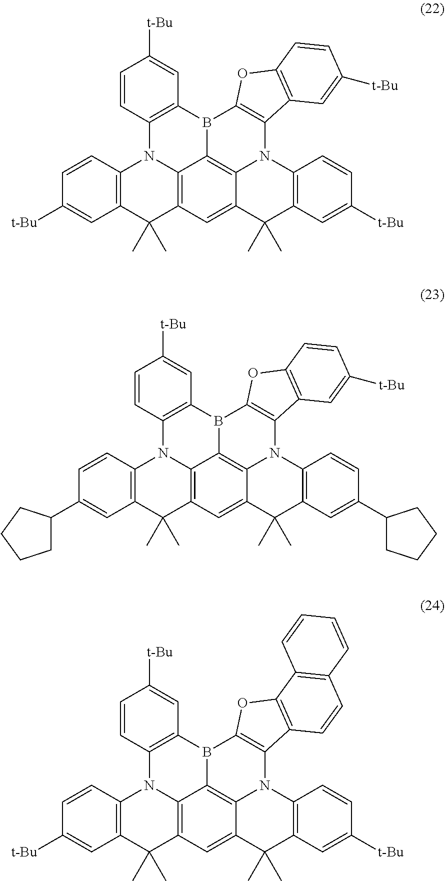 [SMILES: CC(C)(C)c1ccc2c(c1)B1c3oc4ccc(C(C)(C)C)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3oc4ccc(C(C)(C)C)cc4c3N3c4ccc(C5CCCC5)cc4C(C)(C)c4cc5c(c1c43)N2c1ccc(C2CCCC2)cc1C5(C)C ; CC(C)(C)c1ccc2c(c1)B1c3oc4c(ccc5ccccc54)c3N3c4ccc(C(C)(C)C)cc4C(C)(C)c4cc5c(c1c43)N2c1ccc(C(C)(C)C)cc1C5(C)C]

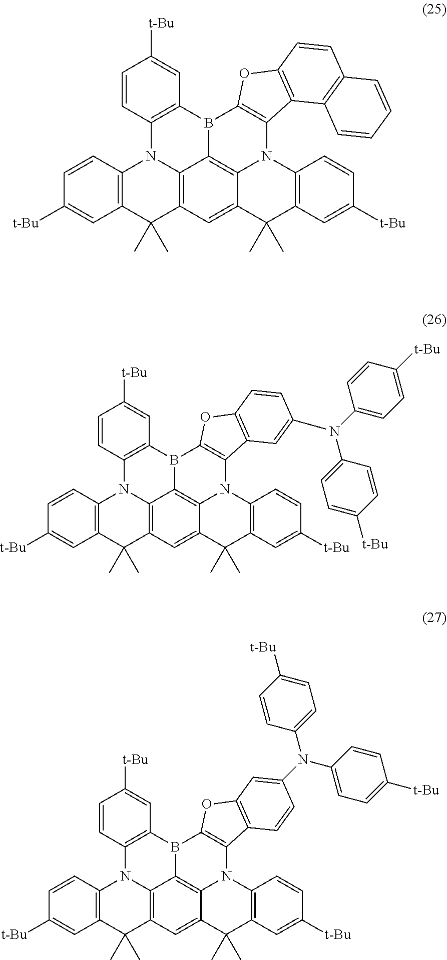 [SMILES: CC(C)(C)c1ccc2c(c1)B1c3oc4ccc5ccccc5c4c3N3c4ccc(C(C)(C)C)cc4C(C)(C)c4cc5c(c1c43)N2c1ccc(C(C)(C)C)cc1C5(C)C ; CC(C)(C)c1ccc(N(c2ccc(C(C)(C)C)cc2)c2ccc3oc4c(c3c2)N2c3ccc(C(C)(C)C)cc3C(C)(C)c3cc5c6c(c32)B4c2cc(C(C)(C)C)ccc2N6c2ccc(C(C)(C)C)cc2C5(C)C)cc1 ; CC(C)(C)c1ccc(N(c2ccc(C(C)(C)C)cc2)c2ccc3c4c(oc3c2)B2c3cc(C(C)(C)C)ccc3N3c5ccc(C(C)(C)C)cc5C(C)(C)c5cc6c(c2c53)N4c2ccc(C(C)(C)C)cc2C6(C)C)cc1]

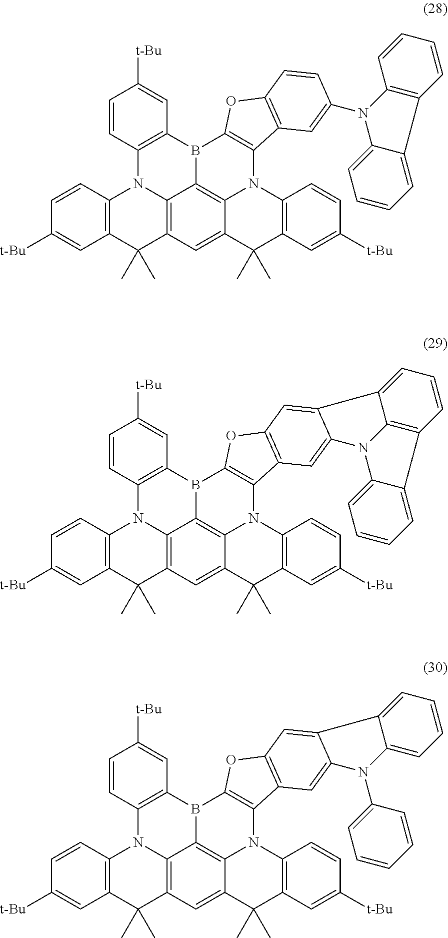 [SMILES: CC(C)(C)c1ccc2c(c1)B1c3oc4ccc(-n5c6ccccc6c6ccccc65)cc4c3N3c4ccc(C(C)(C)C)cc4C(C)(C)c4cc5c(c1c43)N2c1ccc(C(C)(C)C)cc1C5(C)C ; CC(C)(C)c1ccc2c(c1)B1c3oc4cc5c6cccc7c8ccccc8n(c5cc4c3N3c4ccc(C(C)(C)C)cc4C(C)(C)c4cc5c(c1c43)N2c1ccc(C(C)(C)C)cc1C5(C)C)c76 ; CC(C)(C)c1ccc2c(c1)B1c3oc4cc5c6ccccc6n(-c6ccccc6)c5cc4c3N3c4ccc(C(C)(C)C)cc4C(C)(C)c4cc5c(c1c43)N2c1ccc(C(C)(C)C)cc1C5(C)C]

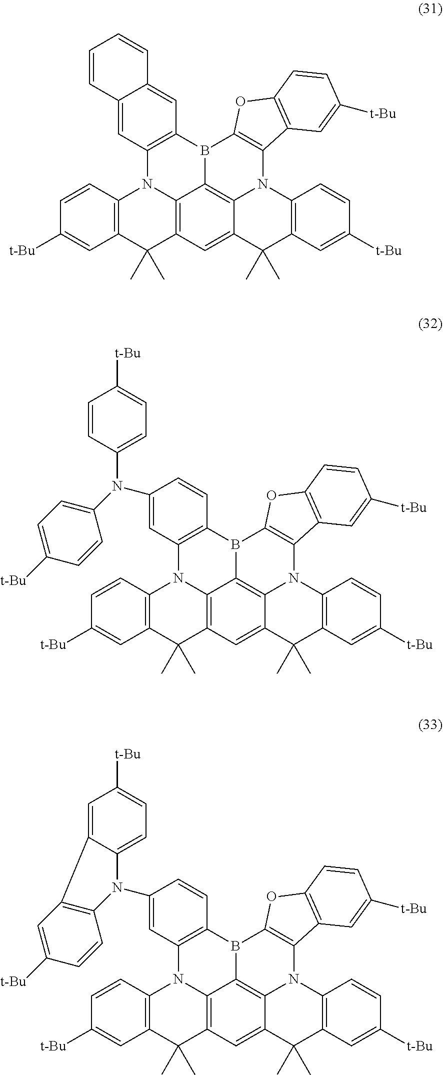 [SMILES: CC(C)(C)c1ccc2c(c1)C(C)(C)c1cc3c4c5c1N2c1cc2ccccc2cc1B5c1oc2ccc(C(C)(C)C)cc2c1N4c1ccc(C(C)(C)C)cc1C3(C)C ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2oc3ccc(C(C)(C)C)cc3c2N6c2ccc(C(C)(C)C)cc2C5(C)C)cc1 ; CC(C)(C)c1ccc2c(c1)C(C)(C)c1cc3c4c5c1N2c1cc(-n2c6ccc(C(C)(C)C)cc6c6cc(C(C)(C)C)ccc62)ccc1B5c1oc2ccc(C(C)(C)C)cc2c1N4c1ccc(C(C)(C)C)cc1C3(C)C]

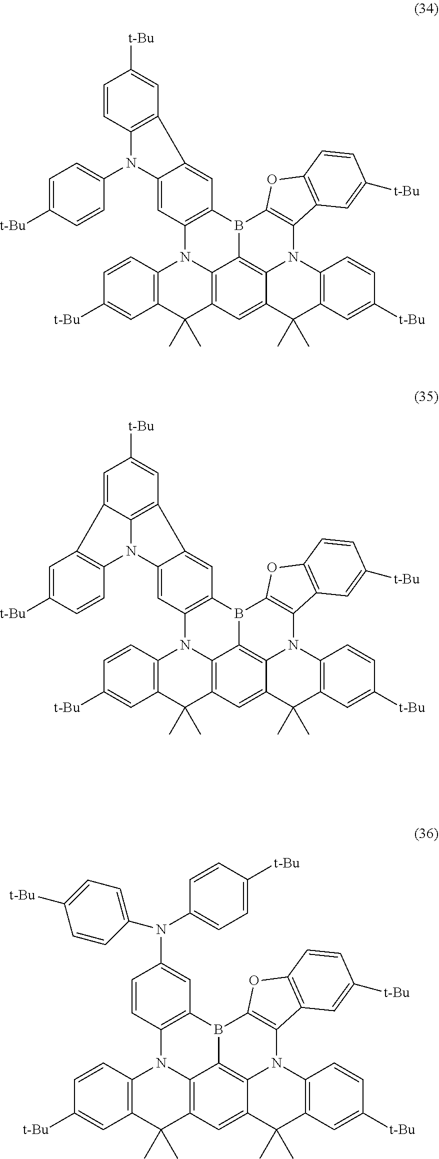 [SMILES: CC(C)(C)c1ccc(-n2c3ccc(C(C)(C)C)cc3c3cc4c(cc32)N2c3ccc(C(C)(C)C)cc3C(C)(C)c3cc5c6c(c32)B4c2oc3ccc(C(C)(C)C)cc3c2N6c2ccc(C(C)(C)C)cc2C5(C)C)cc1 ; CC(C)(C)c1ccc2c(c1)C(C)(C)c1cc3c4c5c1N2c1cc2c(cc1B5c1oc5ccc(C(C)(C)C)cc5c1N4c1ccc(C(C)(C)C)cc1C3(C)C)c1cc(C(C)(C)C)cc3c4cc(C(C)(C)C)ccc4n2c31 ; CC(C)(C)c1ccc(N(c2ccc(C(C)(C)C)cc2)c2ccc3c(c2)B2c4oc5ccc(C(C)(C)C)cc5c4N4c5ccc(C(C)(C)C)cc5C(C)(C)c5cc6c(c2c54)N3c2ccc(C(C)(C)C)cc2C6(C)C)cc1]

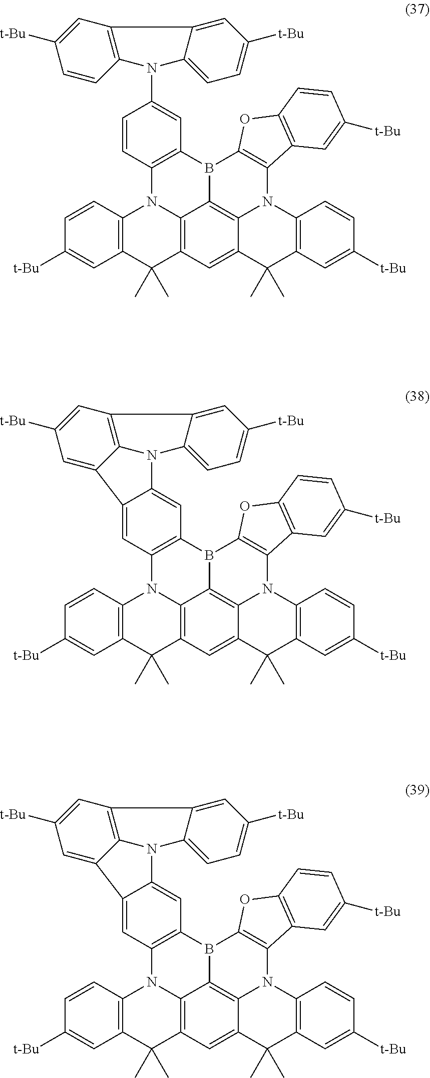 [SMILES: CC(C)(C)c1ccc2c(c1)C(C)(C)c1cc3c4c5c1N2c1ccc(-n2c6ccc(C(C)(C)C)cc6c6cc(C(C)(C)C)ccc62)cc1B5c1oc2ccc(C(C)(C)C)cc2c1N4c1ccc(C(C)(C)C)cc1C3(C)C ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1oc2ccc(C(C)(C)C)cc2c1N4c1ccc(C(C)(C)C)cc1C3(C)C)c76 ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1oc2ccc(C(C)(C)C)cc2c1N4c1ccc(C(C)(C)C)cc1C3(C)C)c76]

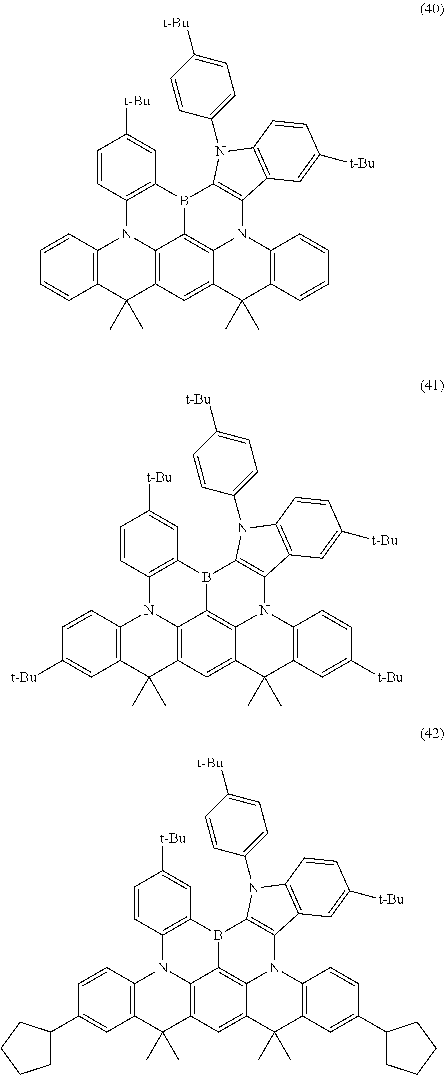 [SMILES: CC(C)(C)c1ccc(-n2c3c(c4cc(C(C)(C)C)ccc42)N2c4ccccc4C(C)(C)c4cc5c6c(c42)B3c2cc(C(C)(C)C)ccc2N6c2ccccc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4cc(C(C)(C)C)ccc42)N2c4ccc(C5CCCC5)cc4C(C)(C)c4cc5c6c(c42)B3c2cc(C(C)(C)C)ccc2N6c2ccc(C3CCCC3)cc2C5(C)C)cc1]

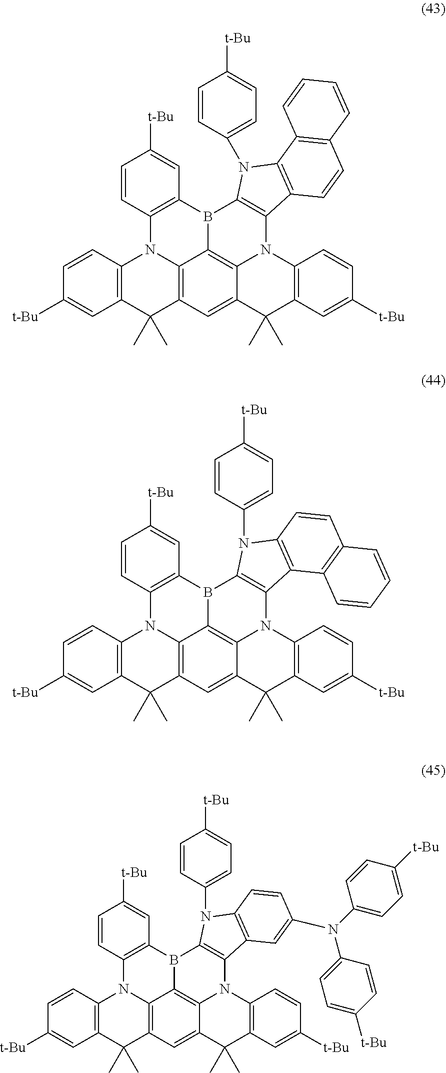 [SMILES: CC(C)(C)c1ccc(-n2c3c(c4ccc5ccccc5c42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4c5ccccc5ccc42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(N(c2ccc(C(C)(C)C)cc2)c2ccc3c(c2)c2c(n3-c3ccc(C(C)(C)C)cc3)B3c4cc(C(C)(C)C)ccc4N4c5ccc(C(C)(C)C)cc5C(C)(C)c5cc6c(c3c54)N2c2ccc(C(C)(C)C)cc2C6(C)C)cc1]

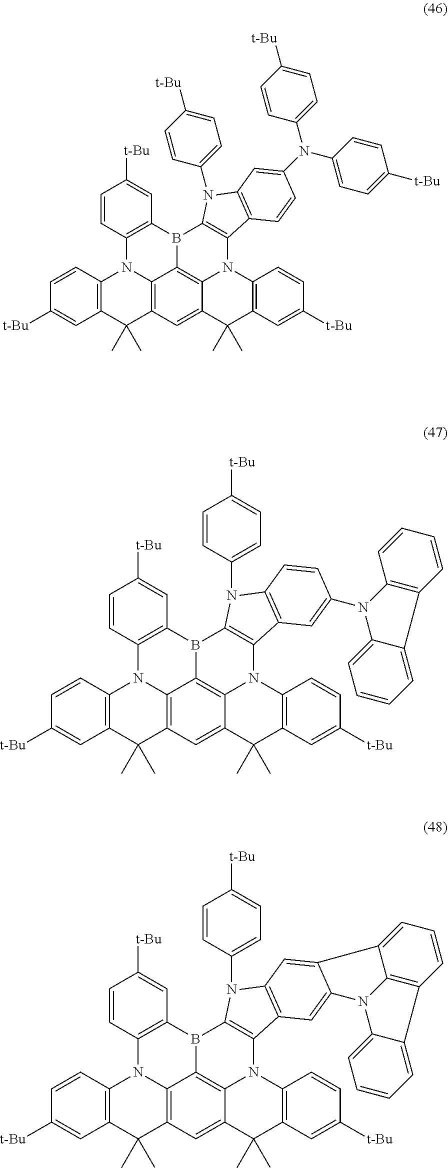 [SMILES: CC(C)(C)c1ccc(N(c2ccc(C(C)(C)C)cc2)c2ccc3c4c(n(-c5ccc(C(C)(C)C)cc5)c3c2)B2c3cc(C(C)(C)C)ccc3N3c5ccc(C(C)(C)C)cc5C(C)(C)c5cc6c(c2c53)N4c2ccc(C(C)(C)C)cc2C6(C)C)cc1 ; CC(C)(C)c1ccc(-n2c3c(c4cc(-n5c6ccccc6c6ccccc65)ccc42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4cc5c(cc42)c2cccc4c6ccccc6n5c42)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1]

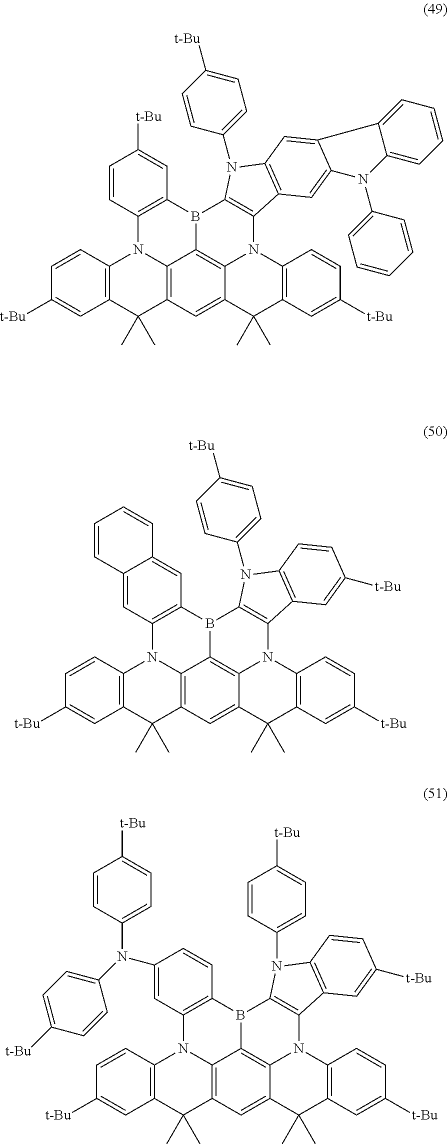 [SMILES: CC(C)(C)c1ccc(-n2c3c(c4cc5c(cc42)c2ccccc2n5-c2ccccc2)N2c4ccc(C(C)(C)C)cc4C(C)(C)c4cc5c6c(c42)B3c2cc(C(C)(C)C)ccc2N6c2ccc(C(C)(C)C)cc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc3ccccc3cc2N6c2ccc(C(C)(C)C)cc2C5(C)C)cc1 ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2c(c3cc(C(C)(C)C)ccc3n2-c2ccc(C(C)(C)C)cc2)N6c2ccc(C(C)(C)C)cc2C5(C)C)cc1]

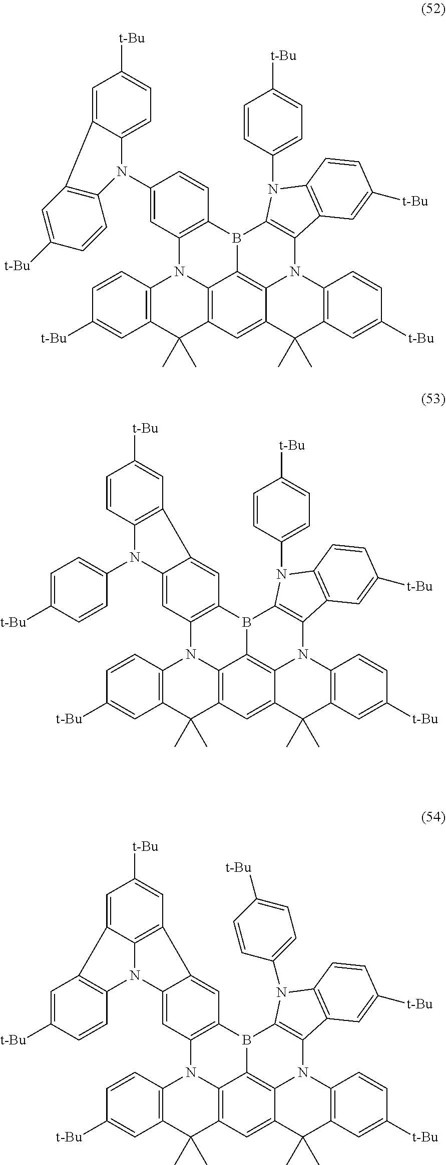 [SMILES: CC(C)(C)c1ccc(-n2c3c(c4cc(C(C)(C)C)ccc42)N2c4ccc(C(C)(C)C)cc4C(C)(C)c4cc5c6c(c42)B3c2ccc(-n3c4ccc(C(C)(C)C)cc4c4cc(C(C)(C)C)ccc43)cc2N6c2ccc(C(C)(C)C)cc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc3c4cc(C(C)(C)C)ccc4n(-c4ccc(C(C)(C)C)cc4)c3cc2N6c2ccc(C(C)(C)C)cc2C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc3c4cc(C(C)(C)C)cc7c8cc(C(C)(C)C)ccc8n(c3cc2N6c2ccc(C(C)(C)C)cc2C5(C)C)c74)cc1]

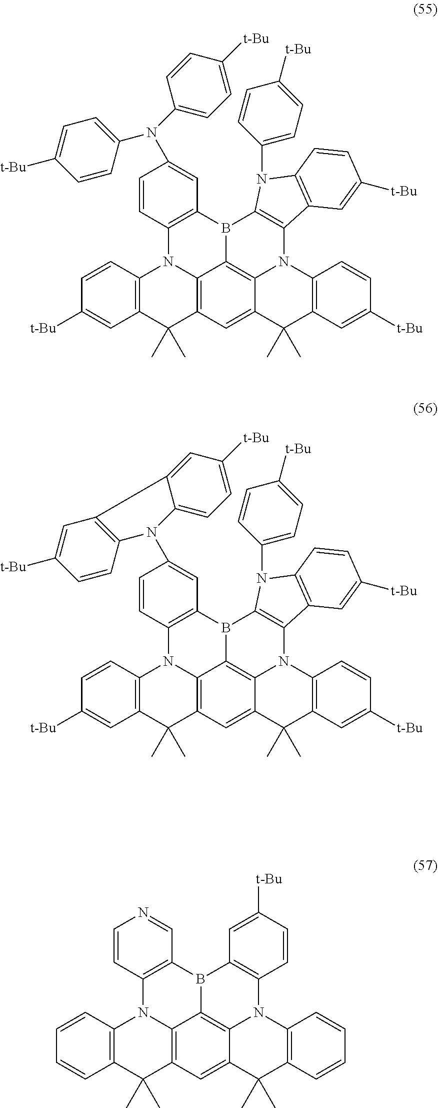 [SMILES: CC(C)(C)c1ccc(N(c2ccc(C(C)(C)C)cc2)c2ccc3c(c2)B2c4c5c(cc6c4N(c4ccc(C(C)(C)C)cc4C6(C)C)c4c2n(-c2ccc(C(C)(C)C)cc2)c2ccc(C(C)(C)C)cc42)C(C)(C)c2cc(C(C)(C)C)ccc2N35)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2cc(-n3c4ccc(C(C)(C)C)cc4c4cc(C(C)(C)C)ccc43)ccc2N6c2ccc(C(C)(C)C)cc2C5(C)C)cc1 ; CC(C)(C)c1ccc2c(c1)B1c3cnccc3N3c4ccccc4C(C)(C)c4cc5c(c1c43)N2c1ccccc1C5(C)C]

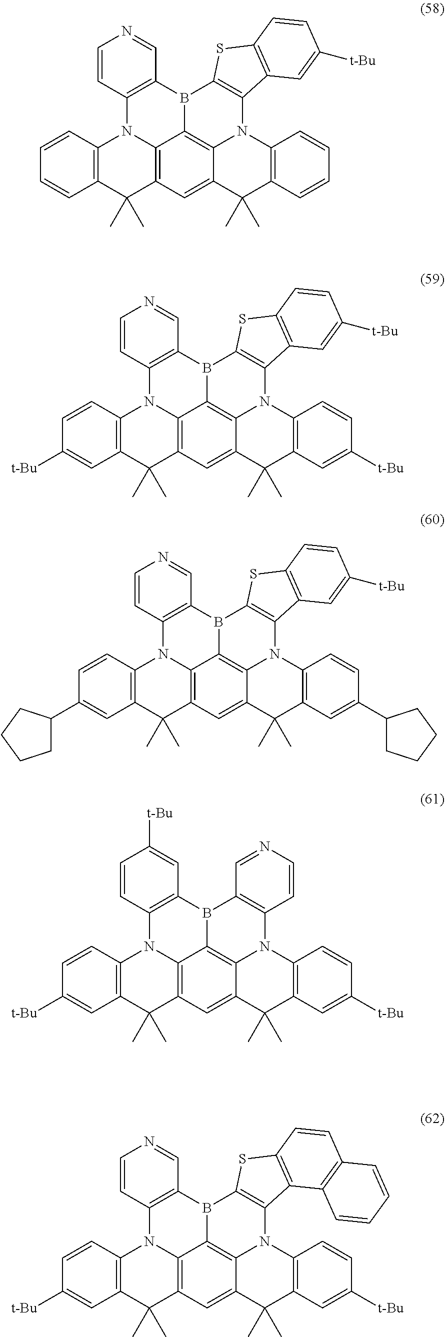 [SMILES: CC(C)(C)c1ccc2sc3c(c2c1)N1c2ccccc2C(C)(C)c2cc4c5c(c21)B3c1cnccc1N5c1ccccc1C4(C)C ; CC(C)(C)c1ccc2c(c1)C(C)(C)c1cc3c4c5c1N2c1ccncc1B5c1sc2ccc(C(C)(C)C)cc2c1N4c1ccc(C(C)(C)C)cc1C3(C)C ; CC(C)(C)c1ccc2sc3c(c2c1)N1c2ccc(C4CCCC4)cc2C(C)(C)c2cc4c5c(c21)B3c1cnccc1N5c1ccc(C2CCCC2)cc1C4(C)C ; CC(C)(C)c1ccc2c(c1)B1c3cnccc3N3c4ccc(C(C)(C)C)cc4C(C)(C)c4cc5c(c1c43)N2c1ccc(C(C)(C)C)cc1C5(C)C ; CC(C)(C)c1ccc2c(c1)C(C)(C)c1cc3c4c5c1N2c1ccncc1B5c1sc2ccc5ccccc5c2c1N4c1ccc(C(C)(C)C)cc1C3(C)C]

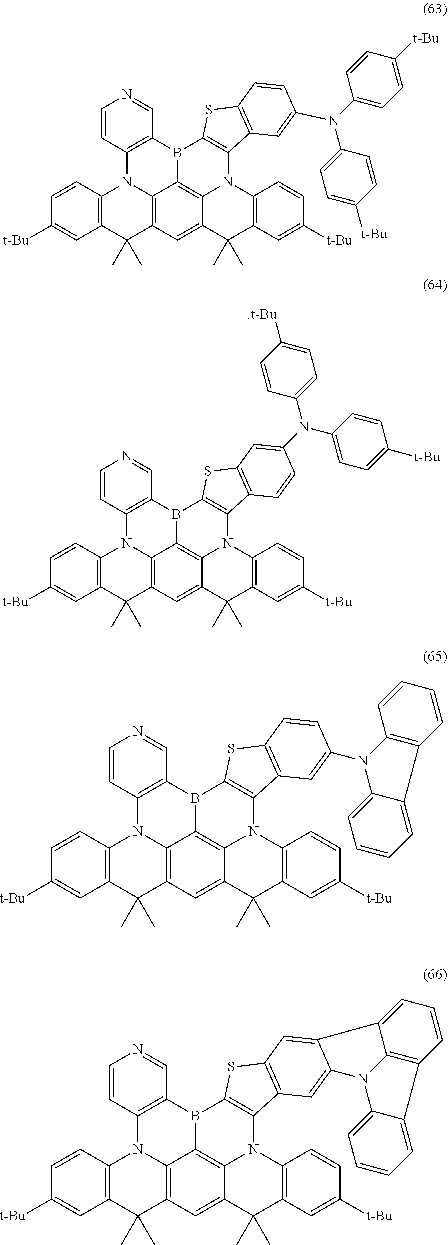

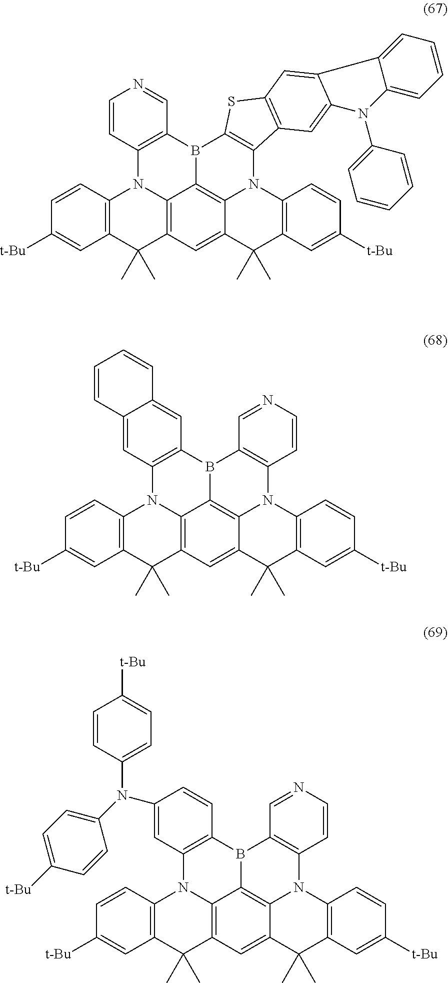 [SMILES: CC(C)(C)c1ccc2c(c1)C(C)(C)c1cc3c4c5c1N2c1ccncc1B5c1sc2cc5c6ccccc6n(-c6ccccc6)c5cc2c1N4c1ccc(C(C)(C)C)cc1C3(C)C ; CC(C)(C)c1ccc2c(c1)C(C)(C)c1cc3c4c5c1N2c1ccncc1B5c1cc2ccccc2cc1N4c1ccc(C(C)(C)C)cc1C3(C)C ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2cnccc2N6c2ccc(C(C)(C)C)cc2C5(C)C)cc1]

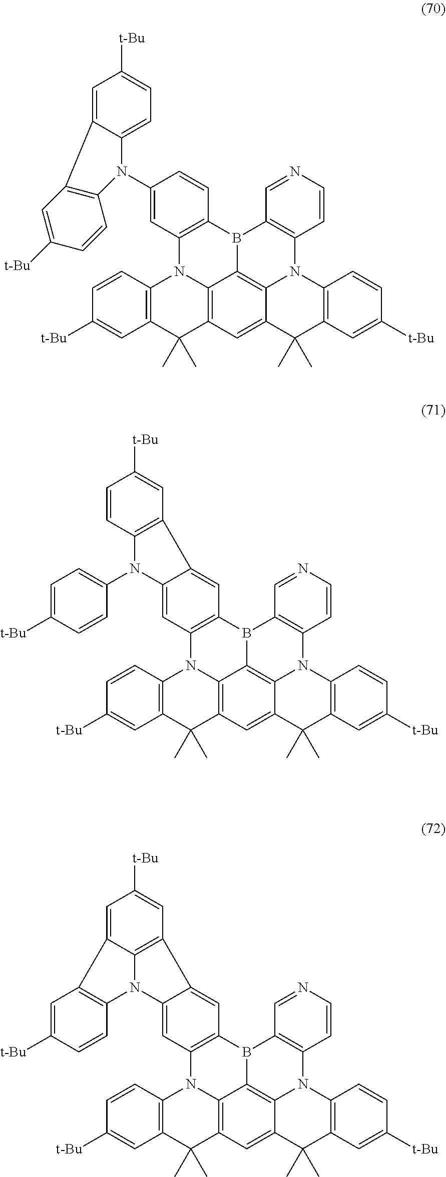 [SMILES: CC(C)(C)c1ccc2c(c1)C(C)(C)c1cc3c4c5c1N2c1ccncc1B5c1ccc(-n2c5ccc(C(C)(C)C)cc5c5cc(C(C)(C)C)ccc52)cc1N4c1ccc(C(C)(C)C)cc1C3(C)C ; CC(C)(C)c1ccc(-n2c3ccc(C(C)(C)C)cc3c3cc4c(cc32)N2c3ccc(C(C)(C)C)cc3C(C)(C)c3cc5c6c(c32)B4c2cnccc2N6c2ccc(C(C)(C)C)cc2C5(C)C)cc1 ; CC(C)(C)c1ccc2c(c1)C(C)(C)c1cc3c4c5c1N2c1ccncc1B5c1cc2c5cc(C(C)(C)C)cc6c7cc(C(C)(C)C)ccc7n(c2cc1N4c1ccc(C(C)(C)C)cc1C3(C)C)c65]

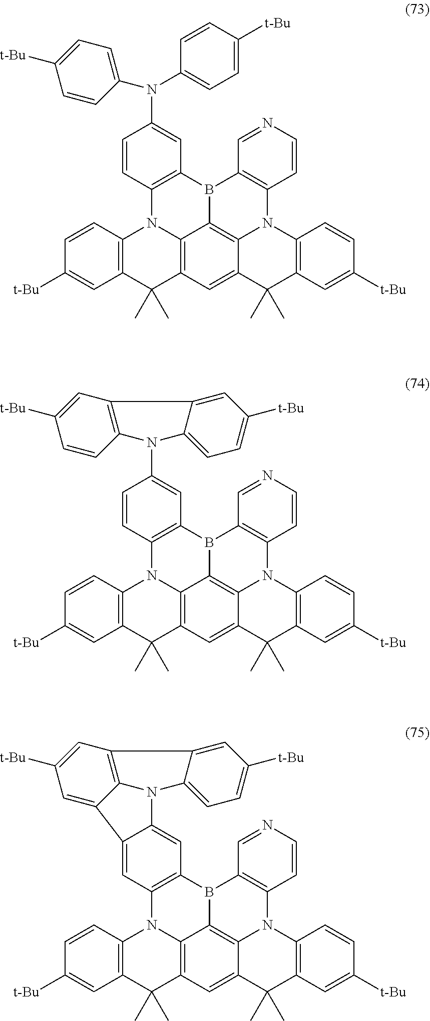 [SMILES: CC(C)(C)c1ccc(N(c2ccc(C(C)(C)C)cc2)c2ccc3c(c2)B2c4cnccc4N4c5ccc(C(C)(C)C)cc5C(C)(C)c5cc6c(c2c54)N3c2ccc(C(C)(C)C)cc2C6(C)C)cc1 ; CC(C)(C)c1ccc2c(c1)C(C)(C)c1cc3c4c5c1N2c1ccncc1B5c1cc(-n2c5ccc(C(C)(C)C)cc5c5cc(C(C)(C)C)ccc52)ccc1N4c1ccc(C(C)(C)C)cc1C3(C)C ; CC(C)(C)c1ccc2c(c1)C(C)(C)c1cc3c4c5c1N2c1ccncc1B5c1cc2c(cc1N4c1ccc(C(C)(C)C)cc1C3(C)C)c1cc(C(C)(C)C)cc3c4cc(C(C)(C)C)ccc4n2c31]

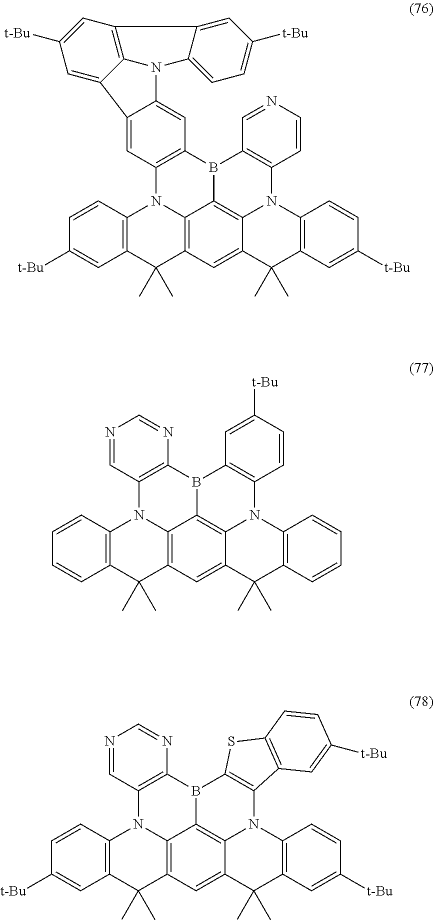 [SMILES: CC(C)(C)c1ccc2c(c1)C(C)(C)c1cc3c4c5c1N2c1ccncc1B5c1cc2c(cc1N4c1ccc(C(C)(C)C)cc1C3(C)C)c1cc(C(C)(C)C)cc3c4cc(C(C)(C)C)ccc4n2c31 ; CC(C)(C)c1ccc2c(c1)B1c3ncncc3N3c4ccccc4C(C)(C)c4cc5c(c1c43)N2c1ccccc1C5(C)C ; CC(C)(C)c1ccc2c(c1)C(C)(C)c1cc3c4c5c1N2c1cncnc1B5c1sc2ccc(C(C)(C)C)cc2c1N4c1ccc(C(C)(C)C)cc1C3(C)C]

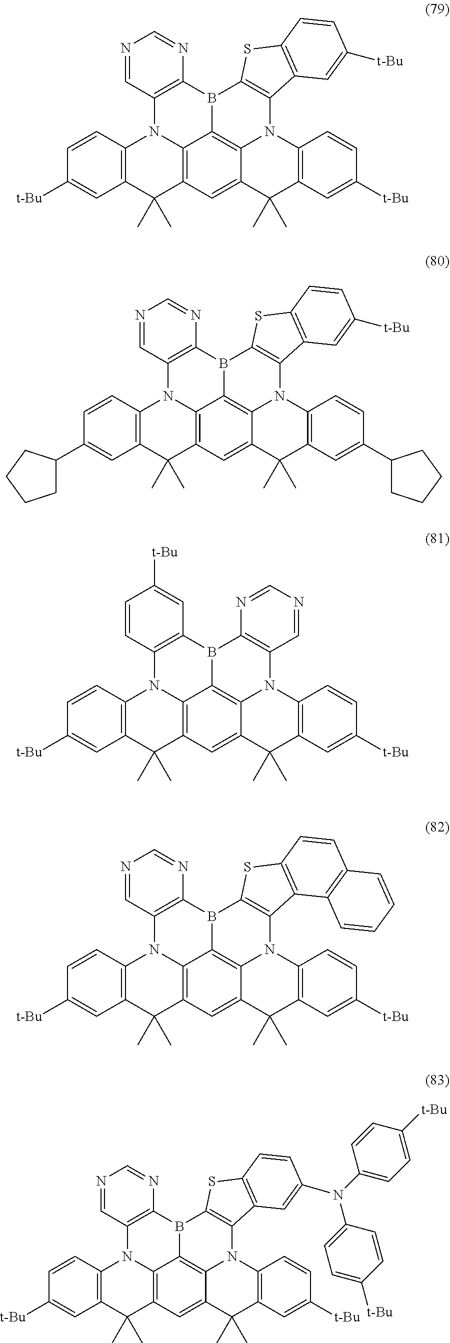

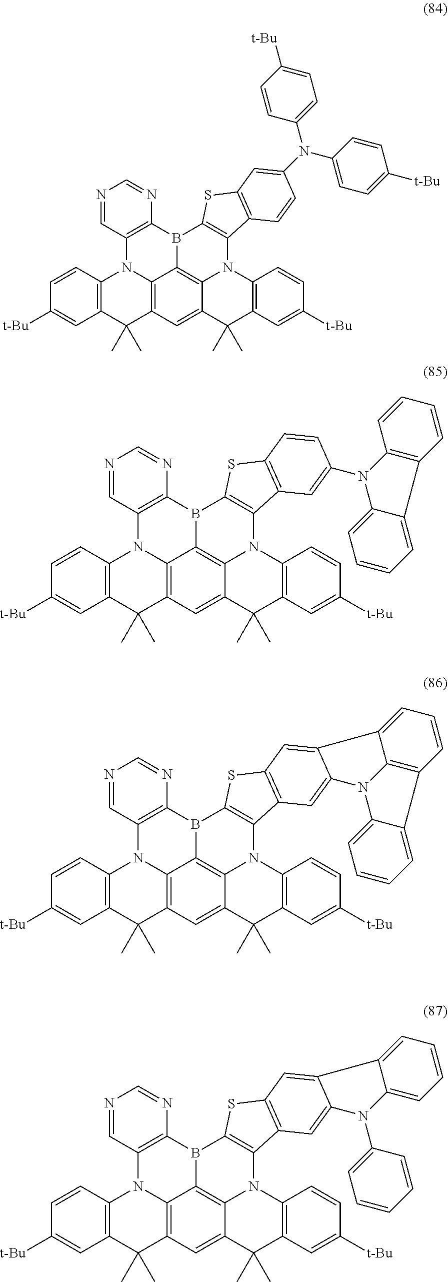 [SMILES: CC(C)(C)c1ccc(N(c2ccc(C(C)(C)C)cc2)c2ccc3c4c(sc3c2)B2c3ncncc3N3c5ccc(C(C)(C)C)cc5C(C)(C)c5cc6c(c2c53)N4c2ccc(C(C)(C)C)cc2C6(C)C)cc1 ; CC(C)(C)c1ccc2c(c1)C(C)(C)c1cc3c4c5c1N2c1cncnc1B5c1sc2ccc(-n5c6ccccc6c6ccccc65)cc2c1N4c1ccc(C(C)(C)C)cc1C3(C)C ; CC(C)(C)c1ccc2c(c1)C(C)(C)c1cc3c4c5c1N2c1cncnc1B5c1sc2cc5c6cccc7c8ccccc8n(c5cc2c1N4c1ccc(C(C)(C)C)cc1C3(C)C)c76 ; CC(C)(C)c1ccc2c(c1)C(C)(C)c1cc3c4c5c1N2c1cncnc1B5c1sc2cc5c6ccccc6n(-c6ccccc6)c5cc2c1N4c1ccc(C(C)(C)C)cc1C3(C)C]

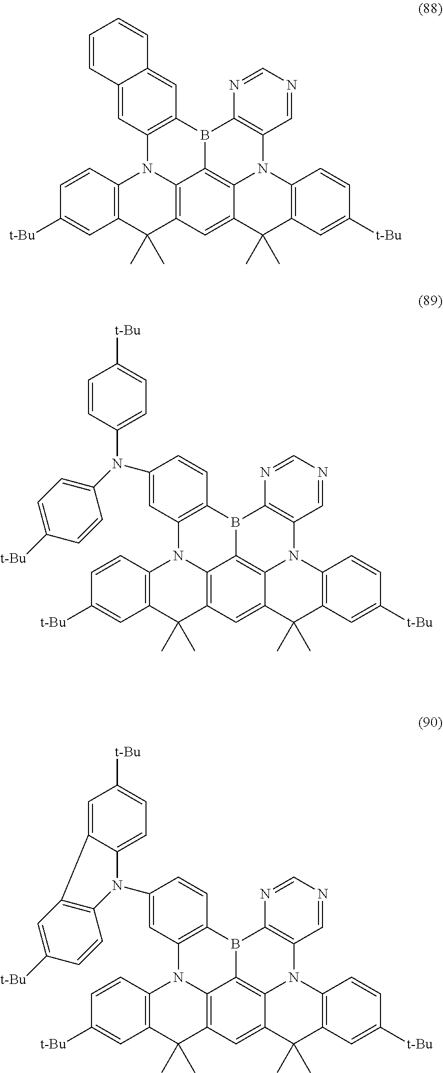 [SMILES: CC(C)(C)c1ccc2c(c1)C(C)(C)c1cc3c4c5c1N2c1cc2ccccc2cc1B5c1ncncc1N4c1ccc(C(C)(C)C)cc1C3(C)C ; CC(C)(C)c1ccc(N(c2ccc(C(C)(C)C)cc2)c2ccc3c(c2)N2c4ccc(C(C)(C)C)cc4C(C)(C)c4cc5c6c(c42)B3c2ncncc2N6c2ccc(C(C)(C)C)cc2C5(C)C)cc1 ; CC(C)(C)c1ccc2c(c1)C(C)(C)c1cc3c4c5c1N2c1cc(-n2c6ccc(C(C)(C)C)cc6c6cc(C(C)(C)C)ccc62)ccc1B5c1ncncc1N4c1ccc(C(C)(C)C)cc1C3(C)C]

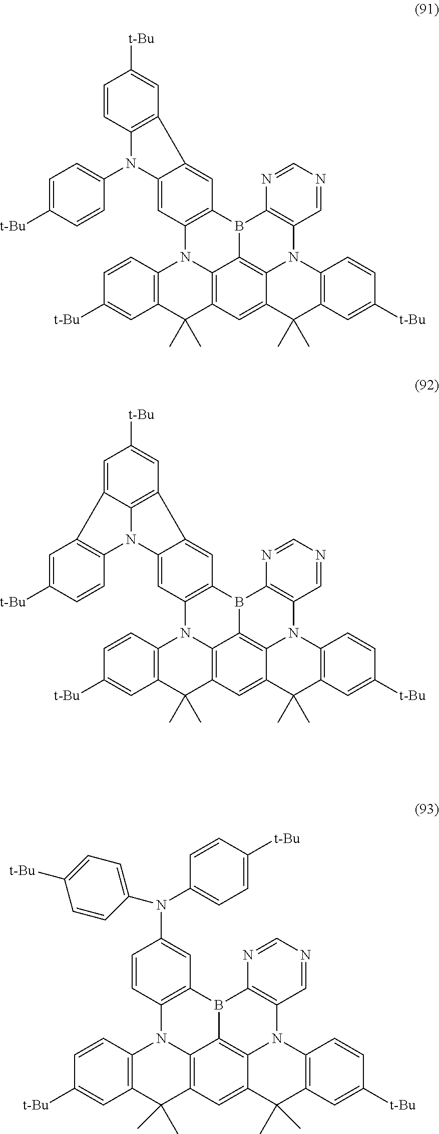 [SMILES: CC(C)(C)c1ccc(-n2c3ccc(C(C)(C)C)cc3c3cc4c(cc32)N2c3ccc(C(C)(C)C)cc3C(C)(C)c3cc5c6c(c32)B4c2ncncc2N6c2ccc(C(C)(C)C)cc2C5(C)C)cc1 ; CC(C)(C)c1ccc2c(c1)C(C)(C)c1cc3c4c5c1N2c1cc2c(cc1B5c1ncncc1N4c1ccc(C(C)(C)C)cc1C3(C)C)c1cc(C(C)(C)C)cc3c4cc(C(C)(C)C)ccc4n2c31 ; CC(C)(C)c1ccc(N(c2ccc(C(C)(C)C)cc2)c2ccc3c(c2)B2c4ncncc4N4c5ccc(C(C)(C)C)cc5C(C)(C)c5cc6c(c2c54)N3c2ccc(C(C)(C)C)cc2C6(C)C)cc1]

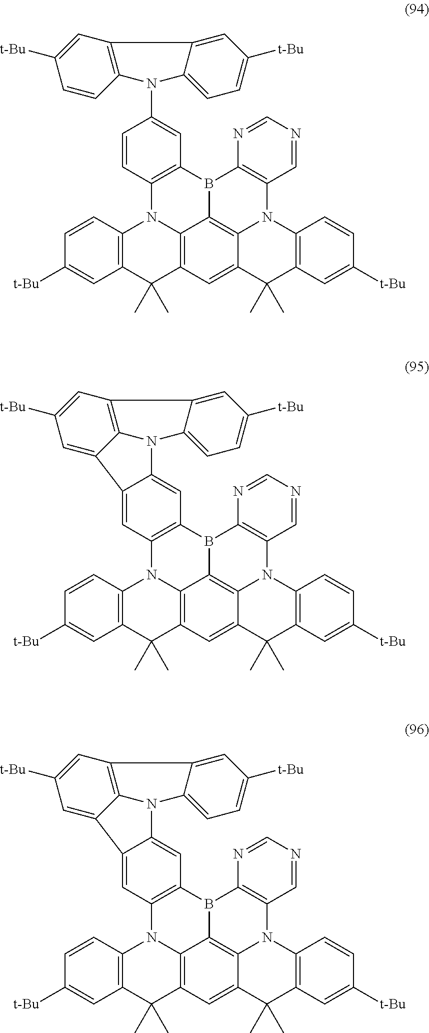 [SMILES: CC(C)(C)c1ccc2c(c1)C(C)(C)c1cc3c4c5c1N2c1ccc(-n2c6ccc(C(C)(C)C)cc6c6cc(C(C)(C)C)ccc62)cc1B5c1ncncc1N4c1ccc(C(C)(C)C)cc1C3(C)C ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1ncncc1N4c1ccc(C(C)(C)C)cc1C3(C)C)c76 ; CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1ncncc1N4c1ccc(C(C)(C)C)cc1C3(C)C)c76]

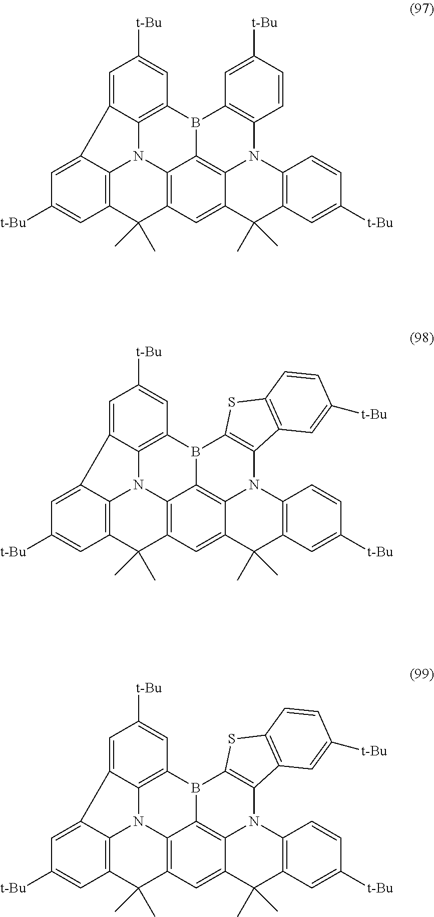 [SMILES: CC(C)(C)c1ccc2c(c1)B1c3c4c(cc5c3-n3c6c1cc(C(C)(C)C)cc6c1cc(C(C)(C)C)cc(c13)C5(C)C)C(C)(C)c1cc(C(C)(C)C)ccc1N24 ; CC(C)(C)c1ccc2c(c1)C(C)(C)c1cc3c4c5c1N2c1c(sc2ccc(C(C)(C)C)cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc(C(C)(C)C)cc12)B5c1cc(C(C)(C)C)cc2c5cc(C(C)(C)C)cc(c5n-4c12)C3(C)C]

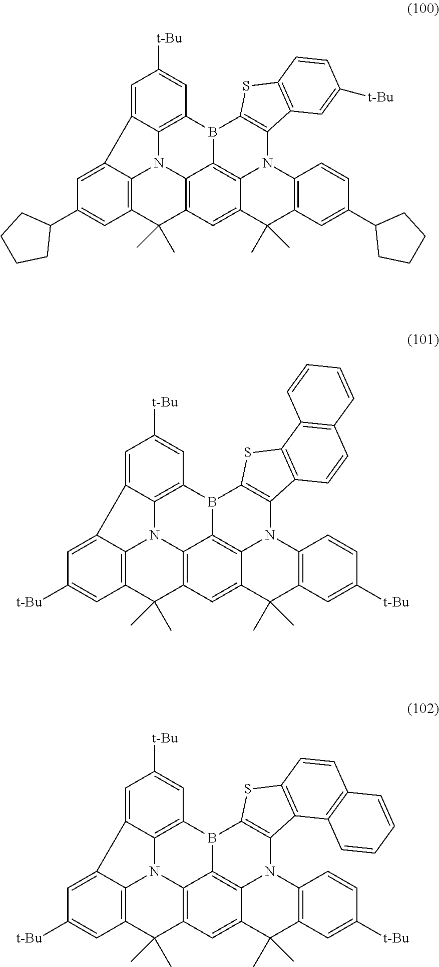 [SMILES: CC(C)(C)c1ccc2sc3c(c2c1)N1c2ccc(C4CCCC4)cc2C(C)(C)c2cc4c5c(c21)B3c1cc(C(C)(C)C)cc2c3cc(C6CCCC6)cc(c3n-5c12)C4(C)C ; CC(C)(C)c1ccc2c(c1)C(C)(C)c1cc3c4c5c1N2c1c(sc2c1ccc1ccccc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc6ccccc6c12)B5c1cc(C(C)(C)C)cc2c5cc(C(C)(C)C)cc(c5n-4c12)C3(C)C]

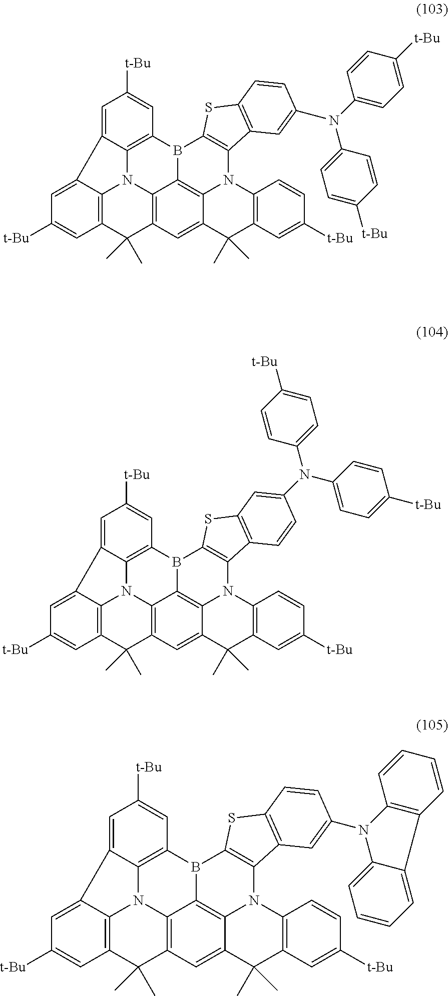 [SMILES: CC(C)(C)c1ccc(N(c2ccc(C(C)(C)C)cc2)c2ccc3sc4c(c3c2)N2c3ccc(C(C)(C)C)cc3C(C)(C)c3cc5c6c(c32)B4c2cc(C(C)(C)C)cc3c4cc(C(C)(C)C)cc(c4n-6c23)C5(C)C)cc1 ; CC(C)(C)c1ccc(N(c2ccc(C(C)(C)C)cc2)c2ccc3c4c(sc3c2)B2c3c5c(cc6c3-n3c7c2cc(C(C)(C)C)cc7c2cc(C(C)(C)C)cc(c23)C6(C)C)C(C)(C)c2cc(C(C)(C)C)ccc2N54)cc1 ; CC(C)(C)c1ccc2c(c1)C(C)(C)c1cc3c4c5c1N2c1c(sc2ccc(-n6c7ccccc7c7ccccc76)cc12)B5c1cc(C(C)(C)C)cc2c5cc(C(C)(C)C)cc(c5n-4c12)C3(C)C]

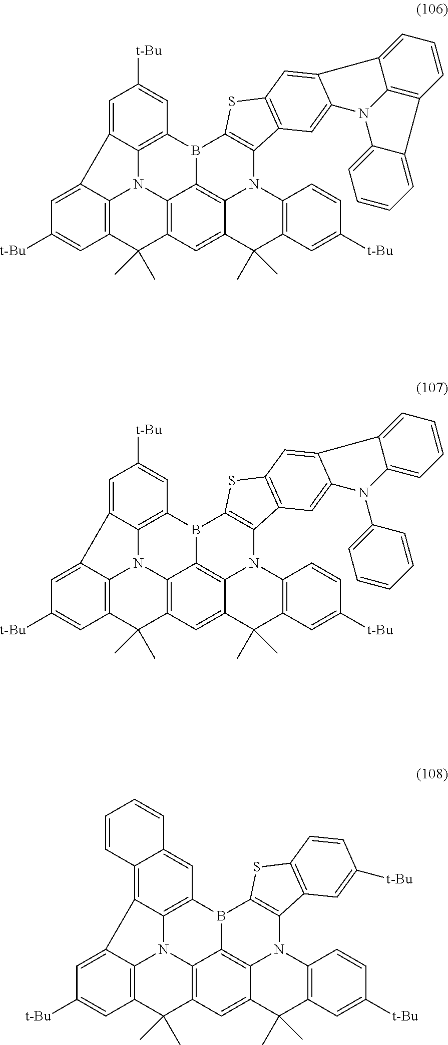 [SMILES: CC(C)(C)c1ccc2c(c1)C(C)(C)c1cc3c4c5c1N2c1c(sc2cc6c7cccc8c9ccccc9n(c6cc12)c87)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2cc6c7ccccc7n(-c7ccccc7)c6cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc(C(C)(C)C)cc12)B5c1cc2ccccc2c2c5cc(C(C)(C)C)cc(c5n-4c12)C3(C)C]

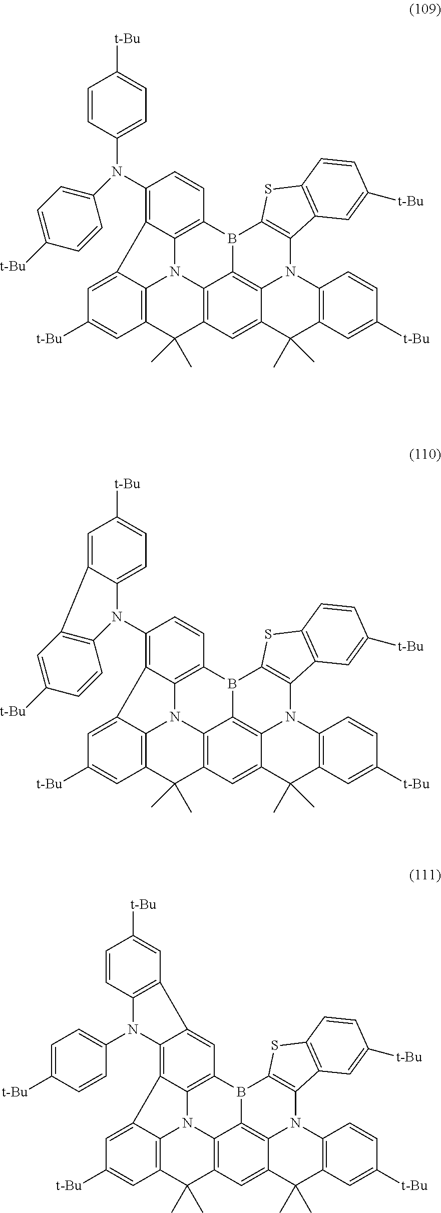 [SMILES: CC(C)(C)c1ccc(N(c2ccc(C(C)(C)C)cc2)c2ccc3c4c2c2cc(C(C)(C)C)cc5c2n4-c2c(cc4c6c2B3c2sc3ccc(C(C)(C)C)cc3c2N6c2ccc(C(C)(C)C)cc2C4(C)C)C5(C)C)cc1 ; CC(C)(C)c1ccc2c(c1)C(C)(C)c1cc3c4c5c1N2c1c(sc2ccc(C(C)(C)C)cc12)B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4sc5ccc(C(C)(C)C)cc5c4N8c4ccc(C(C)(C)C)cc4C6(C)C)C7(C)C)c32)cc1]

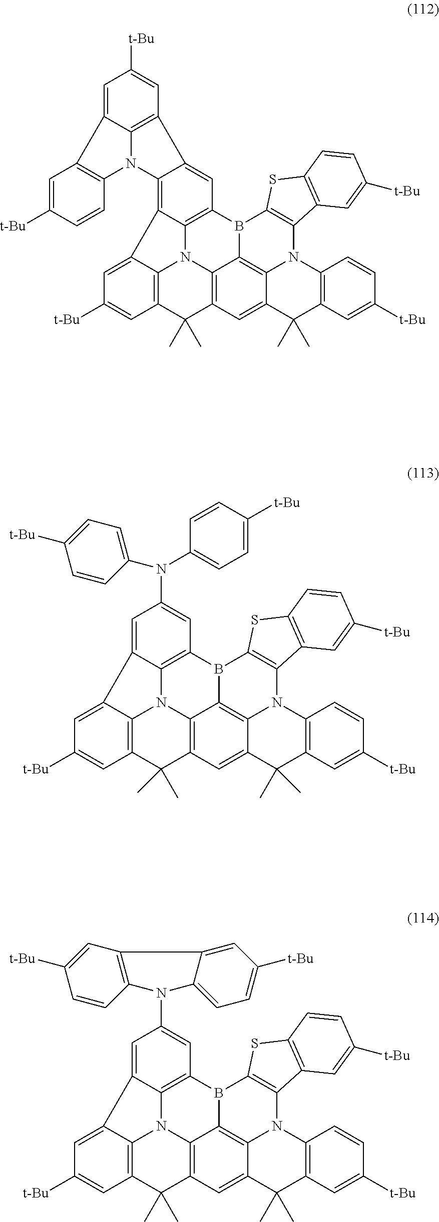 [SMILES: CC(C)(C)c1ccc2c(c1)C(C)(C)c1cc3c4c5c1N2c1c(sc2ccc(C(C)(C)C)cc12)B5c1cc2c5cc(C(C)(C)C)cc6c7cc(C(C)(C)C)ccc7n(c65)c2c2c5cc(C(C)(C)C)cc(c5n-4c12)C3(C)C ; CC(C)(C)c1ccc(N(c2ccc(C(C)(C)C)cc2)c2cc3c4c(c2)c2cc(C(C)(C)C)cc5c2n4-c2c(cc4c6c2B3c2sc3ccc(C(C)(C)C)cc3c2N6c2ccc(C(C)(C)C)cc2C4(C)C)C5(C)C)cc1 ; CC(C)(C)c1ccc2c(c1)C(C)(C)c1cc3c4c5c1N2c1c(sc2ccc(C(C)(C)C)cc12)B5c1cc(-n2c5ccc(C(C)(C)C)cc5c5cc(C(C)(C)C)ccc52)cc2c5cc(C(C)(C)C)cc(c5n-4c12)C3(C)C]

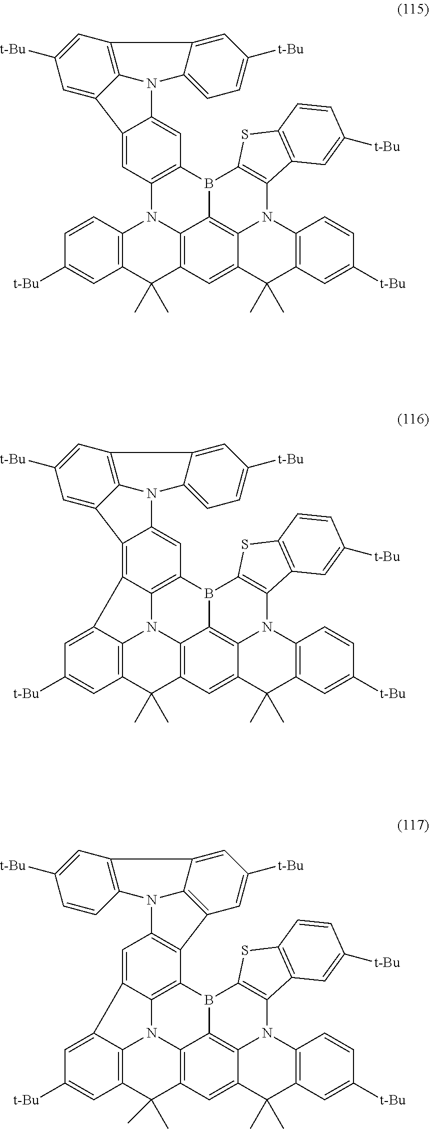 [SMILES: CC(C)(C)c1ccc2c(c1)C(C)(C)c1cc3c4c5c1N2c1cc2c6cc(C(C)(C)C)cc7c8cc(C(C)(C)C)ccc8n(c2cc1B5c1sc2ccc(C(C)(C)C)cc2c1N4c1ccc(C(C)(C)C)cc1C3(C)C)c76 ; CC(C)(C)c1ccc2c(c1)C(C)(C)c1cc3c4c5c1N2c1c(sc2ccc(C(C)(C)C)cc12)B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1c(sc2ccc(C(C)(C)C)cc12)B5c1c2c5cc(C(C)(C)C)cc6c7cc(C(C)(C)C)ccc7n(c2cc2c7cc(C(C)(C)C)cc(c7n-4c12)C3(C)C)c65]

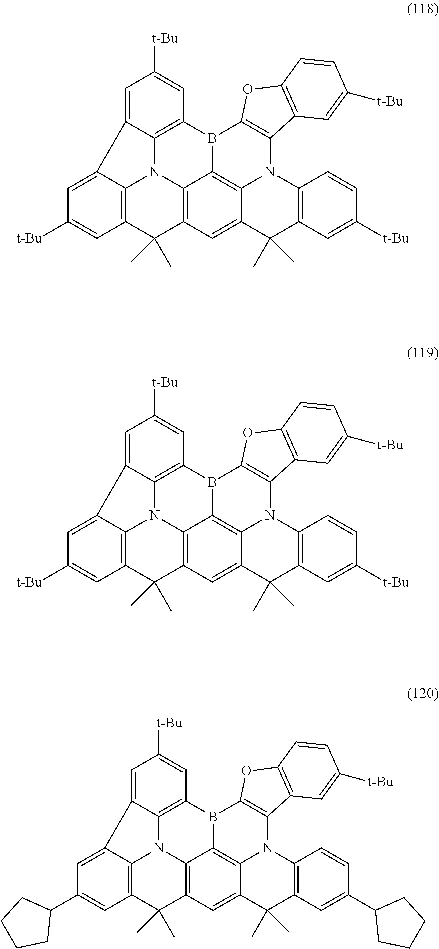 [SMILES: CC(C)(C)c1ccc2c(c1)C(C)(C)c1cc3c4c5c1N2c1c(oc2ccc(C(C)(C)C)cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1cc(C(C)(C)C)cc2c5cc(C(C)(C)C)cc(c5n-4c12)C3(C)C ; CC(C)(C)c1ccc2oc3c(c2c1)N1c2ccc(C4CCCC4)cc2C(C)(C)c2cc4c5c(c21)B3c1cc(C(C)(C)C)cc2c3cc(C6CCCC6)cc(c3n-5c12)C4(C)C]

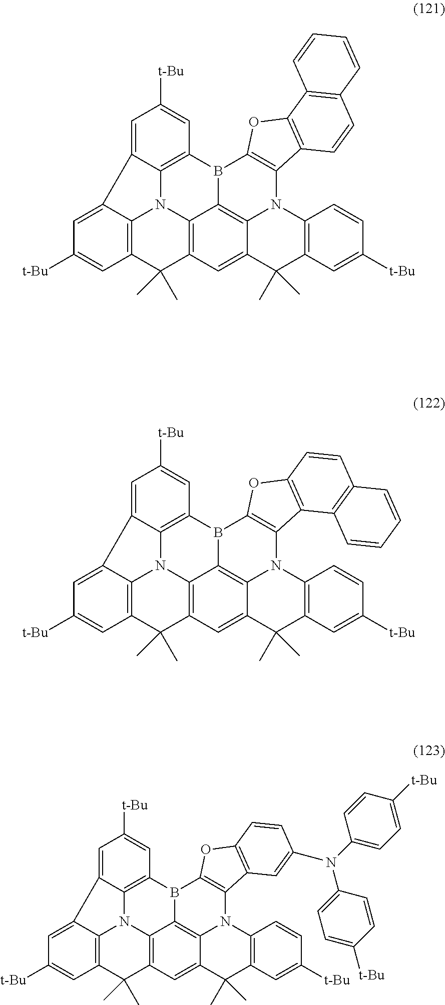 [SMILES: CC(C)(C)c1ccc2c(c1)C(C)(C)c1cc3c4c5c1N2c1c(oc2c1ccc1ccccc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2ccc6ccccc6c12)B5c1cc(C(C)(C)C)cc2c5cc(C(C)(C)C)cc(c5n-4c12)C3(C)C ; CC(C)(C)c1ccc(N(c2ccc(C(C)(C)C)cc2)c2ccc3oc4c(c3c2)N2c3ccc(C(C)(C)C)cc3C(C)(C)c3cc5c6c(c32)B4c2cc(C(C)(C)C)cc3c4cc(C(C)(C)C)cc(c4n-6c23)C5(C)C)cc1]

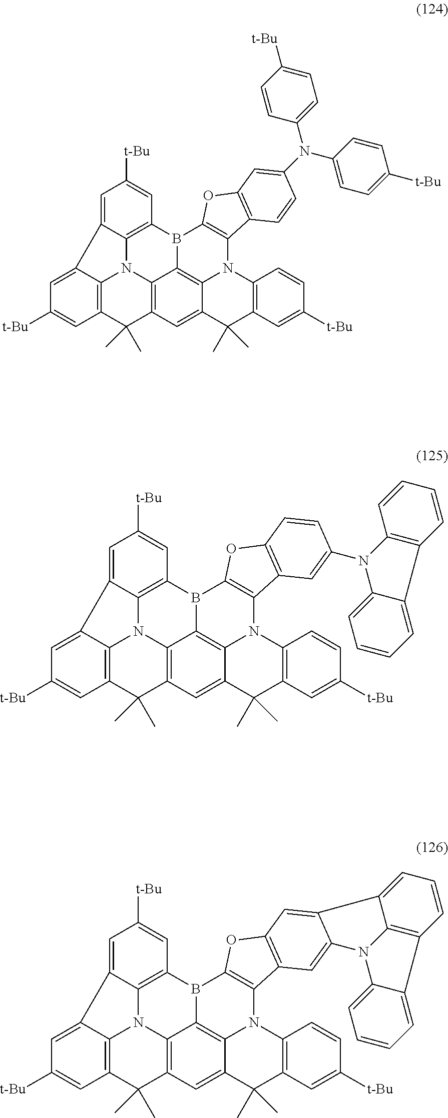 [SMILES: CC(C)(C)c1ccc(N(c2ccc(C(C)(C)C)cc2)c2ccc3c4c(oc3c2)B2c3c5c(cc6c3-n3c7c2cc(C(C)(C)C)cc7c2cc(C(C)(C)C)cc(c23)C6(C)C)C(C)(C)c2cc(C(C)(C)C)ccc2N54)cc1 ; CC(C)(C)c1ccc2c(c1)C(C)(C)c1cc3c4c5c1N2c1c(oc2ccc(-n6c7ccccc7c7ccccc76)cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2cc6c7cccc8c9ccccc9n(c6cc12)c87)B5c1cc(C(C)(C)C)cc2c5cc(C(C)(C)C)cc(c5n-4c12)C3(C)C]

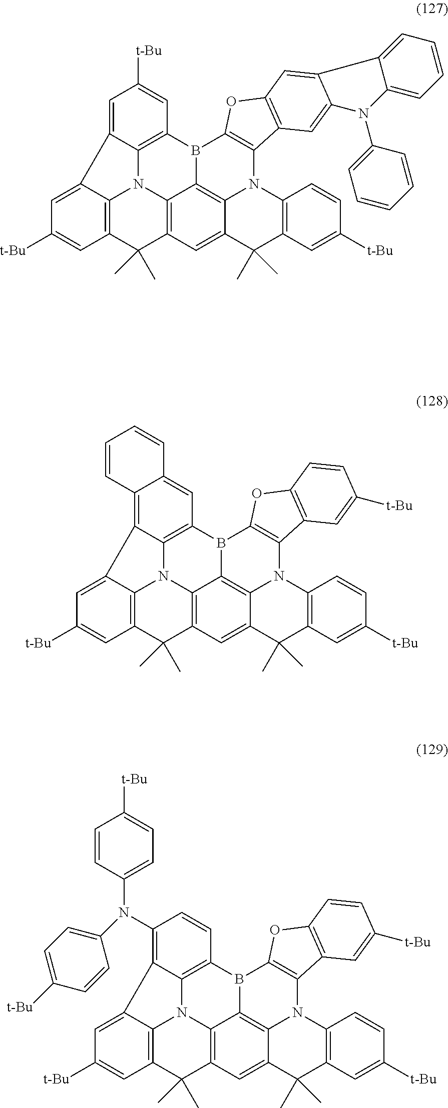 [SMILES: CC(C)(C)c1ccc2c(c1)C(C)(C)c1cc3c4c5c1N2c1c(oc2cc6c7ccccc7n(-c7ccccc7)c6cc12)B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1cc2ccccc2c2c5cc(C(C)(C)C)cc(c5n-4c12)C3(C)C ; CC(C)(C)c1ccc(N(c2ccc(C(C)(C)C)cc2)c2ccc3c4c2c2cc(C(C)(C)C)cc5c2n4-c2c(cc4c6c2B3c2oc3ccc(C(C)(C)C)cc3c2N6c2ccc(C(C)(C)C)cc2C4(C)C)C5(C)C)cc1]

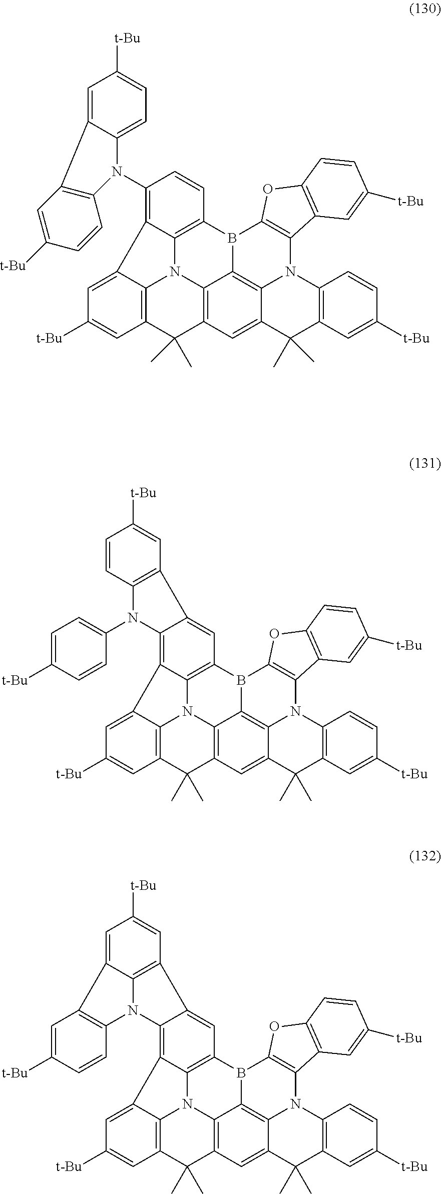 [SMILES: CC(C)(C)c1ccc2c(c1)C(C)(C)c1cc3c4c5c1N2c1c(oc2ccc(C(C)(C)C)cc12)B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4oc5ccc(C(C)(C)C)cc5c4N8c4ccc(C(C)(C)C)cc4C6(C)C)C7(C)C)c32)cc1 ; CC(C)(C)c1ccc2c(c1)C(C)(C)c1cc3c4c5c1N2c1c(oc2ccc(C(C)(C)C)cc12)B5c1cc2c5cc(C(C)(C)C)cc6c7cc(C(C)(C)C)ccc7n(c65)c2c2c5cc(C(C)(C)C)cc(c5n-4c12)C3(C)C]

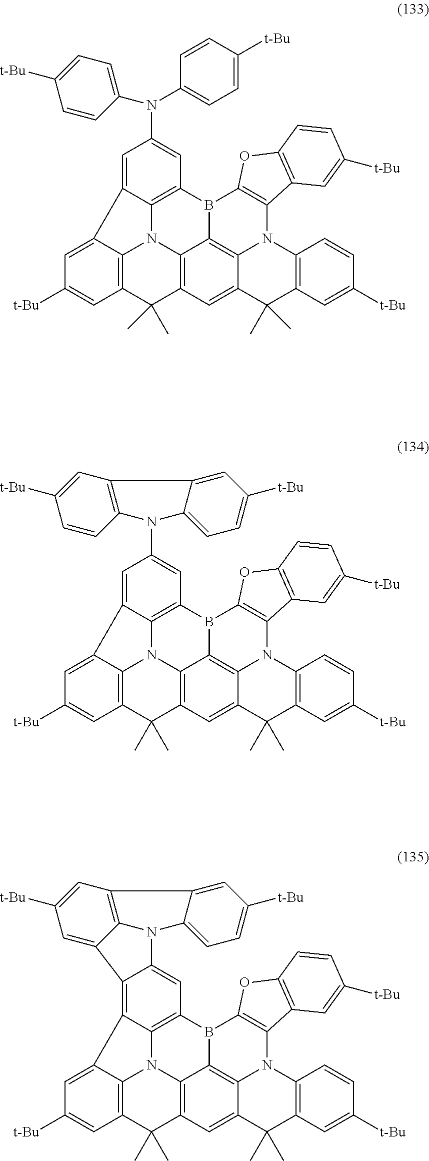 [SMILES: CC(C)(C)c1ccc(N(c2ccc(C(C)(C)C)cc2)c2cc3c4c(c2)c2cc(C(C)(C)C)cc5c2n4-c2c(cc4c6c2B3c2oc3ccc(C(C)(C)C)cc3c2N6c2ccc(C(C)(C)C)cc2C4(C)C)C5(C)C)cc1 ; CC(C)(C)c1ccc2c(c1)C(C)(C)c1cc3c4c5c1N2c1c(oc2ccc(C(C)(C)C)cc12)B5c1cc(-n2c5ccc(C(C)(C)C)cc5c5cc(C(C)(C)C)ccc52)cc2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1cc2c(c5cc(C(C)(C)C)cc6c7cc(C(C)(C)C)ccc7n2c65)c2c5cc(C(C)(C)C)cc(c5n-4c12)C3(C)C]

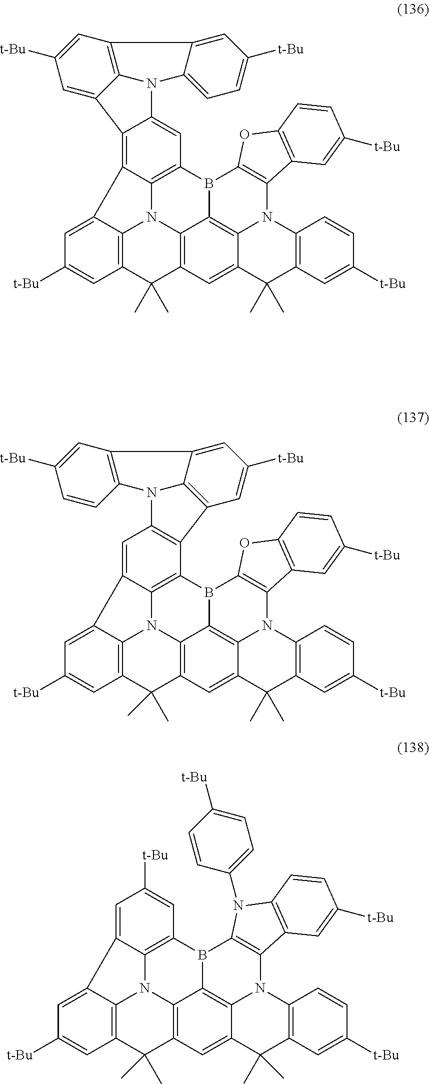 [SMILES: CC(C)(C)c1ccc2c(c1)C(C)(C)c1cc3c4c5c1N2c1c(oc2ccc(C(C)(C)C)cc12)B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1c(oc2ccc(C(C)(C)C)cc12)B5c1c2c5cc(C(C)(C)C)cc6c7cc(C(C)(C)C)ccc7n(c2cc2c7cc(C(C)(C)C)cc(c7n-4c12)C3(C)C)c65 ; CC(C)(C)c1ccc(-n2c3c(c4cc(C(C)(C)C)ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1]

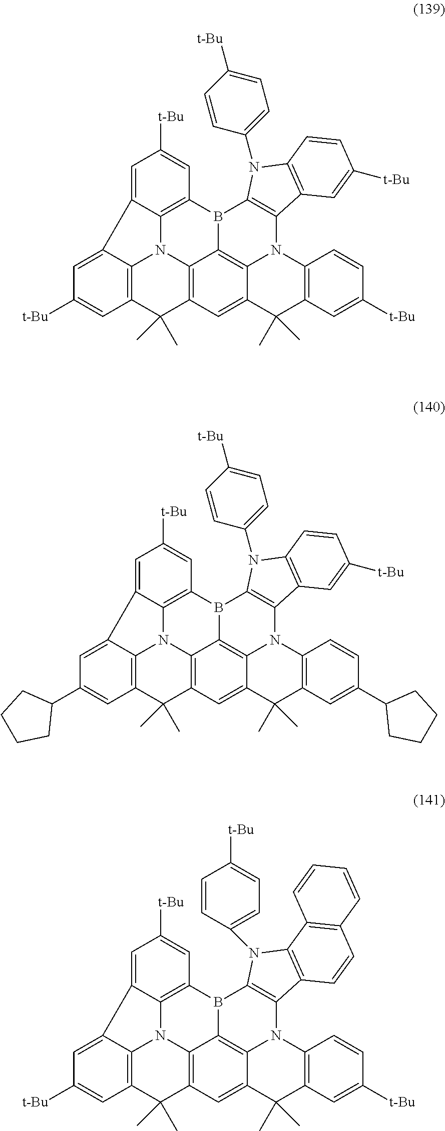 [SMILES: CC(C)(C)c1ccc(-n2c3c(c4cc(C(C)(C)C)ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(-n2c3c(c4cc(C(C)(C)C)ccc42)N2c4ccc(C5CCCC5)cc4C(C)(C)c4cc5c6c(c42)B3c2cc(C(C)(C)C)cc3c4cc(C7CCCC7)cc(c4n-6c23)C5(C)C)cc1 ; CC(C)(C)c1ccc(-n2c3c(c4ccc5ccccc5c42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1]

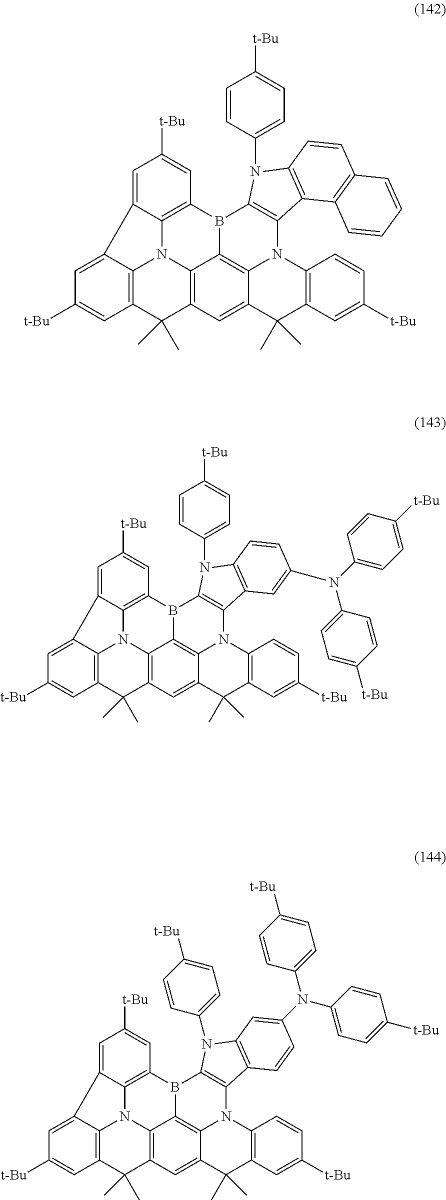 [SMILES: CC(C)(C)c1ccc(-n2c3c(c4c5ccccc5ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(N(c2ccc(C(C)(C)C)cc2)c2ccc3c(c2)c2c(n3-c3ccc(C(C)(C)C)cc3)B3c4c5c(cc6c4-n4c7c3cc(C(C)(C)C)cc7c3cc(C(C)(C)C)cc(c34)C6(C)C)C(C)(C)c3cc(C(C)(C)C)ccc3N52)cc1 ; CC(C)(C)c1ccc(N(c2ccc(C(C)(C)C)cc2)c2ccc3c4c(n(-c5ccc(C(C)(C)C)cc5)c3c2)B2c3c5c(cc6c3-n3c7c2cc(C(C)(C)C)cc7c2cc(C(C)(C)C)cc(c23)C6(C)C)C(C)(C)c2cc(C(C)(C)C)ccc2N54)cc1]

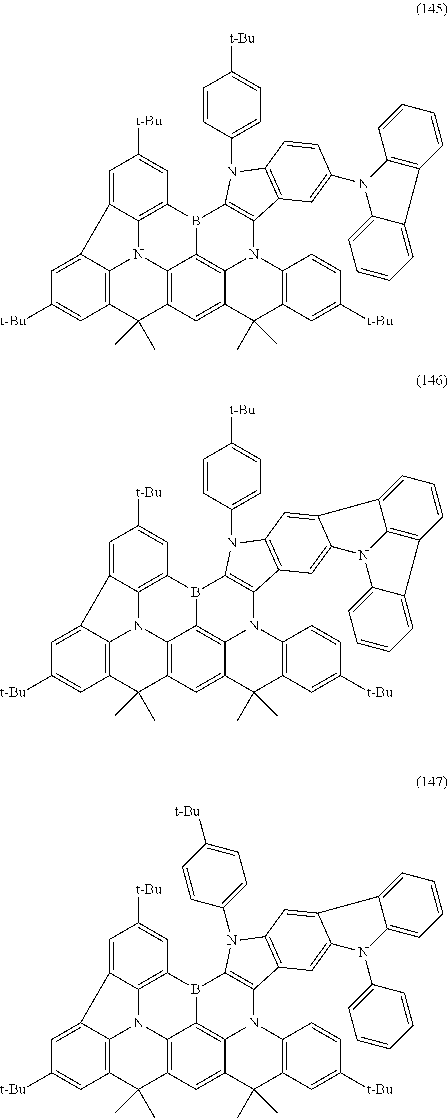 [SMILES: CC(C)(C)c1ccc(-n2c3c(c4cc(-n5c6ccccc6c6ccccc65)ccc42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(-n2c3c(c4cc5c(cc42)c2cccc4c6ccccc6n5c42)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1 ; CC(C)(C)c1ccc(-n2c3c(c4cc5c(cc42)c2ccccc2n5-c2ccccc2)N2c4ccc(C(C)(C)C)cc4C(C)(C)c4cc5c6c(c42)B3c2cc(C(C)(C)C)cc3c4cc(C(C)(C)C)cc(c4n-6c23)C5(C)C)cc1]

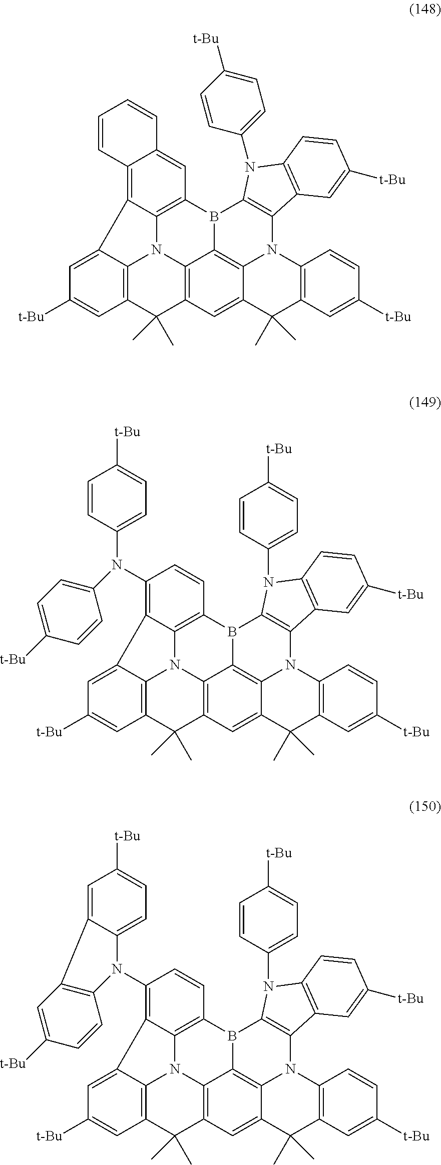 [SMILES: CC(C)(C)c1ccc(-n2c3c(c4cc(C(C)(C)C)ccc42)N2c4ccc(C(C)(C)C)cc4C(C)(C)c4cc5c6c(c42)B3c2cc3ccccc3c3c4cc(C(C)(C)C)cc(c4n-6c23)C5(C)C)cc1 ; CC(C)(C)c1ccc(N(c2ccc(C(C)(C)C)cc2)c2ccc3c4c2c2cc(C(C)(C)C)cc5c2n4-c2c(cc4c6c2B3c2c(c3cc(C(C)(C)C)ccc3n2-c2ccc(C(C)(C)C)cc2)N6c2ccc(C(C)(C)C)cc2C4(C)C)C5(C)C)cc1 ; CC(C)(C)c1ccc(-n2c3c(c4cc(C(C)(C)C)ccc42)N2c4ccc(C(C)(C)C)cc4C(C)(C)c4cc5c6c(c42)B3c2ccc(-n3c4ccc(C(C)(C)C)cc4c4cc(C(C)(C)C)ccc43)c3c4cc(C(C)(C)C)cc(c4n-6c23)C5(C)C)cc1]

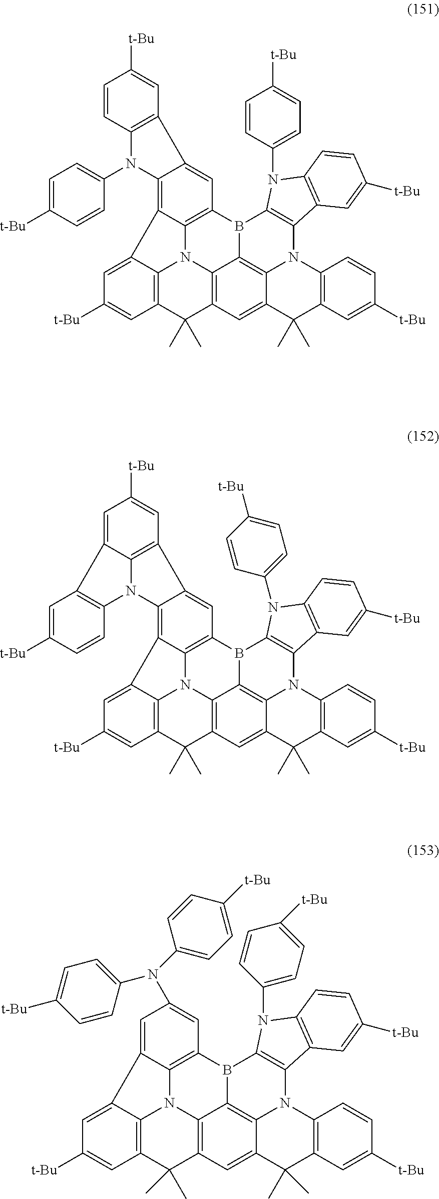

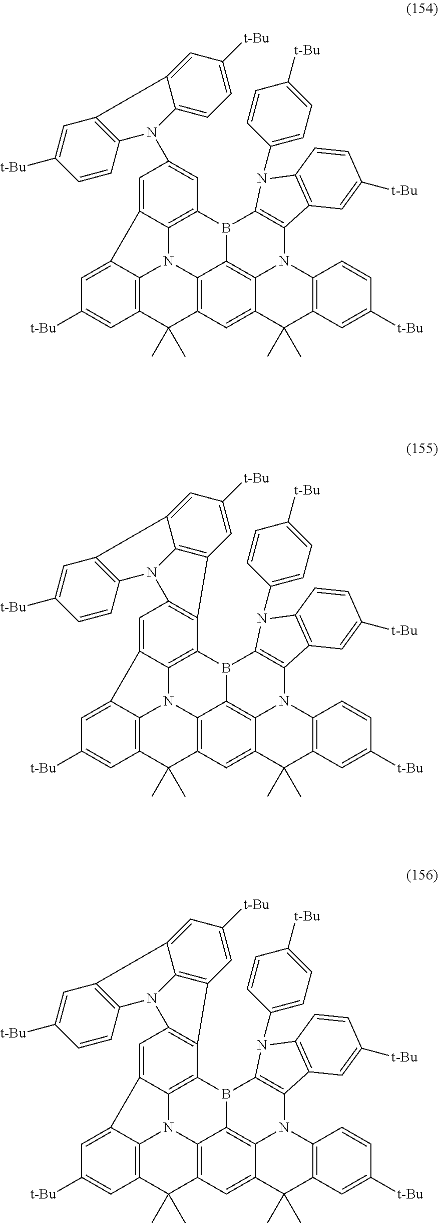

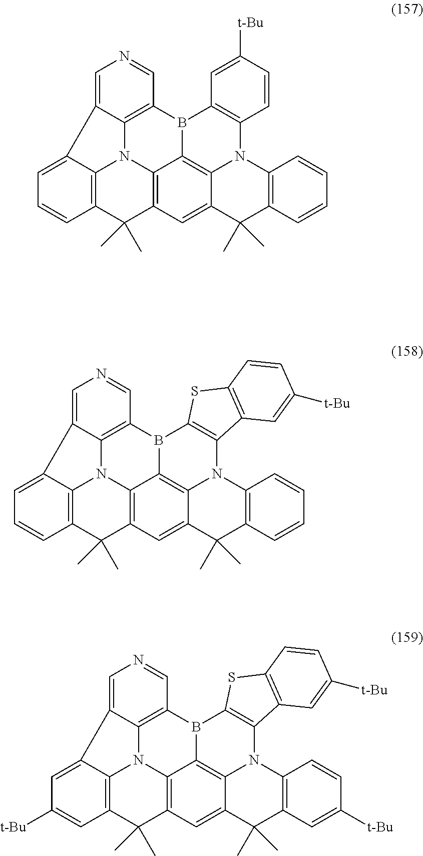 [SMILES: CC(C)(C)c1ccc2c(c1)B1c3c4c(cc5c3-n3c6c1cncc6c1cccc(c13)C5(C)C)C(C)(C)c1ccccc1N24 ; CC(C)(C)c1ccc2sc3c(c2c1)N1c2ccccc2C(C)(C)c2cc4c5c(c21)B3c1cncc2c3cccc(c3n-5c12)C4(C)C ; CC(C)(C)c1ccc2c(c1)C(C)(C)c1cc3c4c5c1N2c1c(sc2ccc(C(C)(C)C)cc12)B5c1cncc2c5cc(C(C)(C)C)cc(c5n-4c12)C3(C)C]

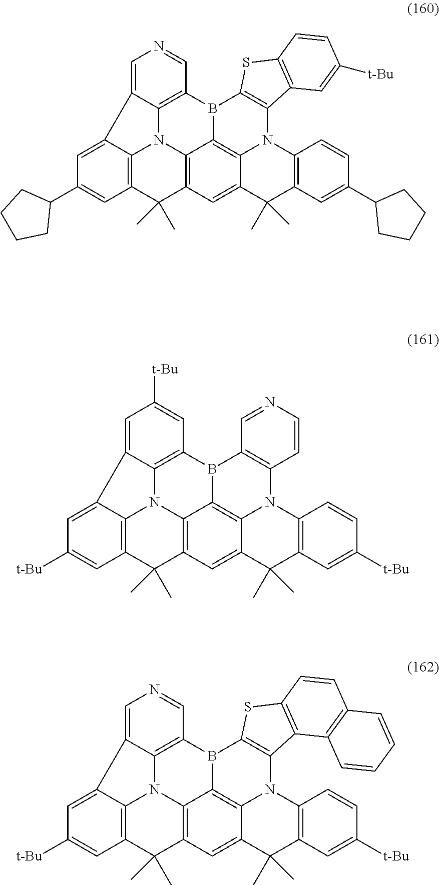 [SMILES: CC(C)(C)c1ccc2sc3c(c2c1)N1c2ccc(C4CCCC4)cc2C(C)(C)c2cc4c5c(c21)B3c1cncc2c3cc(C6CCCC6)cc(c3n-5c12)C4(C)C ; CC(C)(C)c1ccc2c(c1)C(C)(C)c1cc3c4c5c1N2c1ccncc1B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc6ccccc6c12)B5c1cncc2c5cc(C(C)(C)C)cc(c5n-4c12)C3(C)C]

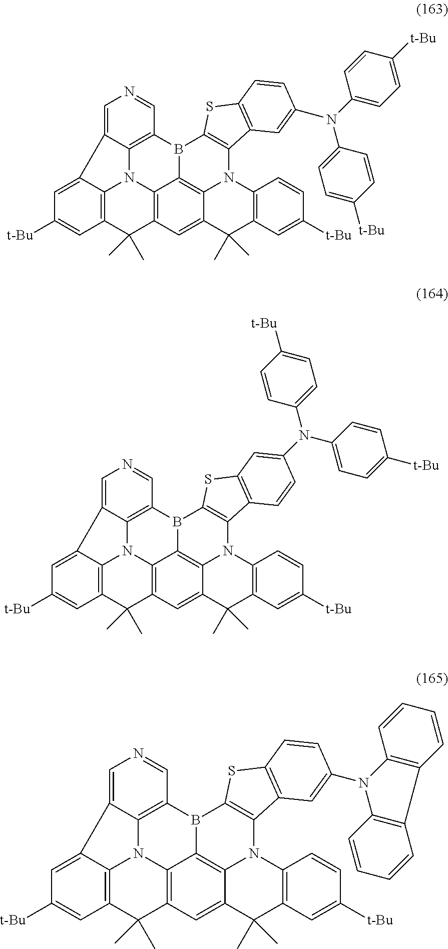 [SMILES: CC(C)(C)c1ccc(N(c2ccc(C(C)(C)C)cc2)c2ccc3sc4c(c3c2)N2c3ccc(C(C)(C)C)cc3C(C)(C)c3cc5c6c(c32)B4c2cncc3c4cc(C(C)(C)C)cc(c4n-6c23)C5(C)C)cc1 ; CC(C)(C)c1ccc(N(c2ccc(C(C)(C)C)cc2)c2ccc3c4c(sc3c2)B2c3c5c(cc6c3-n3c7c2cncc7c2cc(C(C)(C)C)cc(c23)C6(C)C)C(C)(C)c2cc(C(C)(C)C)ccc2N54)cc1 ; CC(C)(C)c1ccc2c(c1)C(C)(C)c1cc3c4c5c1N2c1c(sc2ccc(-n6c7ccccc7c7ccccc76)cc12)B5c1cncc2c5cc(C(C)(C)C)cc(c5n-4c12)C3(C)C]

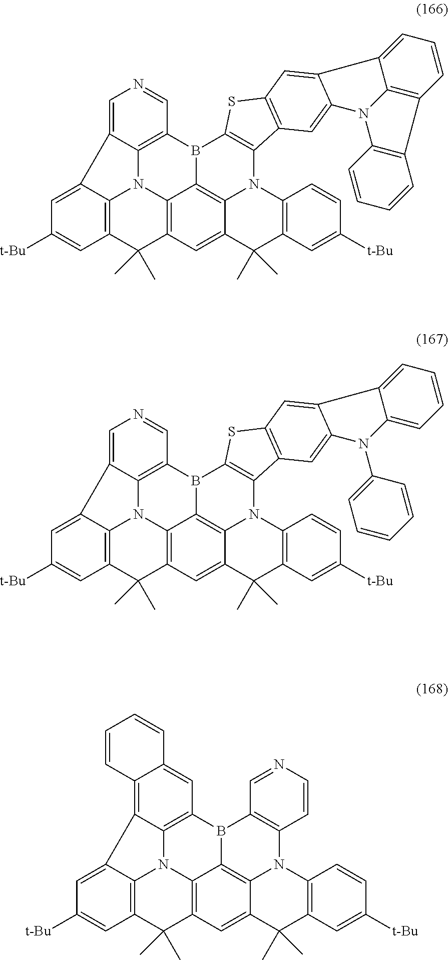 [SMILES: CC(C)(C)c1ccc2c(c1)C(C)(C)c1cc3c4c5c1N2c1c(sc2cc6c7cccc8c9ccccc9n(c6cc12)c87)B5c1cncc2c5cc(C(C)(C)C)cc(c5n-4c12)C3(C)C ; CC(C)(C)c1ccc2c(c1)C(C)(C)c1cc3c4c5c1N2c1c(sc2cc6c7ccccc7n(-c7ccccc7)c6cc12)B5c1cncc2c5cc(C(C)(C)C)cc(c5n-4c12)C3(C)C ; CC(C)(C)c1ccc2c(c1)C(C)(C)c1cc3c4c5c1N2c1ccncc1B5c1cc2ccccc2c2c5cc(C(C)(C)C)cc(c5n-4c12)C3(C)C]

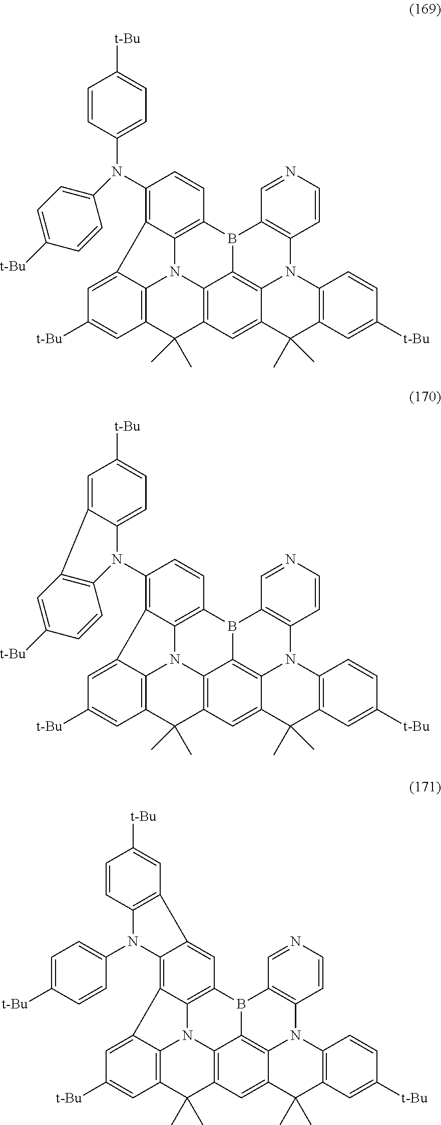 [SMILES: CC(C)(C)c1ccc(N(c2ccc(C(C)(C)C)cc2)c2ccc3c4c2c2cc(C(C)(C)C)cc5c2n4-c2c(cc4c6c2B3c2cnccc2N6c2ccc(C(C)(C)C)cc2C4(C)C)C5(C)C)cc1 ; CC(C)(C)c1ccc2c(c1)C(C)(C)c1cc3c4c5c1N2c1ccncc1B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4cnccc4N8c4ccc(C(C)(C)C)cc4C6(C)C)C7(C)C)c32)cc1]

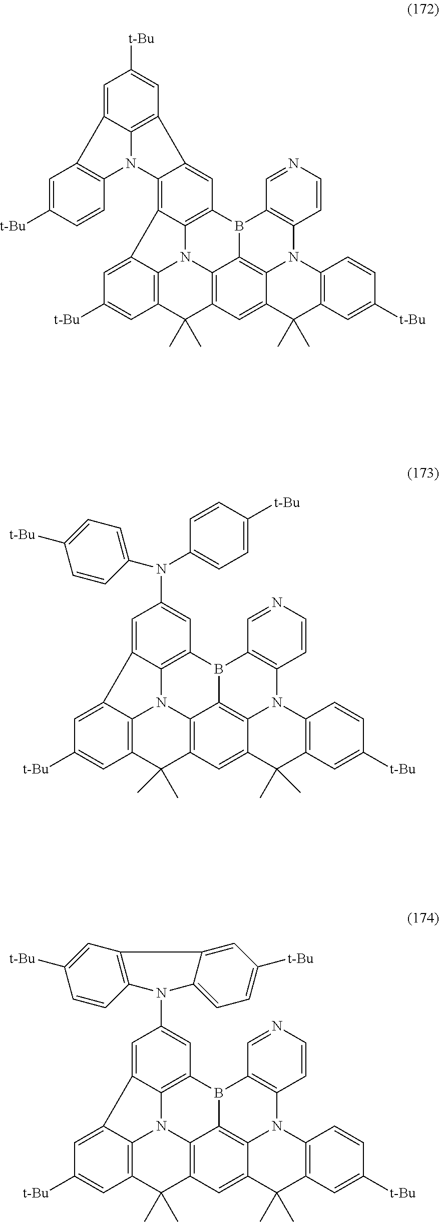 [SMILES: CC(C)(C)c1ccc2c(c1)C(C)(C)c1cc3c4c5c1N2c1ccncc1B5c1cc2c5cc(C(C)(C)C)cc6c7cc(C(C)(C)C)ccc7n(c65)c2c2c5cc(C(C)(C)C)cc(c5n-4c12)C3(C)C ; CC(C)(C)c1ccc(N(c2ccc(C(C)(C)C)cc2)c2cc3c4c(c2)c2cc(C(C)(C)C)cc5c2n4-c2c(cc4c6c2B3c2cnccc2N6c2ccc(C(C)(C)C)cc2C4(C)C)C5(C)C)cc1 ; CC(C)(C)c1ccc2c(c1)C(C)(C)c1cc3c4c5c1N2c1ccncc1B5c1cc(-n2c5ccc(C(C)(C)C)cc5c5cc(C(C)(C)C)ccc52)cc2c5cc(C(C)(C)C)cc(c5n-4c12)C3(C)C]

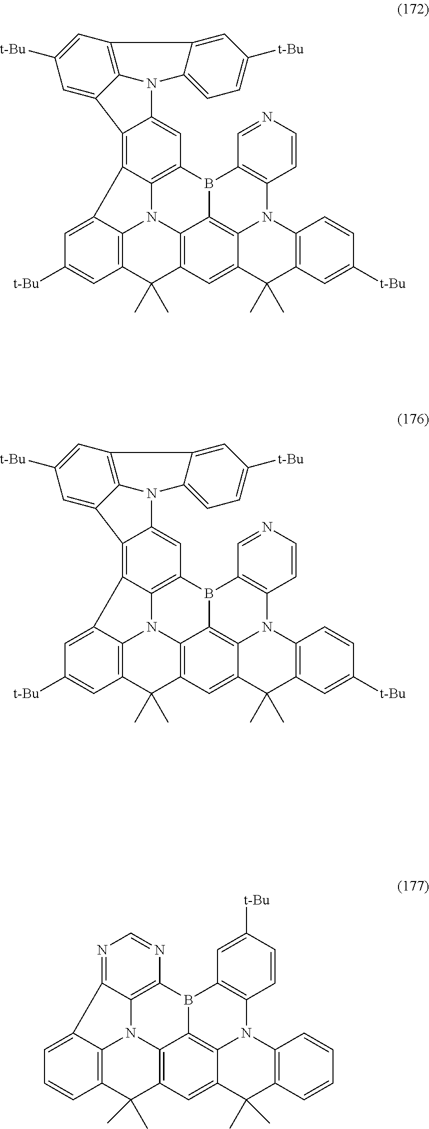 [SMILES: CC(C)(C)c1ccc2c(c1)C(C)(C)c1cc3c4c5c1N2c1ccncc1B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1ccncc1B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)B1c3c4c(cc5c3-n3c6c(cccc6c6ncnc1c63)C5(C)C)C(C)(C)c1ccccc1N24]

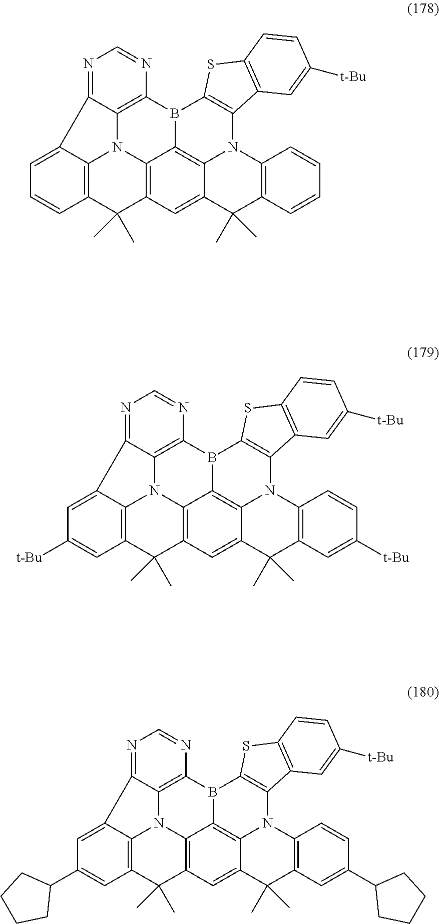 [SMILES: CC(C)(C)c1ccc2sc3c(c2c1)N1c2ccccc2C(C)(C)c2cc4c5c(c21)B3c1ncnc2c3cccc(c3n-5c12)C4(C)C ; CC(C)(C)c1ccc2c(c1)C(C)(C)c1cc3c4c5c1N2c1c(sc2ccc(C(C)(C)C)cc12)B5c1ncnc2c5cc(C(C)(C)C)cc(c5n-4c12)C3(C)C ; CC(C)(C)c1ccc2sc3c(c2c1)N1c2ccc(C4CCCC4)cc2C(C)(C)c2cc4c5c(c21)B3c1ncnc2c3cc(C6CCCC6)cc(c3n-5c12)C4(C)C]

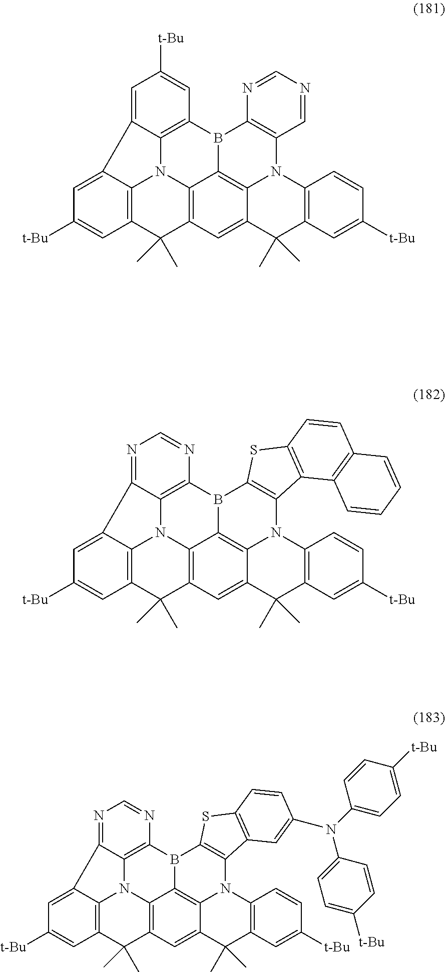 [SMILES: CC(C)(C)c1ccc2c(c1)C(C)(C)c1cc3c4c5c1N2c1cncnc1B5c1cc(C(C)(C)C)cc2c5cc(C(C)(C)C)cc(c5n-4c12)C3(C)C ; CC(C)(C)c1ccc2c(c1)C(C)(C)c1cc3c4c5c1N2c1c(sc2ccc6ccccc6c12)B5c1ncnc2c5cc(C(C)(C)C)cc(c5n-4c12)C3(C)C ; CC(C)(C)c1ccc(N(c2ccc(C(C)(C)C)cc2)c2ccc3sc4c(c3c2)N2c3ccc(C(C)(C)C)cc3C(C)(C)c3cc5c6c(c32)B4c2ncnc3c4cc(C(C)(C)C)cc(c4n-6c23)C5(C)C)cc1]

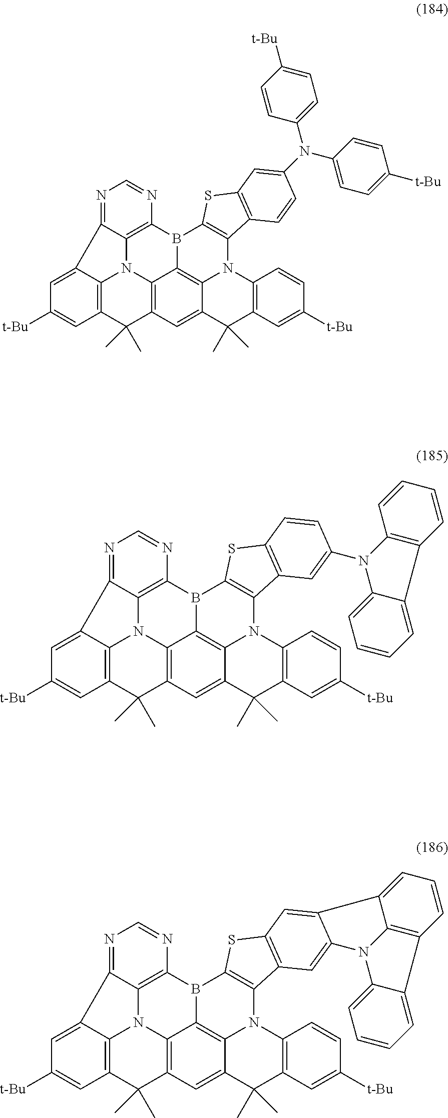 [SMILES: CC(C)(C)c1ccc(N(c2ccc(C(C)(C)C)cc2)c2ccc3c4c(sc3c2)B2c3c5c(cc6c3-n3c7c(cc(C(C)(C)C)cc7c7ncnc2c73)C6(C)C)C(C)(C)c2cc(C(C)(C)C)ccc2N54)cc1 ; CC(C)(C)c1ccc2c(c1)C(C)(C)c1cc3c4c5c1N2c1c(sc2ccc(-n6c7ccccc7c7ccccc76)cc12)B5c1ncnc2c5cc(C(C)(C)C)cc(c5n-4c12)C3(C)C ; CC(C)(C)c1ccc2c(c1)C(C)(C)c1cc3c4c5c1N2c1c(sc2cc6c7cccc8c9ccccc9n(c6cc12)c87)B5c1ncnc2c5cc(C(C)(C)C)cc(c5n-4c12)C3(C)C]

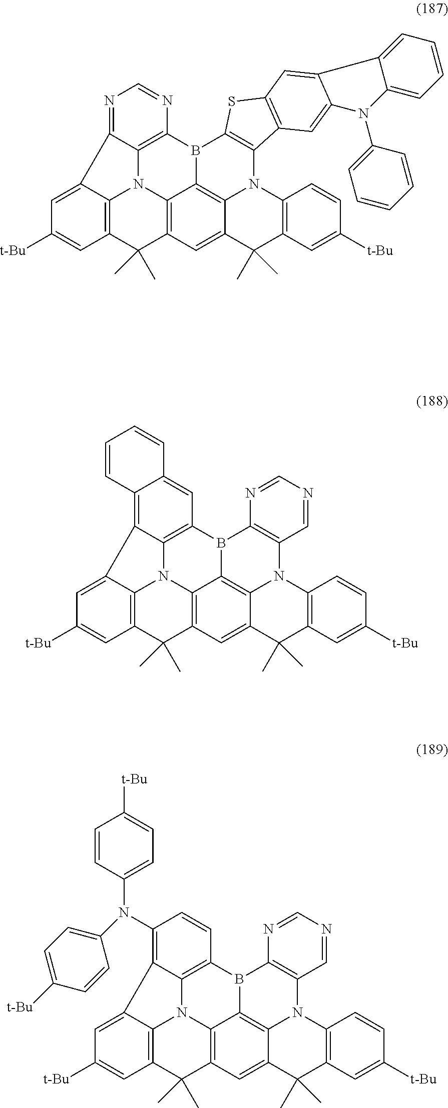 [SMILES: CC(C)(C)c1ccc2c(c1)C(C)(C)c1cc3c4c5c1N2c1c(sc2cc6c7ccccc7n(-c7ccccc7)c6cc12)B5c1ncnc2c5cc(C(C)(C)C)cc(c5n-4c12)C3(C)C ; CC(C)(C)c1ccc2c(c1)C(C)(C)c1cc3c4c5c1N2c1cncnc1B5c1cc2ccccc2c2c5cc(C(C)(C)C)cc(c5n-4c12)C3(C)C ; CC(C)(C)c1ccc(N(c2ccc(C(C)(C)C)cc2)c2ccc3c4c2c2cc(C(C)(C)C)cc5c2n4-c2c(cc4c6c2B3c2ncncc2N6c2ccc(C(C)(C)C)cc2C4(C)C)C5(C)C)cc1]

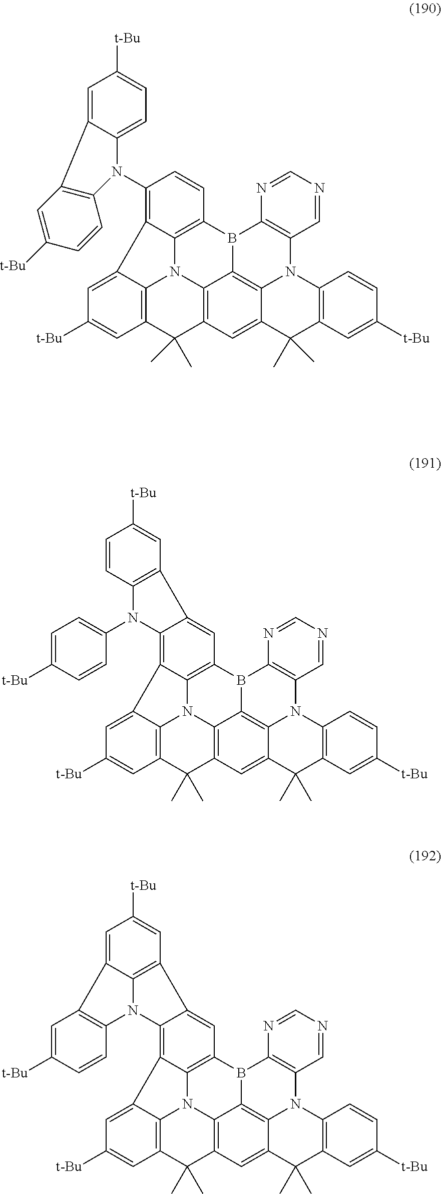 [SMILES: CC(C)(C)c1ccc2c(c1)C(C)(C)c1cc3c4c5c1N2c1cncnc1B5c1ccc(-n2c5ccc(C(C)(C)C)cc5c5cc(C(C)(C)C)ccc52)c2c5cc(C(C)(C)C)cc(c5n-4c12)C3(C)C ; CC(C)(C)c1ccc(-n2c3ccc(C(C)(C)C)cc3c3cc4c5c(c6cc(C(C)(C)C)cc7c6n5-c5c(cc6c8c5B4c4ncncc4N8c4ccc(C(C)(C)C)cc4C6(C)C)C7(C)C)c32)cc1 ; CC(C)(C)c1ccc2c(c1)C(C)(C)c1cc3c4c5c1N2c1cncnc1B5c1cc2c5cc(C(C)(C)C)cc6c7cc(C(C)(C)C)ccc7n(c65)c2c2c5cc(C(C)(C)C)cc(c5n-4c12)C3(C)C]

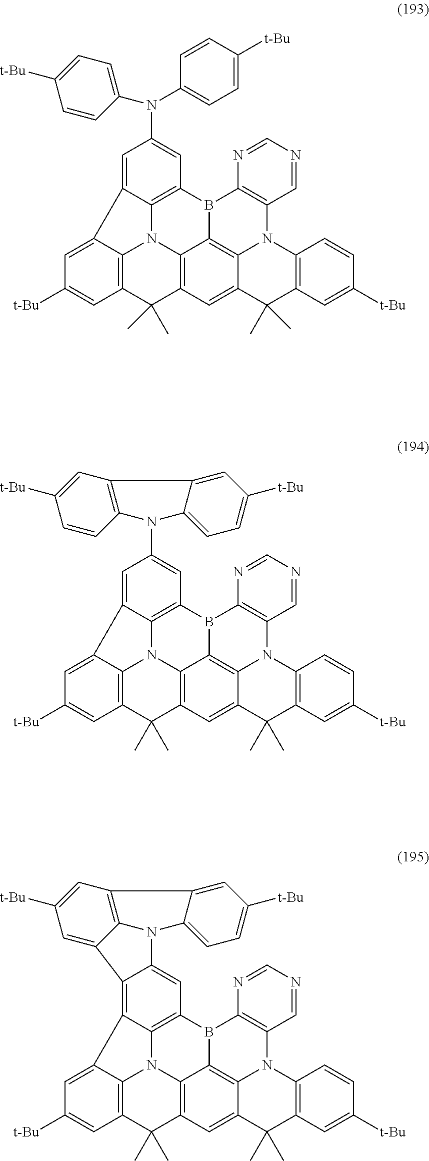 [SMILES: CC(C)(C)c1ccc(N(c2ccc(C(C)(C)C)cc2)c2cc3c4c(c2)c2cc(C(C)(C)C)cc5c2n4-c2c(cc4c6c2B3c2ncncc2N6c2ccc(C(C)(C)C)cc2C4(C)C)C5(C)C)cc1 ; CC(C)(C)c1ccc2c(c1)C(C)(C)c1cc3c4c5c1N2c1cncnc1B5c1cc(-n2c5ccc(C(C)(C)C)cc5c5cc(C(C)(C)C)ccc52)cc2c5cc(C(C)(C)C)cc(c5n-4c12)C3(C)C ; CC(C)(C)c1ccc2c(c1)C(C)(C)c1cc3c4c5c1N2c1cncnc1B5c1cc2c(c5cc(C(C)(C)C)cc6c7cc(C(C)(C)C)ccc7n2c65)c2c5cc(C(C)(C)C)cc(c5n-4c12)C3(C)C]

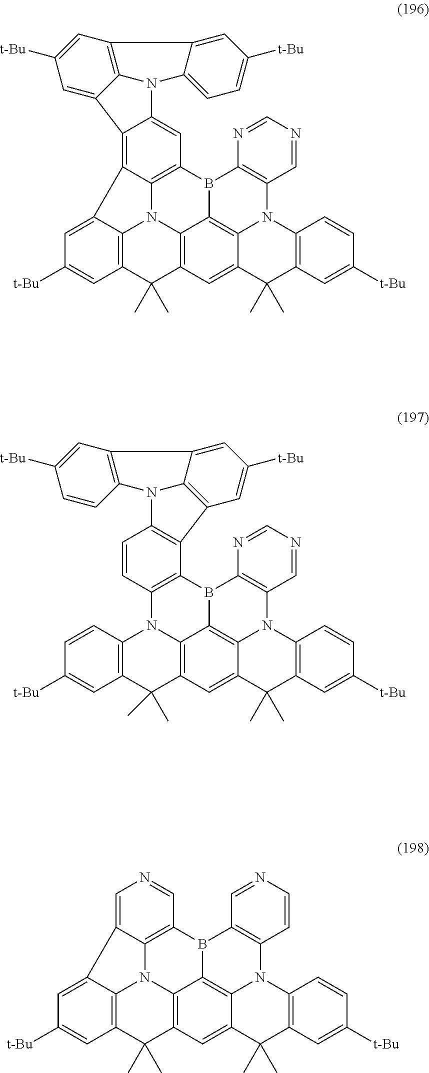 [SMILES: CC(C)(C)c1ccc2c(c1)C(C)(C)c1cc3c4c5c1N2c1cncnc1B5c1cc2c(c5cc(C(C)(C)C)cc6c7cc(C(C)(C)C)ccc7n2c65)c2c5cc(C(C)(C)C)cc(c5n-4c12)C3(C)C ; CC(C)(C)c1ccc2c(c1)C(C)(C)c1cc3c4c5c1N2c1cncnc1B5c1c(ccc2c1c1cc(C(C)(C)C)cc5c6cc(C(C)(C)C)ccc6n2c51)N4c1ccc(C(C)(C)C)cc1C3(C)C ; CC(C)(C)c1ccc2c(c1)C(C)(C)c1cc3c4c5c1N2c1ccncc1B5c1cncc2c5cc(C(C)(C)C)cc(c5n-4c12)C3(C)C]

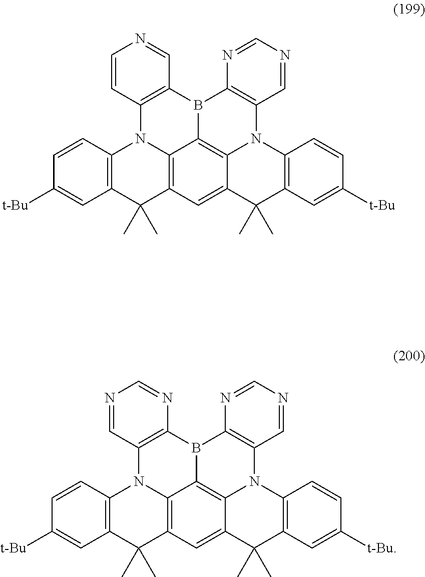 [SMILES: CC(C)(C)c1ccc2c(c1)C(C)(C)c1cc3c4c5c1N2c1ccncc1B5c1ncncc1N4c1ccc(C(C)(C)C)cc1C3(C)C ; CC(C)(C)c1ccc2c(c1)C(C)(C)c1cc3c4c5c1N2c1cncnc1B5c1ncncc1N4c1ccc(C(C)(C)C)cc1C3(C)C]

13. An electroluminescent device, comprising the organic electroluminescent material according to claim 1.

14. (canceled)

15. The electroluminescent device according to claim 13, wherein the electroluminescent device comprises an emission layer containing the organic electroluminescent material.

16. The electroluminescent device according to claim 15, wherein the organic electroluminescent material is used as a doping material or a sensitizer material of the emission layer.

17. A lighting or display element, comprising the electroluminescent device according to claim 13.

18. The organic electroluminescent material according to claim 2, wherein the heteroaryl group is selected from one or more of the group consisting of pyrrolyl, imidazolyl, thienyl, furanyl, 1,2-thiazolyl, 1,3-thiazolyl, 1,2,3-oxadiazolyl, 1,2,4-oxadiazolyl, thiadiazolyl, selenodiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indole, isoindole, benzimidazole, naphthimidazole, phenanthroimidazole, benzotriazole, purine, benzoxazole, naphthoxazole, phenanthroxazole, benzothiadiazolyl, benzotriazolyl, quinolyl, isoquinolyl, benzopyrazinyl, benzothiophenyl, benzofuranyl, benzopyrrolyl, carbazolyl, acridinyl, dibenzothiophenyl, dibenzofuranyl, dibenzothiophene-5,5-dioxy, naphthothiadiazolyl, naphthoselenodiazolyl and 10,15-dihydro-5H-diindolo[3,2-a: 3′,2′-c]carbazolyl.
